(19) United States
(12) Patent Application Publication
(10) Pub. No.: US 2018/0196179 A1
(43) Pub. Date: Jul. 12, 2018

(54) LAMINATE, OPTICAL SENSOR, AND KIT

(71) Applicant: FUJIFILM Corporation, Tokyo (JP)

(72) Inventors: Hirotaka TAKISHITA, Haibara-gun (JP); Tetsushi MIYATA, Haibara-gun (JP); Masahiro MORI, Haibara-gun (JP); Kazuto SHIMADA, Haibara-gun (JP); Ryoji GOTO, Haibara-gun (JP)

(73) Assignee: FUJIFILM Corporation, Tokyo (JP)

(21) Appl. No.: 15/912,574

(22) Filed: Mar. 6, 2018

Related U.S. Application Data
(63) Continuation of application No. PCT/JP2016/076509, filed on Sep. 8, 2016.

(30) Foreign Application Priority Data
Sep. 30, 2015 (JP) 2015-195187
Mar. 28, 2016 (JP) 2016-063768

(51) Int. Cl. G02B 5/26; G02B 5/20; C09K 19/36; C09K 19/56; C09K 19/58

(52) U.S. Cl. CPC G02B 5/26; G02B 5/208; H01L 27/14621; C09K 19/56; C09K 19/588; C09K 19/36

(57) ABSTRACT

A laminate includes at least one first reflective layer formed by immobilizing a liquid crystal phase in which a rotational direction of the helical axis is rightward, and at least one second reflective layer formed by immobilizing a liquid crystal phase in which the rotational direction of the helical axis is leftward, in which the laminate has a first transmission band in the wavelength range of 300 to 3,000 nm, the half-width of the first transmission band is 200 nm or less, an average transmittance in a wavelength range from a half-value wavelength A on the short wavelength side of the first transmission band to a half-value wavelength B on the long wavelength side of the first transmission band is 50% or more, and the average transmittance in the wavelength range of 100 nm from the half-value wavelength A to the short wavelength side and the average transmittance in the wavelength range of 100 nm from the half-value wavelength B to the long wavelength side are respectively less than 20%.

### CROSS-REFERENCE TO RELATED APPLICATIONS

This application is a Continuation of PCT International Application No. PCT/JP2016/76509, filed on Sep. 8, 2016, which claims priority under 35 U.S.C. §119(a) to Japanese Patent Application No. 2015-195187, filed on Sep. 30, 2015, and Japanese Patent Application No. 2016-63768, filed on Mar. 28, 2016. Each of the above application(s) is hereby expressly incorporated by reference, in its entirety, into the present application.

### BACKGROUND OF THE INVENTION

### 1. Field of the Invention

The present invention relates to a laminate, an optical sensor, and a kit.

### 2. Description of the Related Art

The bandpass filter can transmit light in a predetermined wavelength range and is therefore applied to various optical sensors. By using such a bandpass filter, for example, only the light reflected by an object, among the light emitted from a light source included in an optical sensor, can be selectively transmitted and received by various kinds of elements.

Among the bandpass filters, for example, as described in JP2004-004764A, a technique utilizing selective reflection characteristics of a cholesteric liquid crystal phase has been proposed.

### SUMMARY OF THE INVENTION

On the other hand, along with the improvement of the required characteristics of an optical sensor in recent years, improvement of the performance of a filter to be used is also demanded. In particular, a further reduction of a haze value of a filter is demanded.

The present inventors have studied about the cholesteric liquid crystal bandpass filter described in JP2004-004764A and found that the haze value thereof does not satisfy the recently required level and therefore a further improvement is required.

In view of the above-mentioned circumstances, it is an object of the present invention to provide a laminate having a predetermined transmission band and a reduced haze value.

It is another object of the present invention to provide an optical sensor including such a laminate and a kit for use in the production of such a laminate.

As a result of extensive studies to achieve the foregoing objects, the present inventors have found that the foregoing objects can be achieved by controlling an average transmittance in a transmission band and a wavelength range in the vicinity thereof. The present invention has been completed based on these findings.

That is, the present inventors have found that the foregoing objects can be achieved by the following constitution.

(1) A laminate, comprising:

at least one first reflective layer formed by immobilizing a liquid crystal phase in which a rotational direction of the helical axis is rightward; and

at least one second reflective layer formed by immobilizing a liquid crystal phase in which the rotational direction of the helical axis is leftward,

in which the laminate has a first transmission band in the wavelength range of 300 to 3,000 nm,

the half-width of the first transmission band is 200 nm or less,

an average transmittance in a wavelength range from a half-value wavelength A on the short wavelength side of the first transmission band to a half-value wavelength B on the long wavelength side of the first transmission band is 50% or more, and

the average transmittance in the wavelength range of 100 nm from the half-value wavelength A to the short wavelength side and the average transmittance in the wavelength range of 100 nm from the half-value wavelength B to the long wavelength side are respectively less than 20%.

(2) The laminate according to (1), further having a second transmission band in the wavelength range of 300 to 3,000 nm, in which

the half-width of the second transmission band is 200 nm or more,

the average transmittance in the wavelength range from a half-value wavelength C on the short wavelength side of the second transmission band to a half-value wavelength D on the long wavelength side of the second transmission band is 30% or more, and

the average transmittance in the wavelength range of 50 nm from the half-value wavelength C to the short wavelength side and the average transmittance in the wavelength range of 50 nm from the half-value wavelength D to the long wavelength side are respectively less than 30%.

(3) The laminate according to (2), in which the average transmittance in the wavelength range from the half-value wavelength C to the half-value wavelength D is 70% or more.

(4) The laminate according to (2) or (3), in which at least one of the first transmission band or the second transmission band is within a wavelength range of 650 to 3,000 nm.

(5) The laminate according to any one of (2) to (4), in which at least one of the first transmission band or the second transmission band is within a wavelength range of 650 to 1,200 nm.

(6) The laminate according to any one of (2) to (5), further having a wavelength range X being present only within at least one of the first transmission band or the second transmission band,

in which the wavelength range X is a range in which the transmittance exceeds 30% in the wavelength range of 400 to 1,200 nm.

(7) The laminate according to any one of (1) to (6), in which the value determined by (T2−T1)/20 is 1 to 5 in the case where the transmittance at a wavelength of 10 nm from the half-value wavelength A to the short wavelength side is T1 and the transmittance at a wavelength of 10 nm from the half-value wavelength A to the long wavelength side is T2, and

the value determined by (T3−T4)/20 is 1 to 5 in the case where the transmittance at a wavelength of 10 nm from the half-value wavelength B to the short wavelength side is T3 and the transmittance at a wavelength of 10 nm from the half-value wavelength B to the long wavelength side is T4, with the unit of T1 to T4 being %.

(8) The laminate according to any one of (1) to (7), which is used as a filter for an optical sensor.

(9) The laminate according to any one of (1) to (7), which is used as a filter for a solid-state imaging device.

(10) An optical sensor, comprising:

the laminate according to any one of (1) to (7); and

a light source emitting light having a peak wavelength located within a first transmission band of the laminate.

(11) A kit for use in the production of the laminate according to any one of (1) to (7), comprising:

a liquid crystal composition containing at least a liquid crystal compound and a dextrorotatory chiral agent; and

a liquid crystal composition containing at least a liquid crystal compound and a levorotatory chiral agent.

According to the present invention, it is possible to provide a laminate having a predetermined transmission band and a reduced haze value.

Further, according to the present invention, it is possible to provide an optical sensor including such a laminate and a kit for use in the production of such a laminate.

### BRIEF DESCRIPTION OF THE DRAWINGS

FIG. 1 is a cross-sectional view of a first embodiment of a laminate of the present invention.

FIG. 2 is an example of a transmission spectrum of a laminate for explaining a first transmission band.

FIG. 3 is an example of a transmission spectrum of a laminate for explaining a second transmission band.

FIG. 4A is an enlarged view of a transmission spectrum in the vicinity of a half-value wavelength A of a first transmission band, and FIG. 4B is an enlarged view of a transmission spectrum in the vicinity of a half-value wavelength B of a first transmission band.

FIG. 5 is an example of a transmission spectrum of each reflective layer.

FIG. 6 is a cross-sectional view of a second embodiment of the laminate of the present invention.

FIG. 7 is a cross-sectional view of a third embodiment of the laminate of the present invention.

FIG. 8 is a cross-sectional view of a fourth embodiment of the laminate of the present invention.

FIG. 9 is a cross-sectional view of a fifth embodiment of the laminate of the present invention.

### DESCRIPTION OF THE PREFERRED EMBODIMENTS

Hereinafter, suitable aspects of the present invention will be described.

Descriptions of the constituent elements described below may be made based on representative embodiments of the present invention, but the present invention is not limited to such embodiments. As used herein, the numerical range expressed by using “to” means a range including numerical values described before and after “to” as a lower limit value and an upper limit value, respectively.

The term “infrared light” as used herein is intended to mean a range of at least about 650 to 1,300 nm even though it may vary depending on the sensitivity of a solid-state imaging device. The term “visible light” as used herein is intended to mean a range of at least 400 nm or more and less than 650 nm.

In the present specification, in the case where a group (atomic group) is denoted without specifying whether it is substituted or unsubstituted, it includes a group having a substituent and a group having no substituent. For example, the term “alkyl group” includes not only an alkyl group having no substituent (unsubstituted alkyl group) but also an alkyl group having a substituent (substituted alkyl group).

### First Embodiment

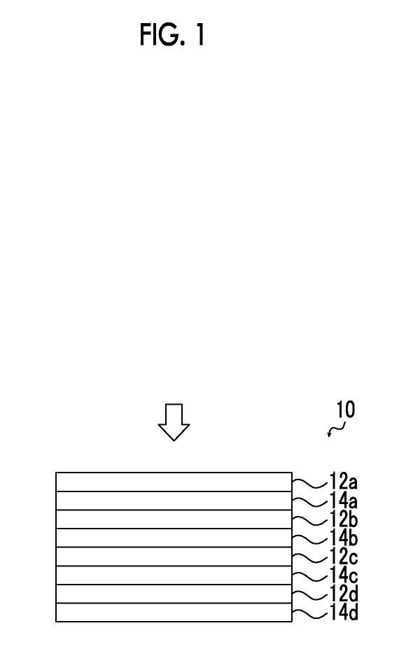

FIG. 1 shows a cross-sectional view of a first embodiment of the laminate of the present invention.

As shown in FIG. 1, a laminate 10 includes first reflective layers 12a to 12d formed by immobilizing a liquid crystal phase in which the rotational direction of the helical axis is rightward, and second reflective layers 14a to 14d formed by immobilizing a liquid crystal phase in which the rotational direction of the helical axis is leftward.

In the laminate 10, in the case where light enters from the direction of the hollow arrow shown in FIG. 1, predetermined light is reflected by the first reflective layers 12a to 12d and the second reflective layers 14a to 14d, and only the light in a predetermined wavelength range passes through the laminate 10. That is, the laminate 10 has a transmission band in a predetermined wavelength range.

As will be described later in detail, the laminate 10 includes four layers of the first reflective layers 12a to 12d and four layers of the second reflective layers 14a to 14d, respectively, but in the present invention, it is sufficient that at least one first reflective layer and at least one second reflective layer are included, and the number of layers of the first reflective layer and the second reflective layer is not particularly limited.

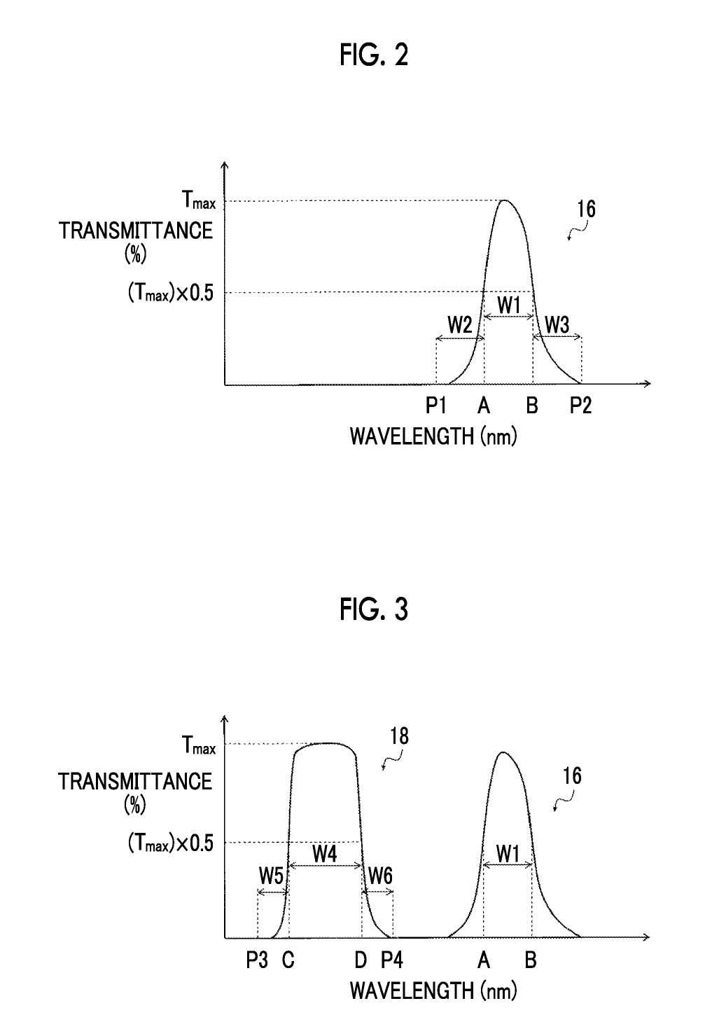

FIG. 2 is an example of a transmission spectrum of the laminate of the present invention.

Hereinafter, the optical characteristics (transmission characteristics) of the laminate will be described in detail with reference to FIG. 2.

The laminate of the present invention can transmit light in a predetermined wavelength range. More specifically, as shown in FIG. 2, the laminate of the present invention has a first transmission band 16 through which light having a predetermined wavelength passes. As will be described later in detail, the laminate of the present invention includes at least one or more layers of each of a first reflective layer and a second reflective layer that reflect light in a predetermined wavelength range, and the transmission band is formed by combining such reflective layers (preferably, combining a plurality of layers of the first reflective layer and the second reflective layer respectively).

The first transmission band is within the wavelength range of 300 to 3,000 nm, and from the viewpoint that the haze of the laminate is further reduced (hereinafter, also simply referred to as “the effects of the present invention are excellent”), it is preferably within the wavelength range of 650 to 3,000 nm and more preferably within the wavelength range of 650 to 1,200 nm.

For the reflective layer, those which selectively reflect on the long wavelength side can use a less amount of a chiral agent, so that haze hardly occurs.

First, the half-value wavelength of the first transmission band means a wavelength in the case where the transmittance is 50% with respect to the maximum transmittance (Tₘₐₓ) in the first transmission band ((Tₘₐₓ)×0.5). In FIG. 2, the half-value wavelength on the short wavelength side of the half-value wavelength is represented as a half-value wavelength A and the half-value wavelength on the long wavelength side of the half-value wavelength is represented as a half-value wavelength B.

As a method of specifying the half-value wavelength, a transmission spectrum of the laminate was obtained using a UV-VIS-NIR spectrophotometer (U-4100, manufactured by Hitachi High-Technologies Corporation), and the wavelength at the position of 50% of the maximum transmittance (Tₘₐₓ) of the first transmission band is calculated. The transmittance is the transmittance of light incident from the front (normal) direction of the laminate.

The half-width of the first transmission band (corresponding to half-width W1 in FIG. 2) is 200 nm or less, and from the viewpoint that the effects of the present invention are excellent, it is preferably 100 nm or less and more preferably 50 nm or less. The lower limit thereof is not particularly limited and is preferably 1 nm or more from the viewpoint of application to a predetermined use.

The half-width of the first transmission band is intended to mean a so-called full-width at half-maximum, and corresponds to the width between wavelengths in the case where it is 50% ((Tᵢₙₐₓ) 0.5) with respect to the maximum transmittance (Tₘₐₓ) in the first transmission band and corresponds to the difference between the half-value wavelength B and the half-value wavelength A.

The average transmittance in the wavelength range from the half-value wavelength A on the short wavelength side of the first transmission band to the half-value wavelength B on the long wavelength side of the first transmission band is 50% or more, and from the viewpoint that the effects of the present invention are excellent, it is preferably 55% or more and more preferably 60% or more. The upper limit thereof is not particularly limited and is often 99% or less in many cases.

As a method of measuring the average transmittance, a transmittance at 300 to 3,000 nm is measured using a UV-VIS-NIR spectrophotometer (U-4100, manufactured by Hitachi High-Technologies Corporation), and an average value of the transmittance in the wavelength range from the half-value wavelength A to the half-value wavelength B is calculated.

The transmittance T(%) is expressed by T=I/I₀×100 (where I is an intensity of the transmitted light and I₀ is an intensity of the incident light).

Further, in the laminate of the present invention, the average transmittance in the wavelength range of 100 nm from the half-value wavelength A on the short wavelength side to the short wavelength side is less than 20%. More specifically, as shown in FIG. 2, in the case where the wavelength on the short wavelength side 100 nm from the half-value wavelength A is taken as a wavelength P1, the average value of the transmittance in the wavelength range from the wavelength P1 to the half-value wavelength A is less than 20%. In FIG. 2, the width W2 from the wavelength P1 to the half-value wavelength A corresponds to 100 nm.

The average transmittance is preferably 15% or less and more preferably 10% or less, from the viewpoint that the effects of the present invention are excellent. The lower limit thereof is not particularly limited and is often 0.1% or more in many cases.

Measurement of the average transmittance is carried out by measuring the transmittance at 300 to 3,000 nm with a UV-VIS-NIR spectrophotometer (U-4100, manufactured by Hitachi High-Technologies Corporation) and calculating the average value of the transmittance in the wavelength range from the wavelength P1 to the half-value wavelength A.

In the laminate of the present invention, the average transmittance in the wavelength range of 100 nm from the half-value wavelength B on the long wavelength side to the long wavelength side is less than 20%. More specifically, as shown in FIG. 2, in the case where the wavelength on the long wavelength side 100 nm from the half-value wavelength B is taken as a wavelength P2, the average value of the transmittance in the wavelength range from the half-value wavelength B to the wavelength P2 is less than 20%. In FIG. 2, the width W3 from the half-value wavelength B to the wavelength P2 corresponds to 100 nm.

The average transmittance is preferably 15% or less and more preferably 10% or less, from the viewpoint that the effects of the present invention are excellent. The lower limit thereof is not particularly limited and is often 0.1% or more in many cases.

Measurement of the average transmittance is carried out by measuring the transmittance at 300 to 3,000 nm with a UV-VIS-NIR spectrophotometer (U-4100, manufactured by Hitachi High-Technologies Corporation) and calculating the average value of the transmittance in the wavelength range from the half-value wavelength B to the wavelength P2.

Although the details of the reason why the haze value is further reduced by including the foregoing first transmission band is unknown, it is presumed that the haze derived from the interference is reduced by overlapping the reflective layers formed by immobilizing a predetermined liquid crystal phase so that the wavelength range of the transmission band is within a predetermined range. At that time, fluctuation (slight variation in helical axis and pitch width) possessed by the reflective layer seems to work effectively.

The transmission spectrum of the laminate of the present invention is not limited to the aspect of FIG. 2, but it may be, for example, an aspect shown in FIG. 3. In the case of the aspect of FIG. 3, sensing using light within the first transmission band and sensing using light within the second transmission band to be described later can be carried out at the same time. In particular, in the case where the second transmission band to be described later is in the visible range and the first transmission band is in the near-infrared range, the laminate of the present invention can be suitably used for a device or the like which simultaneously plays the role of an image sensor using light in the visible range and an optical sensor using light in the near-infrared range.

As shown in FIG. 3, the laminate of the present invention may further have a second transmission band 18 which is a band different from the first transmission band 16 and through which light of a predetermined wavelength passes, together with the first transmission band 16 through which light of a predetermined wavelength passes.

The description of the first transmission band is as described above, and hereinafter the second transmission band will be described in detail.

The second transmission band is within the wavelength range of 300 to 3,000 nm.

In the case where the laminate has the second transmission band, it is preferred that one of the first transmission band and the second transmission band is within a wavelength range of 650 to 3,000 nm (more preferably, 650 to 1,200 nm) from the viewpoint that the effects of the present invention are excellent. The other of the first transmission band and the second transmission band is preferably within a wavelength range of 300 nm or more and less than 750 nm (more preferably 400 to 700 nm).

The second transmission band is preferably located on the shorter wavelength side than the first transmission band, from the viewpoint that the effects of the present invention are excellent. That is, in the case where the laminate has the second transmission band, it is preferred that the first transmission band is within the wavelength range of 650 to 3,000 nm (more preferably, 650 to 1,200 nm) and the second transmission band is within the wavelength range of 300 nm or more and less than 750 nm (more preferably, 400 to 700 nm).

First, the half-value wavelength of the second transmission band means a wavelength in the case where the transmittance is 50% with respect to the maximum transmittance (Tₘₐₓ) in the second transmission band ((Tₘₐₓ)×0.5). In FIG. 3, the half-value wavelength on the short wavelength side of the half-value wavelength is represented as a half-value wavelength C and the half-value wavelength on the long wavelength side of the half-value wavelength is represented as a half-value wavelength D.

As a method of specifying the half-value wavelength, a transmission spectrum of the laminate was obtained using a UV-VIS-NIR spectrophotometer (U-4100, manufactured by Hitachi High-Technologies Corporation), and the wavelength at the position of 50% of the maximum transmittance (Tₘₐₓ) of the second transmission band is calculated. The transmittance is the transmittance of light incident from the front (normal) direction of the laminate.

The half-width of the second transmission band (corresponding to half-width W4 in FIG. 3) is 200 nm or more, and from the viewpoint that the effects of the present invention are excellent, it is preferably 240 nm or more and more preferably 280 nm or more. The upper limit thereof is not particularly limited and is preferably 400 nm or less from the viewpoint of application to a predetermined use.

The half-width of the second transmission band is intended to mean a so-called full-width at half-maximum, and corresponds to the width between wavelengths in the case where it is 50% ((Tₘₐₓ)×0.5) with respect to the maximum transmittance (Tₘₐₓ) in the second transmission band and corresponds to the difference between the half-value wavelength D and the half-value wavelength C.

The average transmittance in the wavelength range from the half-value wavelength C on the short wavelength side of the second transmission band to the half-value wavelength D on the long wavelength side of the second transmission band is 30% or more, and from the viewpoint that the effects of the present invention are excellent, it is preferably 50% or more and more preferably 70% or more. The upper limit thereof is not particularly limited and is often 99% or less in many cases.

As a method of measuring the average transmittance, a transmittance at 300 to 3,000 nm is measured using a UV-VIS-NIR spectrophotometer (U-4100, manufactured by Hitachi High-Technologies Corporation), and an average value of the transmittance in the wavelength range from the half-value wavelength C to the half-value wavelength D is calculated.

Further, in the laminate of the present invention, the average transmittance in the wavelength range of 50 nm from the half-value wavelength C on the short wavelength side to the short wavelength side is less than 30%. More specifically, as shown in FIG. 3, in the case where the wavelength on the short wavelength side 50 nm from the half-value wavelength C is taken as a wavelength P3, the average value of the transmittance in the wavelength range from the wavelength P3 to the half-value wavelength C is less than 30%. In FIG. 3, the width W5 from the wavelength P3 to the half-value wavelength C corresponds to 50 nm.

The average transmittance is preferably 20% or less and more preferably 10% or less, from the viewpoint that the effects of the present invention are excellent. The lower limit thereof is not particularly limited and is often 0.1% or more in many cases.

Measurement of the average transmittance is carried out by measuring the transmittance at 300 to 3,000 nm with a UV-VIS-NIR spectrophotometer (U-4100, manufactured by Hitachi High-Technologies Corporation) and calculating the average value of the transmittance in the wavelength range from the wavelength P3 to the half-value wavelength C.

In the laminate of the present invention, the average transmittance in the wavelength range of 50 nm from the half-value wavelength D on the long wavelength side to the long wavelength side is less than 30%. More specifically, as shown in FIG. 3, in the case where the wavelength on the long wavelength side 50 nm from the half-value wavelength D is taken as a wavelength P4, the average value of the transmittance in the wavelength range from the half-value wavelength D to the wavelength P4 is less than 30%. In FIG. 3, the width W6 from the half-value wavelength D to the wavelength P4 corresponds to 50 nm.

The average transmittance is preferably 20% or less and more preferably 10% or less, from the viewpoint that the effects of the present invention are excellent. The lower limit thereof is not particularly limited and is often 0.1% or more in many cases.

Measurement of the average transmittance is carried out by measuring the transmittance at 300 to 3,000 nm with a UV-VIS-NIR spectrophotometer (U-4100, manufactured by Hitachi High-Technologies Corporation) and calculating the average value of the transmittance in the wavelength range from the half-value wavelength D to the wavelength P4.

As one suitable aspect of the laminate of the present invention, it is preferred that there is a wavelength range X in which the transmittance exceeds 30% in the wavelength range of 400 to 1,200 nm, and the wavelength range X is present only within at least one of the first transmission band or the second transmission band. In other words, in the laminate of the present invention, the wavelength range where the transmittance exceeds 30% in the wavelength range of 400 to 1,200 nm is preferably only the wavelength range of at least one of the first transmission band or the second transmission band.

As one suitable aspect of the laminate of the present invention, it is preferred that, in the first transmission band, a value determined by (T2−T1)/20 is 1 to 5 in the case where the transmittance at the wavelength of 10 nm from the half-value wavelength A on the short wavelength side to the short wavelength side is taken as T1 and the transmittance at the wavelength of 10 nm from the half-value wavelength A on the short wavelength side to the long wavelength side is taken as T2; and a value determined by (T3−T4)/20 is 1 to 5 in the case where the transmittance at the wavelength of 10 nm from the half-value wavelength B on the long wavelength side to the short wavelength side is taken as T3 and the transmittance at the wavelength of 10 nm from the half-value wavelength B on the short wavelength side to the long wavelength side is taken as T4. The unit of T1 to T4 is %. In the case where the above-mentioned requirements are satisfied, the transmittance of the transmission band tends to be kept high and the light sensing efficiency increases even in the case where the half-width of the transmission band is narrowed.

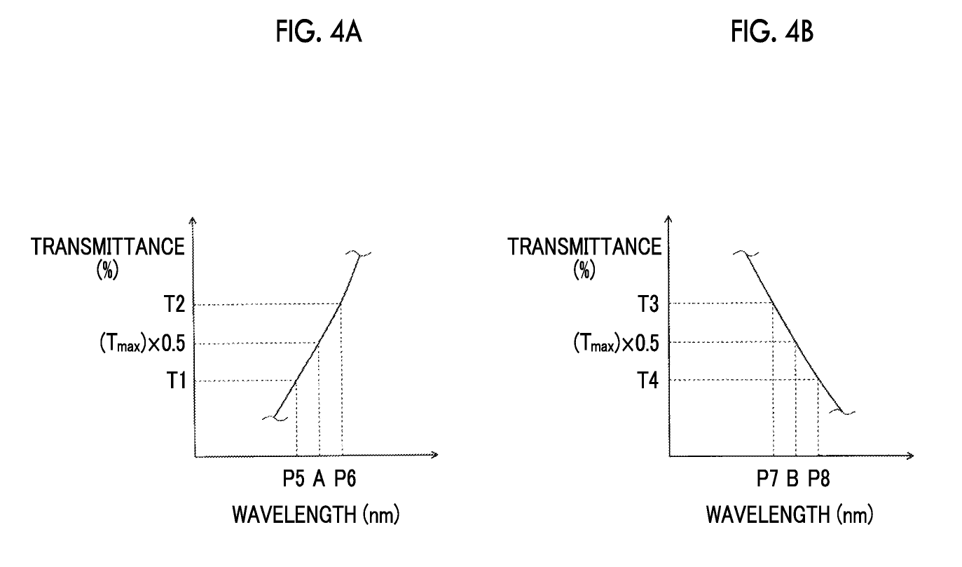

The above-mentioned requirements will be described with reference to FIGS. 4(A) and 4(B). FIG. 4(A) is an enlarged view of the transmission spectrum in the vicinity of the half-value wavelength A of the first transmission band, and FIG. 4(B) is an enlarged view of the transmission spectrum in the vicinity of the half-value wavelength B of the first transmission band.

As will be described later in detail, the values determined by (T2-T1)/20 and (T3-T4)/20 represent the slope of the transmission spectrum in the vicinity of the half-value wavelength A and the half-value wavelength B.

As shown in FIG. 4(A), in the case where the position of 10 nm from the half-value wavelength A to the short wavelength side is set as a wavelength P5, the transmittance at the wavelength P5 is taken as T1. Further, in the case where the position of 10 nm from the half-value wavelength A to the long wavelength side is set as a wavelength P6, the transmittance at the wavelength P6 is taken as T2.

Next, the slope S1 of the transmission spectrum in the wavelength range from the wavelength P5 to the wavelength P6 is calculated by obtaining the difference between T2 and T1 and dividing the obtained value (T2−T1) by “20” (nm) which is the difference between the wavelength P6 and the wavelength P5. That is, S1=(T2−T1)/20. The unit of S1 corresponds to (%/nm).

The value of S1 thus obtained is preferably 1 to 10, more preferably 1 to 5, still more preferably 2 to 5, and particularly preferably 3 to 5.

As shown in FIG. 4(B), in the case where the position of 10 nm from the half-value wavelength B to the short wavelength side is set as a wavelength P7, the transmittance at the wavelength P7 is taken as T3. Further, in the case where the position of 10 nm from the half-value wavelength B to the long wavelength side is set as a wavelength P8, the transmittance at the wavelength P8 is taken as T4.

Next, the absolute value S2 of the slope of the transmission spectrum in the wavelength range from the wavelength P8 to the wavelength P7 is calculated by obtaining the difference between T3 and T4 and dividing the obtained value (T3−T4) by “20” (nm) which is the difference between the wavelength P8 and the wavelength P7. That is, S2=(T3−T4)/20. The unit of S2 corresponds to (%/nm).

The value of S2 thus obtained is preferably 1 to 10, more preferably 1 to 5, still more preferably 2 to 5, and particularly preferably 3 to 5.

Hereinafter, members constituting the laminate of the present invention will be described in detail.

<First Reflective Layer (First Selective Reflective Layer) and Second Reflective Layer (Second Selective Reflective Layer)>

The first reflective layer and the second reflective layer are layers having shielding properties (reflectivity) against light of a predetermined wavelength. As shown in FIG. 1, in the laminate 10 of the present invention, eight layers of the first reflective layer 12a, the second reflective layer 14a, the first reflective layer 12b, the second reflective layer 14b, the first reflective layer 12c, the second reflective layer 14c, a first reflective layer 12d, and a second reflective layer 14d are laminated in this order. The first reflective layers 12a to 12d are layers formed by immobilizing a liquid crystal phase in which the rotational direction of the helical axis is rightward, and are layers for selectively reflecting the dextrorotatory circularly polarized light in a predetermined wavelength range. The second reflective layers 14a to 14d are layers formed by immobilizing a liquid crystal phase in which the rotational direction of the helical axis is leftward and are layers for selectively reflecting the levorotatory circularly polarized light in a predetermined wavelength range.

It should be noted that the above-mentioned rotational direction is determined as to whether the rotational direction of the helical axis is rightward or leftward in the case of observing the laminate 10 from the hollow arrow side (the upper side in the drawing) in FIG. 1.

Each of the first reflective layers 12a to 12d and the second reflective layers 14a to 14d is made of a layer in which a liquid crystal phase (for example, a rod-like liquid crystal or a disk-like liquid crystal) having a helical axis is immobilized. The liquid crystal phase having each helical axis in each reflective layer consists of an overlap of a number of layers, and within that one thin layer, the liquid crystal compound is aligned in such a way that, for example, the long axis is parallel to the layer and the direction is aligned. Then, the thin layer is accumulated so that the arrangement direction of the molecules is spiral with respect to each other. The helical axis is usually perpendicular to the surface of each reflective layer. Therefore, one of the levorotatory/dextrorotatory circular polarization components is selectively reflected corresponding to the helical pitch.

The first reflective layer 12a and the second reflective layer 14a have substantially the same helical pitch, the first reflective layer 12b and the second reflective layer 14b have substantially the same helical pitch, the first reflective layer 12c and the second reflective layer 14c have substantially the same helical pitch, and the first reflective layer 12d and the second reflective layer 14d have substantially the same helical pitch. Therefore, by combining each of the first reflective layers 12a to 12d and the second reflective layers 14a to 14d, each of the levorotatory circularly polarized component and the dextrorotatory circularly polarized component can be reflected, and as a result, light in a predetermined wavelength range can be reflected.

For example, the first reflective layers 12a and 12b and the second reflective layers 14a and 14b are responsible for reflecting light on the short wavelength side, and the first reflective layers 12c and 12d and the second reflective layers 14c and 14d are responsible for reflecting light on the long wavelength side. In other words, by using eight reflective layers, a predetermined wavelength range is complementarily reflected and a transmission band where only light in a specific wavelength range transmits is formed.

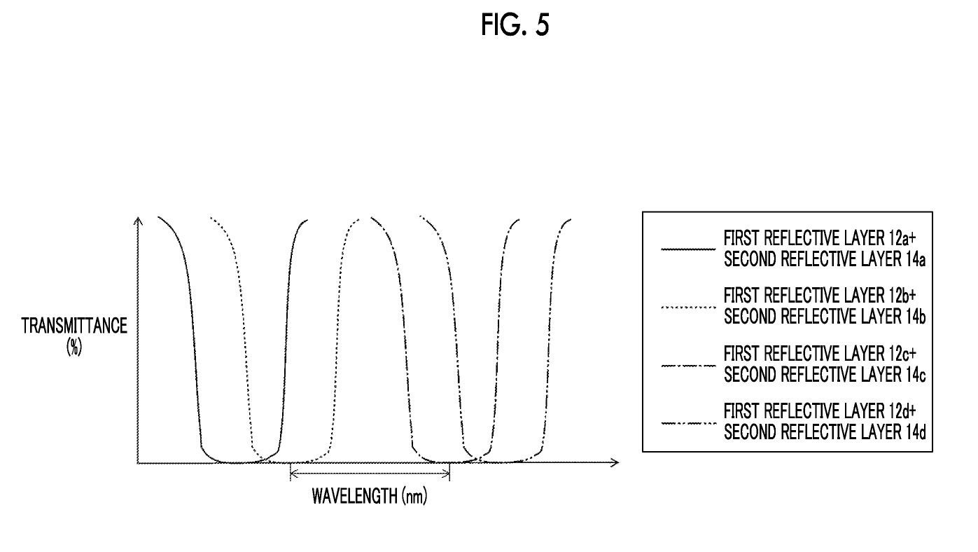

More specifically, FIG. 5 shows an example of a transmission spectrum of a laminate in which the first reflective layers 12a to 12d and the second reflective layers 14a to 14d are combined and laminated, respectively. Light in a predetermined wavelength range can be reflected by a combination of the respective reflective layers, and the wavelength in the region indicated by the arrow in FIG. 5 can be selectively transmitted by laminating these eight layers, so that the above-mentioned transmission band (first transmission band or second transmission band) can be formed.

In the case where there are a plurality of first reflective layers as described above, it is preferred that selective reflection wavelengths of the respective first reflective layers are different from the viewpoint of complementarily reflecting the light of each region. Here, the difference in selective reflection wavelengths between the two first reflective layers means that the difference between the two selective reflection wavelengths is preferably at least 20 nm, more preferably 30 nm or more, and still more preferably 40 nm or more. The upper limit thereof is not particularly limited and is preferably 200 nm or less.

Even in the case where there are a plurality of second reflective layers, it is preferred that selective reflection wavelengths of the respective second reflective layers are different, as in the case where there are a plurality of the first reflective layers, and suitable aspects thereof are as described above.

The term “selective reflection wavelength of the reflective layer” means an average value of the two wavelengths showing the half value transmittance: T½(%) represented by the following equation, in the case where the minimum value of the transmittance in the reflective layer is Tmin(%).

Equation for determining half value transmittance: T½=100−(100−Tmin)/2 p More specifically, there are two wavelengths showing the above-mentioned half value transmittance per layer of the reflective layer in the long wave side (λ1) and the short wavelength side (λ2), and the value of the selective reflection wavelength is represented by an average value of λ1 and λ2.

As described above, in FIG. 1, the first reflective layer and the second reflective layer each have an aspect of a four-layer structure, but it is not limited to such an aspect.

The total number of layers of the first reflective layer and the second reflective layer is not particularly limited, and it is, for example, preferably 1 to 20 layers and more preferably 1 to 10 layers for each of the first reflective layer and the second reflective layer.

The total number of layers of the first reflective layer and the total number of layers of the second reflective layer are independent of each other and may be the same or different, preferably the same.

The laminate may have two or more sets each including one layer of the first reflective layer and one layer of the second reflective layer. In this case, the selective reflection wavelengths of the first reflective layer and the second reflective layer included in each set are preferably equal to each other.

In the laminate, the selective reflection wavelength of at least one first reflective layer and the selective reflection wavelength of at least one second reflective layer are preferably equal to each other. In an aspect in which at least one first reflective layer and at least one second reflective layer have substantially the same helical pitch and exhibit optical rotations in opposite directions to each other, both of levorotatory circularly polarized light and dextrorotatory circularly polarized light having substantially the same wavelength can be reflected, which is thus preferable.

In addition, the selective reflection wavelengths of the reflective layers are “equal to each other” does not mean that they are exactly equal to each other, but an error in a range that does not have an optical influence is allowed. In the present specification, the selective reflection wavelengths of two reflective layers are “equal to each other” means that the difference between the selective reflection wavelengths of the two reflective layers is 20 nm or less, and such a difference is preferably 15 nm or less and more preferably 10 nm or less.

By laminating two reflective layers having selective reflection wavelengths equal to each other and having right and left optical rotation properties different from each other, the transmission spectrum of the laminate shows one strong peak at this selective reflection wavelength, which is preferable from the viewpoint of reflection performance.

The thicknesses of the first reflective layer and the second reflective layer are not particularly limited, and are preferably about 1 to 8 μm (more preferably about 2 to 7 μm). However, the thickness of the reflective layer is not limited to such a range. It is possible to form each reflective layer having a desired helical pitch by adjusting the types and concentrations of the materials (mainly liquid crystal materials and chiral agents) used for forming each of the first reflective layer and the second reflective layer.

Each of the reflective layers (the first reflective layer and the second reflective layer) is preferably a layer in which a cholesteric liquid crystal phase is immobilized (a layer in which a cholesteric liquid crystal compound is immobilized). In other words, the first reflective layer is preferably a layer formed by immobilizing a cholesteric liquid crystal phase in which the rotational direction of the helical axis is rightward, and the second reflective layer is preferably a layer formed by immobilizing a cholesteric liquid crystal phase in which the rotational direction of the helical axis is leftward.

Each of the reflective layers is preferably formed by applying a liquid crystal compound having a polymerizable group (cholesteric liquid crystal compound), aligning the applied liquid crystal compound into a cholesteric liquid crystal phase, and then immobilizing the cholesteric liquid crystal phase by polymerization (preferably photopolymerization).

For forming each reflective layer, it is preferable to use a curable (polymerizable) liquid crystal composition. As an example of the liquid crystal composition, preferred is an aspect containing at least a rod-like liquid crystal compound having a polymerizable group, a chiral agent, and a polymerization initiator. Two or more kinds of each component may be contained. For example, it is possible to use a combination of a polymerizable liquid crystal compound and a non-polymerizable liquid crystal compound. It is also possible to use a combination of a low molecular weight liquid crystal compound and a high molecular weight liquid crystal compound. Furthermore, in order to improve the uniformity of alignment, coating suitability, and film strength, the liquid crystal composition may contain at least one selected from various additives such as a horizontal alignment agent, an unevenness inhibitor, a cissing inhibitor, and a polymerizable monomer. If necessary, the polymerizable liquid crystal composition may further contain a polymerization inhibitor, an antioxidant, an ultraviolet absorber, a photostabilizer, a coloring material, metal oxide fine particles, or the like within a range not deteriorating the optical performance.

The antioxidant (coloring inhibitor) is preferably a phenol compound, a phosphite ester compound, or a thioether compound and more preferably a phenol compound having a molecular weight of 500 or more, a phosphite ester compound having a molecular weight of 500 or more, or a thioether compound. These compounds may be used in combination of two or more thereof. As the phenol compound, any phenol compound known as a phenol-based antioxidant can be used. The preferred phenol compound may be, for example, a hindered phenol compound. In particular, preferred is a compound having a substituent at a site (ortho position) adjacent to the phenolic hydroxyl group, and in that case, the substituent is preferably a substituted or unsubstituted alkyl group having 1 to 22 carbon atoms and more preferably a methyl group, an ethyl group, a propyl group, an isopropyl group, a butyl group, an isobutyl group, a t-butyl group, a pentyl group, an isopentyl group, a t-pentyl group, a hexyl group, an octyl group, an isooctyl group, or a 2-ethylhexyl group. A stabilizer having a phenol group and a phosphite ester group in the same molecule can also be mentioned as a preferred material.

A phosphorus-based antioxidant can also be suitably used. The phosphorus-based antioxidant may be, for example, at least one compound selected from the group consisting of tris[2-[[2,4,8,10-tetrakis(1,1-dimethylethyl)dibenzo[d,f] [1,3,2]dioxaphosphepin-6-yl]oxy]ethyl]amine, tris[2-[(4,6,9,11-tetra-tert-butyldibenzo[d,f] [1,3,2]dioxaphosphepin-2-yl)oxy]ethyl]amine, and ethyl bis(2,4-di-tert-butyl-6-methylphenyl)phosphite.

These compounds are readily commercially available and are sold by the manufacturers below. The commercial products of the antioxidant are available as ADEKASTAB AO-20, ADEKASTAB AO-30, ADEKASTAB AO-40, ADEKASTAB AO-50, ADEKASTAB AO-50F, ADEKASTAB AO-60, ADEKASTAB AO-60G ADEKASTAB AO-80, and ADEKASTAB AO-330 from Asahi Denka Kogyo Kabushiki Kaisha.

The content of the antioxidant (coloring inhibitor) in the reflective layer is preferably 0.01 mass % or more and 20 mass % or less and more preferably 0.3 mass % or more and 15 mass % or less in terms of solid content.

The antioxidants may be used in combination of two or more thereof.

(Liquid Cystal Cmpound)

The liquid crystal compound that can be used in the present invention may be a so-called rod-like liquid crystal compound or a disk-like liquid crystal compound, and is not particularly limited. Among them, preferred is a rod-like liquid crystal compound.

Examples of the rod-like liquid crystal compound that can be used in the present invention are rod-like nematic liquid crystal compounds. As the rod-like nematic liquid crystal compound, azomethines, azoxys, cyanobiphenyls, cyanophenyl esters, benzoic acid esters, cyclohexane carboxylic acid phenyl esters, cyanophenyl cyclohexanes, cyano-substituted phenyl pyrimidines, alkoxy-substituted phenyl pyrimidines, phenyl dioxanes, tolans, and alkenyl cyclohexyl benzonitriles are preferably used. Not only low molecular weight liquid crystal compounds but also high molecular weight liquid crystal compounds can be used.

The liquid crystal compound may be polymerizable or non-polymerizable, and a liquid crystal compound having a polymerizable group is preferably used. As described above, the first reflective layer and/or the second reflective layer is preferably a layer formed using a liquid crystal compound having a polymerizable group. In other words, it is preferred that the first reflective layer and/or the second reflective layer is a layer formed by using and polymerizing a liquid crystal compound having a polymerizable group.

Examples of the polymerizable group include an unsaturated polymerizable group, an epoxy group, and an aziridinyl group, among which an unsaturated polymerizable group is preferable and an ethylenically unsaturated polymerizable group (for example, an acryloyloxy group or a methacryloyloxy group) is more preferable. The number of polymerizable groups contained in the liquid crystal compound is preferably 1 to 6 and more preferably 1 to 3.

Specific examples of the liquid crystal compound include the compounds described in, for example, paragraphs [0031] to [0053] of JP2014-119605A, the contents of which are incorporated herein by reference in its entirety.

More specifically, the liquid crystal compound may be, for example, a liquid crystal compound represented by General Formula (X).

Q¹-L¹—Cy¹-L²-(Cy²-L³)ₙ—Cy³-L⁴-Q² General Formula (X)

In General Formula (X), Q¹ and Q² are each independently a polymerizable group, L¹ and L⁴ are each independently a divalent linking group, L² and L³ are each independently a single bond or a divalent linking group, Cy¹, Cy², and Cy³ are each independently a divalent cyclic group, and n is 0, 1, 2, or 3.

Hereinafter, the liquid crystal compound represented by General Formula (X) will be described.

In General Formula (X), Q¹ and Q² are each independently a polymerizable group. The polymerization reaction of the polymerizable group is preferably addition polymerization (including ring-opening polymerization) or condensation polymerization. In other words, the polymerizable group is preferably a functional group capable of addition polymerization reaction or condensation polymerization reaction.

In General Formula (X), L¹ and L⁴ are each independently a divalent linking group. L² and L³ are each independently a single bond or a divalent linking group.

L¹ to L⁴ are each independently preferably a divalent linking group selected from the group consisting of —O—, —S—, —CO—, —NR—, —C═N—, a divalent chain-like group, a divalent cyclic group, and a combination thereof. R is an alkyl group having 1 to 7 carbon atoms or a hydrogen atom.

In General Formula (X), Cy¹, Cy², and Cy³ are each independently a divalent cyclic group.

The ring contained in the cyclic group is preferably a 5-membered ring, a 6-membered ring, or a 7-membered ring, more preferably a 5-membered ring or a 6-membered ring, and still more preferably a 6-membered ring.

The ring contained in the cyclic group may be a fused ring. However, it is more preferred that the ring is a monocyclic ring rather than a fused ring.

The ring contained in the cyclic group may be any of an aromatic ring, an aliphatic ring, and a heterocyclic ring. Examples of the aromatic ring include a benzene ring and a naphthalene ring. Examples of the aliphatic ring include a cyclohexane ring. Examples of the heterocyclic ring include a pyridine ring and a pyrimidine ring.

As the rod-like liquid crystal compound, in addition to the liquid crystal compound represented by General Formula (X), it is preferable to use at least one compound represented by General Formula (V) in combination.

In General Formula (V)

M¹-(L¹)ₚ—Cy¹-L²-(Cy²-L³)ₙ—Cy³-(L⁴)(_{q}-M²

In General Formula (V), M¹ and M² each independently represent a hydrogen atom, a substituted or unsubstituted alkyl group, a substituted or unsubstituted aryl group, a heterocyclic group, a cyano group, a halogen, —SCN, —CF₃, a nitro group, or Q¹, provided that at least one of M¹ or M² represents a group other than Q¹.

Meanwhile, Q¹, L¹, L², L³, L⁴, Cy¹, Cy², Cy³, and n have the same definition as in the group represented by General Formula (X). Further, p and q are 0 or 1.

The following compounds are exemplified as the liquid crystal compound.

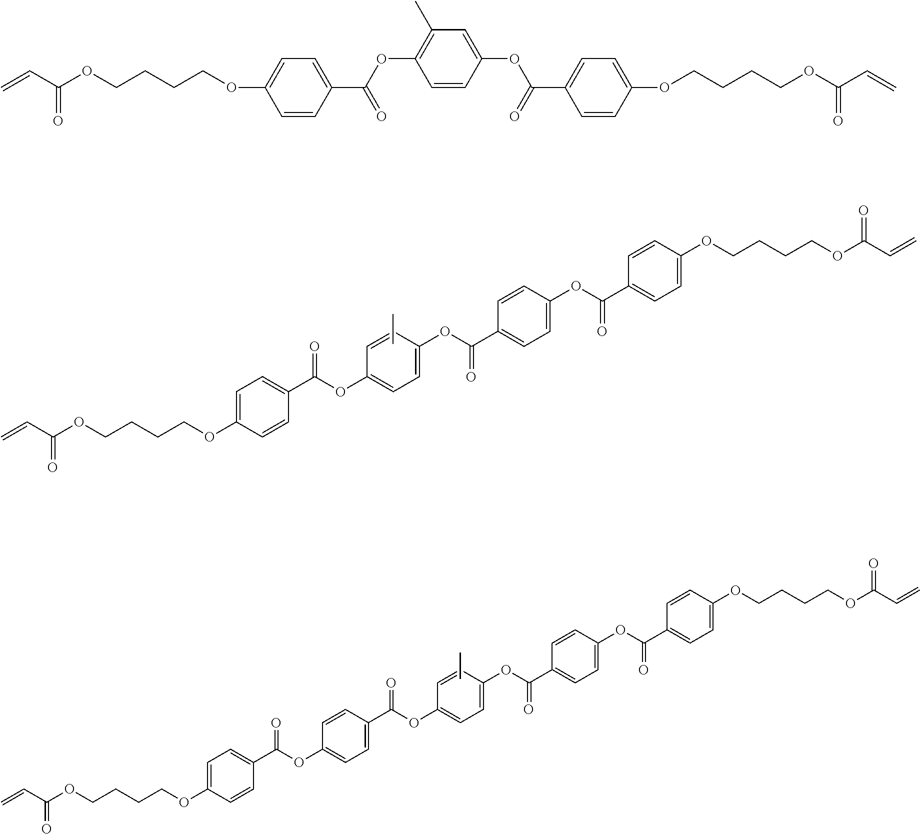

The bandwidth Δλ of selective reflection by the first reflective layer and the second reflective layer is expressed by Δλ=Δn×P using the refractive index anisotropy An and the helical pitch P of a liquid crystal compound to be used (for example, a liquid crystal compound having a polymerizable group). Therefore, in order to obtain a wide bandwidth Δλ, it is preferable to use a liquid crystal compound exhibiting a high Δn. Specifically, Δn at 30° C. of the liquid crystal compound is preferably 0.25 or more, more preferably 0.3 or more, and still more preferably 0.35 or more. The upper limit thereof is not particularly limited and is often 0.6 or less in many cases.

As a method for measuring the refractive index anisotropy Δn, a method using a wedge-shaped liquid crystal cell described in the Liquid Crystal Handbook (edited by Liquid Crystal Handbook Editing Committee, published by Maruzen Co., Ltd.), page 202 is generally used. In the case of a compound which is liable to crystallize, it is also possible to estimate the refractive index anisotropy An from the extrapolated value after evaluation was conducted by using a mixture with other liquid crystal compounds.

Examples of liquid crystal compounds exhibiting a high An include those disclosed in U.S. Pat. No. 6,514,578B, JP3999400B, JP4117832B, JP4517416B, JP4836335B, JP5411770B, JP5411771B, JP5510321B, JP5705465B, JP5721484B, JP5723641B, and the like.

Another suitable aspect of the liquid crystal compound having a polymerizable group may be, for example, a compound represented by General Formula (5).

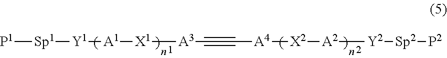

A¹ to A⁴ each independently represent an aromatic carbocyclic ring or heterocyclic ring which may have a substituent. Examples of the aromatic carbocyclic ring include a benzene ring and a naphthalene ring. Examples of the heterocyclic ring include a furan ring, a thiophene ring, a pyrrole ring, a pyrroline ring, a pyrrolidine ring, an oxazole ring, an isoxazole ring, a thiazole ring, an isothiazole ring, an imidazole ring, an imidazoline ring, an imidazolidine ring, a pyrazole ring, a pyrazoline ring, a pyrazolidine ring, a triazole ring, a furazan ring, a tetrazole ring, a pyran ring, a thiine ring, a pyridine ring, a piperidine ring, an oxazine ring, a morpholine ring, a thiazine ring, a pyridazine ring, a pyrimidine ring, a pyrazine ring, a piperazine ring, and a triazine ring. Among them, A¹ to A⁴ are each preferably an aromatic carbocyclic ring and more preferably a benzene ring.

The type of the substituent which may be substituted on the aromatic carbocyclic ring or the heterocyclic ring is not particularly limited and examples thereof include a halogen atom, a cyano group, a nitro group, an alkyl group, a halogen-substituted alkyl group, an alkoxy group, an alkylthio group, an acyloxy group, an alkoxycarbonyl group, a carbamoyl group, an alkyl-substituted carbamoyl group, and an acylamino group having 2 to 6 carbon atoms.

X¹ and X² each independently represent a single bond, —COO—, —OCO—, —CH₂CH₂—, —OCH₂13 , —CH₂O—, —CH═CH—, —CH═CH—COO—, —OCO—CH═CH—, or —C≡C—. Among them, a single bond, —COO—, or —C≡C— is preferable.

Y¹ and Y² each independently represent a single bond, —O—, —S—, —CO—, —COO—, —OCO—, —CONH—, —NHCO—, —CH═CH—, —CH═CH—COO—, —OCO—CH═CH—, or Among them, —O— is preferable.

Sp¹ and Sp² each independently represent a single bond or a carbon chain having 1 to 25 carbon atoms. The carbon chain may be linear, branched, or cyclic. As the carbon chain, a so-called alkyl group is preferable. Among them, an alkyl group having 1 to 10 carbon atoms is more preferable.

P¹ and P² each independently represent a hydrogen atom or a polymerizable group, and at least one of P¹ or P² represents a polymerizable group. Examples of the polymerizable group include the polymerizable groups contained in the above-mentioned liquid crystal compound having a polymerizable group.

n¹ and n² each independently represent an integer of 0 to 2, and in the case where n¹ or n² is 2, each of a plurality of A^{1,}s, A^{2,}s, X^{1,}s, and X^{2,}s may be the same or different.

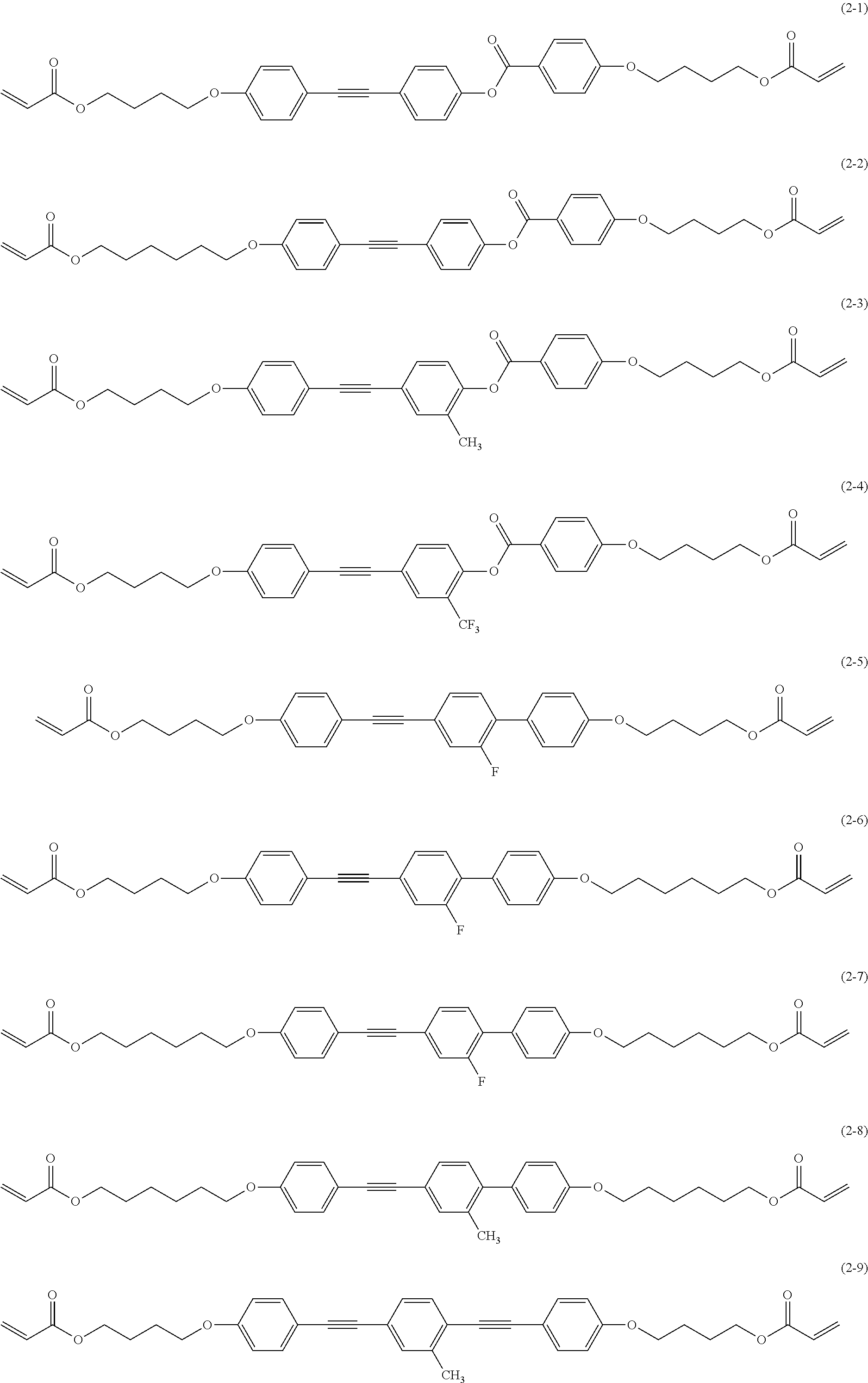

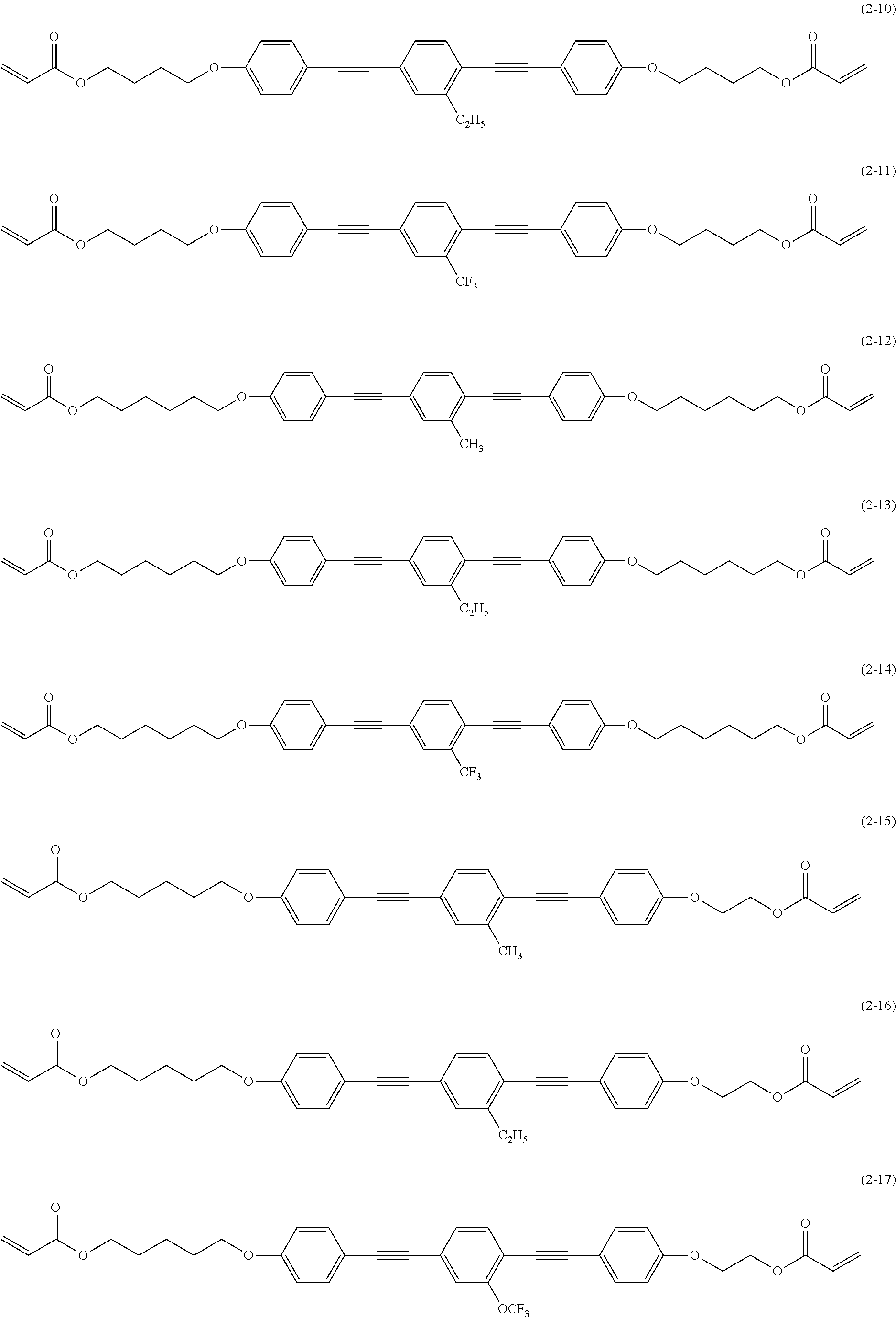

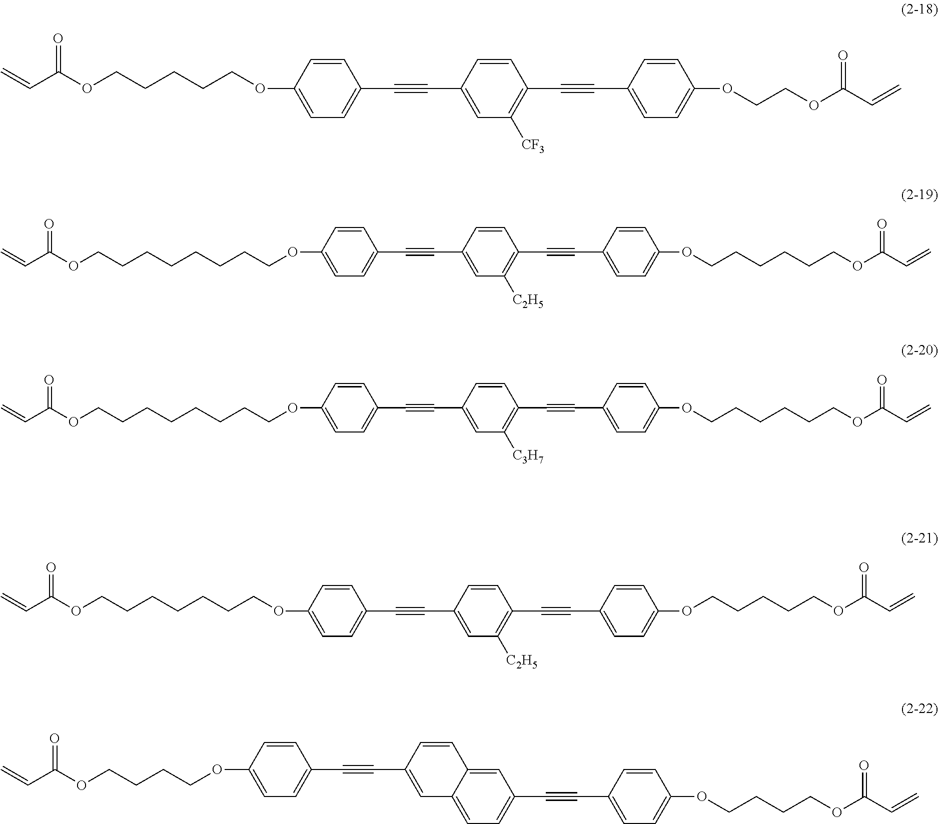

(Chiral Agent (Optically Active Compound))

The liquid crystal composition exhibits a cholesteric liquid crystal phase, for which the composition preferably contains a chiral agent. However, in the case where the rod-like liquid crystal compound is a molecule having an asymmetric carbon atom, there may be a case where the composition can stably form a cholesteric liquid crystal phase even though a chiral agent is not added thereto. The chiral agent may be selected from a variety of known chiral agents (for example, as described in Liquid Crystal Device Handbook, Chap. 3, Item 4-3, Chiral Agents for Twisted Nematic (TN) and Super-Twisted Nematic (STN), p. 199, by the 142^{nd} Committee of the Japan Society for the Promotion of Science, 1989). The chiral agent generally contains an asymmetric carbon atom; however, an axial asymmetric compound or planar asymmetric compound not containing an asymmetric carbon atom may also be used as the chiral agent. Examples of the axial asymmetric compound or the planar asymmetric compound include binaphthyl, helicene, paracyclophane, and derivatives thereof. The chiral agent may have a polymerizable group. In the case where the chiral agent has a polymerizable group and the rod-like liquid crystal compound to be used concurrently also has a polymerizable group, a polymer may be formed through a polymerization reaction of the polymerizable chiral agent and the polymerizable rod-like liquid crystal compound, which has a repeating unit derived from the rod-like liquid crystal compound and a repeating unit derived from the chiral agent. In this aspect, the polymerizable group contained in the polymerizable chiral agent is preferably a group of the same type as that of the polymerizable group contained in the polymerizable rod-like liquid crystal compound. Accordingly, preferably, the polymerizable group of the chiral agent is also an unsaturated polymerizable group, an epoxy group, or an aziridinyl group, more preferably an unsaturated polymerizable group, and still more preferably an ethylenically unsaturated polymerizable group.

Further, the chiral agent may be a liquid crystal compound.

The content of the chiral agent in the liquid crystal composition is preferably 1 to 30 mol % with respect to the liquid crystal compound to be used in combination. The chiral agent is preferably used in a smaller amount, as it generally does not affect the liquid crystallinity. Accordingly, the chiral agent is preferably a compound having a strong twisting power in order that the compound could attain twisting alignment of the desired helical pitch even though its amount used is small. Examples of such a chiral agent having strong twisting power include the chiral agents described in, for example, JP2003-287623A and these chiral agents can be preferably used in the present invention.

Specific examples of the chiral agent include the compounds described in, for example, paragraphs [0055] to [0080] of JP2014-119605A, the contents of which are incorporated herein by reference in its entirety.

As the chiral agent, mainly, a dextrorotatory chiral agent and a levorotatory chiral agent can be mentioned. It is preferable to use a dextrorotatory chiral agent in the case of producing the first reflective layer and a levorotatory chiral agent in the case of producing the second reflective layer.

Here, as the dextrorotatory chiral agents, those having strong twisting power are provided to the market more than levorotatory chiral agents. For example, LC756 (manufactured by BASF Corporation) can be preferably used in the present invention as a dextrorotatory chiral agent having an HTP of 30 μm⁻¹ or more.

In the present invention, it is preferred that the levorotatory chiral agent is represented by General Formula (2), and it is more preferred that the levorotatory chiral agent is represented by General Formula (4).

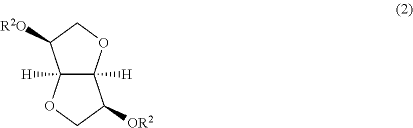

In General Formula (2), R² represents any one of substituents shown below, and the two R^{2,}s may be the same as or different from each other.

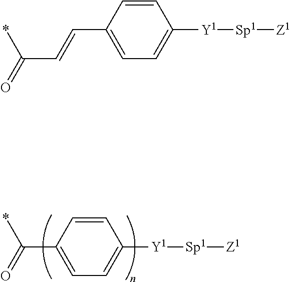

Meanwhile, *'s each represent a bonding site to an oxygen atom in General Formula (2).

Y^{1,}s each independently represent a single bond, —O—, —C(═O)O—, —OC(═O)—, or —OC(═O)O—, preferably a single bond, —O—, or —OC(═O)—, and more preferably —O—.

Sp^{1,}s each independently preferably represent a single bond or an alkylene group having 1 to 8 carbon atoms, more preferably an alkylene group having 1 to 5 carbon atoms, and still more preferably an alkylene group having 2 to 4 carbon atoms.

Z^{1,}s each independently represent a hydrogen atom or a (meth)acryl group and more preferably a hydrogen atom.

n represents an integer of 1 or more and is preferably 1 to 3, more preferably 1 or 2, and still more preferably 1.

The chiral agent represented by General Formula (2) is more preferably a chiral agent represented by General Formula (4).

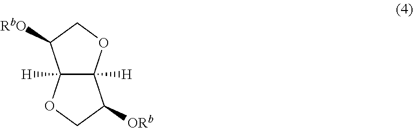

In General Formula (4), R^{b} represents a substituent shown below, and the two R^{b,}s may be the same as or different from each other, and they are preferably the same.

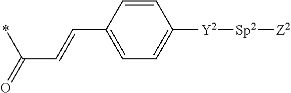

In the above substituent, * represents a bonding site to an oxygen atom in General Formula (4). Y² represents a single bond, —O—, or —OC(═O)— and preferably —O—.

Sp² represents a single bond or an alkylene group having 1 to 8 carbon atoms, preferably an alkylene group having 1 to 8 carbon atoms, more preferably an alkylene group having 1 to 5 carbon atoms, and still more preferably an alkylene group having 2 to 4 carbon atoms.

Z² represents a hydrogen atom or a (meth)acryl group and preferably a hydrogen atom.

An optical isomer of a chiral agent represented by General Formula (2) or (4) may be used as the dextrorotatory chiral agent.

The chiral agent may be, for example, a compound shown below.

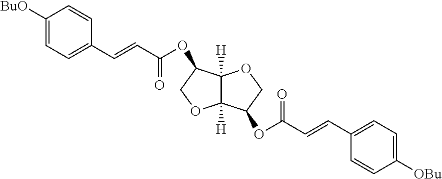

(Polymerization Initiator)

The liquid crystal composition used for forming each reflective layer is preferably a polymerizable liquid crystal composition, for which, therefore, the composition preferably contains a polymerization initiator. In the present invention, it is preferable to allow a curing reaction to proceed by ultraviolet irradiation, and the polymerization initiator to be used is preferably a photopolymerization initiator capable of initiating a polymerization reaction upon irradiation with ultraviolet rays. Examples of the photopolymerization initiator include α-carbonyl compounds (as described in U.S. Pat. No. 2,367,661A and U.S. Pat. No. 2,367,670A), acyloin ethers (as described in U.S. Pat. No. 2,448,828A), a-hydrocarbon-substituted aromatic acyloin compounds (as described in U.S. Pat. No. 2,722,512A), polynuclear quinone compounds (as described in U.S. Pat. No. 3,046,127A and U.S. Pat. No. 2,951,758A), combinations of triarylimidazole dimer and p-aminophenyl ketone (as described in U.S. Pat. No. 3,549,367A), acridine and phenazine compounds (as described in JP1985-105667A (JP-S60-105667A) and U.S. Pat. No. 4,239,850A), oxadiazole compounds (as described in U.S. Pat. No. 4,212,970A), and the like

The amount of the polymerization initiator to be used is preferably 0.1 to 20 mass % and more preferably 1 to 8 mass % of the liquid crystal composition (or the solid content in the case of a coating liquid).

A photopolymerization initiator which may be contained in an infrared light absorbing composition to be described later may be used as the foregoing polymerization initiator.

(Alignment Control Agent)

The liquid crystal composition may contain an alignment control agent that contributes to stably or rapidly forming a cholesteric liquid crystal phase. Examples of the alignment control agent include fluorine-containing (meth)acrylate-based polymers. The composition may contain two or more selected from these compounds. These compounds can reduce the tilt angle of the molecules of the liquid crystal compound at the air interface of the layer, or align the molecules substantially horizontally. In the present specification, the term “horizontal alignment” refers to that the long axis of the liquid crystal molecule is parallel to the film surface, but does not require strict parallelism. In the present specification, the “horizontal alignment” means an alignment in which the tilt angle to the horizontal plane is less than 20 degrees. In the case where the liquid crystal compound is aligned horizontally in the vicinity of the air interface, alignment defects hardly occur, and therefore the transparency in a visible light region is increased and the reflectivity in an infrared region is increased.

Examples of the fluorine-containing (meth)acrylate-based polymers usable as the alignment control agent are described in paragraphs [0018] to [0043] of JP2007-272185A, and the like

Specific examples of the alignment control agent include the compounds described in paragraphs [0081] to [0090] of JP2014-119605A, the contents of which are incorporated herein by reference in its entirety.

The alignment control agent may be, for example, a fluorine-based alignment control agent, which is preferably, for example, a compound represented by General Formula (I).

(Hb¹¹-Sp¹¹-L¹¹-Sp¹²-L¹²)ₘ₁₁A¹¹L¹³-T¹¹-L¹⁴-A¹²-(L¹⁵-Sp¹³-L¹⁶-Sp¹⁴-Hb¹¹)ₐ₁₁ General Formula )I)

In General Formula (I), L¹¹, L¹², L¹³, L¹⁴, L¹⁵, and L¹⁶ each independently represent a single bond, —O—, —S—, —CO—, —COO—, —OCO—, —COS—, —SCO—, —NRCO—, or —CONR— (R in General Formula (I) represents a hydrogen atom or an alkyl group having 1 to 6 carbon atoms). Incidentally, —NRCO— and —CONR— have an effect of reducing solubility. Further, more preferred is —O—, —S—, —CO—, —COO—, —OCO—, —COS—, or —SCO— from the viewpoint that there is a tendency for a haze value to increase at the time of film formation, and more preferred is —O—, —CO—, —COO—, or —OCO— from the viewpoint of stability of the compound.

Sp¹¹, Sp¹², Sp¹³, and Sp¹⁴ each independently represent a single bond or an alkylene group having 1 to 10 carbon atoms, more preferably a single bond or an alkylene group having 1 to 7 carbon atoms, and still more preferably a single bond or an alkylene group having 1 to 4 carbon atoms, provided that the hydrogen atom of the alkylene group may be substituted by a fluorine atom. The alkylene group may be branched or unbranched and is preferably a linear alkylene group having no branching. From the viewpoint of synthesis, it is preferred that Sp¹¹ and Sp¹⁴ are the same and Sp¹² and Sp¹³ are the same.

A¹¹ and A¹² are each a divalent to pentavalent aromatic hydrocarbon. The number of carbon atoms in the aromatic hydrocarbon group is preferably 6 to 22, more preferably 6 to 14, still more preferably 6 to 10, and particularly preferably 6.

Hb¹¹ represents a perfluoroalkyl group having 2 to 30 carbon atoms, more preferably a perfluoroalkyl group having 3 to 20 carbon atoms, and still more preferably a perfluoroalkyl group having 3 to 10 carbon atoms. The perfluoroalkyl group may be linear, branched, or cyclic, preferably linear or branched, and more preferably linear.

m1 1 and n11 are each independently an integer of 0 to 5, and m11+n11≥1. In this case, a plurality of structures present in parentheses may be the same as or different from each other, and are preferably the same as each other. m11 and n11 in General Formula (I) are determined by the valences of A¹¹ and A¹².

T¹¹ represents a divalent group or divalent aromatic heterocyclic group represented by

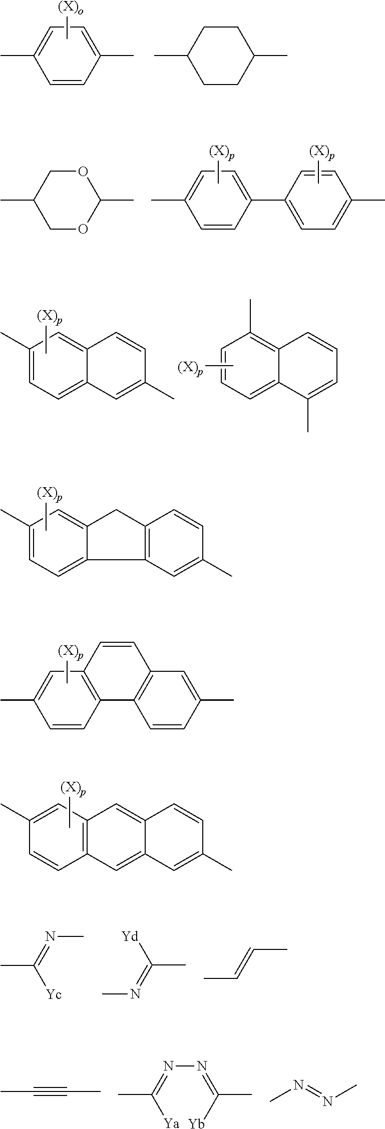

(X contained in the T¹¹ is an alkyl group having 1 to 8 carbon atoms, an alkoxy group having 1 to 8 carbon atoms, a halogen atom, a cyano group, or an ester group, and Ya, Yb, Yc, and Yd each independently represent a hydrogen atom or an alkyl group having 1 to 4 carbon atoms).

o and p contained in the T¹¹ are each independently an integer of 0 or more, and in the case where o and p are 2 or more, a plurality of X's may be the same as or different from each other. o contained in the is preferably 1 or 2. p contained in the T¹¹ is preferably an integer of 1 to 4 and more preferably 1 or 2.

The following compounds are exemplified as the alignment control agent.

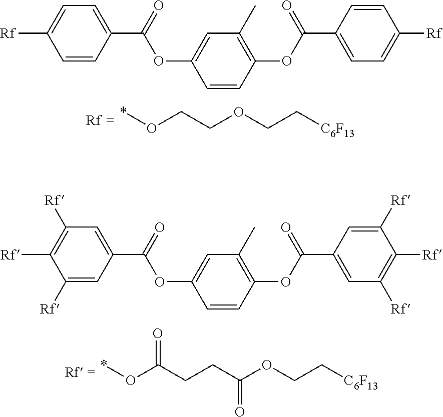

(Method for Producing Laminate)

The method for producing a laminate is not particularly limited, and a method using the above-mentioned liquid crystal composition may be preferably exemplified. More specifically, an example of the production method is a production method including at least

(1) a step of applying a curable liquid crystal composition onto the surface of a predetermined substrate or the like to bring the composition into a state of a cholesteric liquid crystal phase, and

(2) a step of irradiating the curable liquid crystal composition with ultraviolet rays to proceed a curing reaction, and immobilizing the cholesteric liquid crystal phase to form a reflective layer.

A laminate having the same constitution as that shown in FIG. 1 can be produced by repeating the steps (1) and (2) eight times on one surface of the substrate while changing the type of the liquid crystal composition.

The direction of rotation of the cholesteric liquid crystal phase can be adjusted depending on the type of the liquid crystal used or the type of the chiral agent added, and the helical pitch (that is, central reflection wavelength) can be arbitrarily adjusted depending on the concentration of these materials.

In the case of forming the first reflective layer, it is preferable to use a liquid crystal composition containing at least a liquid crystal compound and a dextrorotatory chiral agent. In the case of forming the second reflective layer, it is preferable to use a liquid crystal composition containing at least a liquid crystal compound and a levorotatory chiral agent.

In the step (1), first, a curable liquid crystal composition is applied onto the surface of a predetermined substrate. The curable liquid crystal composition is preferably prepared as a coating liquid in which materials are dissolved and/or dispersed in a solvent. The coating liquid can be applied by various methods such as a wire bar coating method, an extrusion coating method, a direct gravure coating method, a reverse gravure coating method, and a die coating method.

Next, the curable liquid crystal composition coated on the surface and turned into a coating film is brought into a state of a cholesteric liquid crystal phase. In an aspect in which the curable liquid crystal composition is prepared as a coating liquid containing a solvent, there are cases where the liquid crystal composition can be brought into a state of a cholesteric liquid crystal phase by drying the coating film to remove the solvent. Further, in order to obtain the transition temperature to the cholesteric liquid crystal phase, the coating film may be heated as desired. For example, the liquid crystal composition can be stably brought into a state of a cholesteric liquid crystal phase by once heating to a temperature of an isotropic phase and then cooling to a cholesteric liquid crystal phase transition temperature. The liquid crystal phase transition temperature of the curable liquid crystal composition is preferably in the range of 10° C. to 250° C. and more preferably in the range of 10° C. to 150° C. from the viewpoint of production suitability and the like.

Next, in the step (2), the coating film in the state of a cholesteric liquid crystal phase is irradiated with ultraviolet rays to proceed a curing reaction. For irradiation with ultraviolet rays, a light source such as an ultraviolet lamp is used. In this step, the curing reaction of the liquid crystal composition proceeds upon irradiation with ultraviolet rays, and the cholesteric liquid crystal phase is immobilized to form a reflective layer.

In order to accelerate the curing reaction, ultraviolet irradiation may be carried out under heating conditions. In addition, the temperature at the time of irradiation with ultraviolet rays is preferably kept within a temperature range that exhibits a cholesteric liquid crystal phase so that the cholesteric liquid crystal phase is not disturbed.

In the above step, the cholesteric liquid crystal phase is immobilized and therefore a reflective layer is formed. Here, as the state where the liquid crystal phase is “immobilized”, the most typical and preferred aspect is a state in which the alignment of the liquid crystal compound brought into a cholesteric liquid crystal phase is retained. The state where the liquid crystal phase is “immobilized” is not limited thereto, and specifically, it refers to a state in which, in a temperature range of usually 0° C. to 50° C. and in a temperature range of −30° C. to 70° C. under more severe conditions, this layer has no fluidity and can keep an immobilized alignment state stably without causing changes in alignment state due to external field or external force. In the present invention, it is preferable to immobilize the alignment state of a cholesteric liquid crystal phase by a curing reaction proceeding upon irradiation with ultraviolet rays.

In the present invention, it is sufficient if the optical properties of the cholesteric liquid crystal phase are retained in the layer, and finally the liquid crystal composition in the reflective layer no longer needs to show liquid crystallinity. For example, the liquid crystal composition may have a high molecular weight due to a curing reaction and therefore may no longer have liquid crystallinity.

The order of production of the first reflective layer and the second reflective layer is not particularly limited, and either one may be produced first (in random order).

As described above, in order to produce a laminate, a kit including a composition for forming a first reflective layer (a liquid crystal composition containing at least a liquid crystal compound and a dextrorotatory chiral agent) and a composition for forming a second reflective layer (a liquid crystal composition containing at least a liquid crystal compound and a levorotatory chiral agent) can also be used.

Further, the laminate 10 may include layers other than the above-mentioned first reflective layers 12a to 12d and second reflective layers 14a to 14d.

As will be described later in detail, examples of other layers include a substrate (preferably a transparent substrate) such as a glass substrate or a resin substrate, an adhesive layer, an adhesion layer, an undercoat layer, a hard coat layer, an antireflection layer, an infrared light absorbing layer, and a visible light absorbing layer.

### Second Embodiment

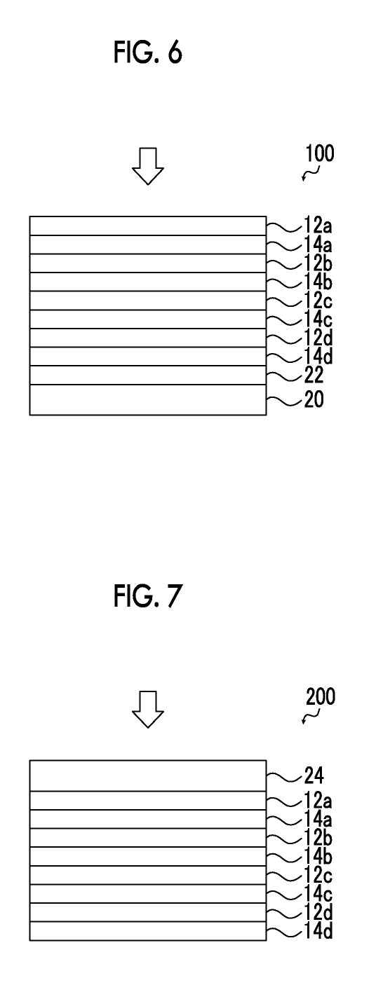

FIG. 6 shows a cross-sectional view of a second embodiment of the laminate of the present invention.

As shown in FIG. 6, a laminate 100 includes a substrate 20, an underlayer 22, first reflective layers 12a to 12d, and second reflective layers 14a to 14d.

The laminate 100 of the second embodiment has the same members as the laminate 10 of the above-mentioned first embodiment except that the substrate 20 and the underlayer 22 are included. The same members are denoted by the same reference numerals and the description thereof will be omitted. Hereinafter, aspects of the substrate 20 and the underlayer 22 will be mainly described in detail.

(Substrate)

The substrate 20 is a base material for supporting the underlayer 22 to be described later and each reflective layer.

The type of the substrate 20 is not particularly limited, and a known substrate can be used. For example, a transparent substrate such as a glass substrate or a resin substrate can be suitably used.

(Underlayer)

The underlayer 22 is disposed adjacent to the reflective layer. By disposing the underlayer 22 adjacent to the reflective layer, the alignment of the liquid crystal compound contained in the reflective layer is more controlled, and the transmission characteristics of the laminate are more preferable.

The underlayer 22 has a function of more precisely defining the alignment direction of the liquid crystal compound in the liquid crystal phase (in particular, the cholesteric liquid crystal phase) in the first reflective layer and the second reflective layer.

As a material used as the underlayer 22, a polymer of an organic compound (organic polymer) is preferable. A polymer which is crosslinkable itself or a polymer which can be crosslinked by a crosslinking agent is often used. Naturally, a polymer having both functions is also used.

Examples of the polymer include polymers such as polymethyl methacrylate, acrylic acid/methacrylic acid copolymer, styrene/maleinimide copolymer, polyvinyl alcohol and modified polyvinyl alcohol, poly(N-methylolacrylamide), styrene/vinyltoluene copolymer, chlorosulfonated polyethylene, nitrocellulose, polyvinyl chloride, chlorinated polyolefin, polyester, polyimide, vinyl acetate/vinyl chloride copolymer, ethylene/vinyl acetate copolymer, carboxymethyl cellulose, gelatin, polyethylene, polypropylene, and polycarbonate, and compounds such as silane coupling agents.

The thickness of the underlayer 22 is preferably 0.1 to 2.0 μm.

As the underlayer 22, an alignment layer subjected to a rubbing treatment (for example, an alignment layer containing polyvinyl alcohol) can be used. A photo-alignment layer can also be used as the underlayer.

As a suitable aspect of the polymer, it is preferable to have a polymerizable group.

As another suitable aspect of the polymer, it is preferable to have a cyclic hydrocarbon group. The cyclic hydrocarbon group may be a non-aromatic cyclic hydrocarbon group or an aromatic cyclic hydrocarbon group.

### Third Embodiment

FIG. 7 shows a cross-sectional view of a third embodiment of the laminate of the present invention.

As shown in FIG. 7, a laminate 200 includes an antireflection layer 24, first reflective layers 12a to 12d, and second reflective layers 14a to 14d.

The laminate 200 of the third embodiment has the same members as the laminate 10 of the above-mentioned first embodiment except that the antireflection layer 24 is included. The same members are denoted by the same reference numerals and the description thereof will be omitted. Hereinafter, the aspect of the antireflection layer 24 will be mainly described in detail.

(Antireflection Layer)

The antireflection layer 24 is disposed on the outermost layer side of the laminate and reduces the light reflected on the surface of the laminate. By disposing the antireflection layer, the amount of light passing through the laminate can be increased.

The refractive index of the antireflection layer 24 is not particularly limited and is preferably 1.45 or less, more preferably 1.35 or less, still more preferably 1.30 or less, and even still more preferably 1.25 or less, from the viewpoint that an antireflection function is excellent. The lower limit thereof is not particularly limited and is usually 1.00 or more in many cases, and more cases are 1.20 or more. The above refractive index is intended to be a refractive index at a wavelength of 633 nm as described below.

The refractive index of the antireflection layer 24 is measured using an ellipsometer (VUV-vase [trade name] manufactured by J.A. Woollam Co.) (wavelength: 633 nm, and measurement temperature: 25° C.).

The material constituting the antireflection layer 24 is not particularly limited and may be an organic material or an inorganic material. An inorganic material (for example, an inorganic resin (siloxane resin) or inorganic particles) is preferable from the viewpoint of durability. In particular, the antireflection layer 24 preferably contains inorganic particles.

The siloxane resin can be obtained through a hydrolysis reaction and a condensation reaction using a known alkoxysilane raw material.

As for the hydrolysis reaction and the condensation reaction, known methods can be used. If necessary, a catalyst such as an acid or a base may be used. The catalyst is not particularly limited as long as it changes a pH. Examples of the acid (organic acid and inorganic acid) include nitric acid, oxalic acid, acetic acid, formic acid, and hydrochloric acid. Examples of the base include ammonia, triethylamine, and ethylenediamine.

If necessary, a solvent may be added to the reaction system of the hydrolysis reaction and the condensation reaction. The solvent is not particularly limited as long as the hydrolysis reaction and condensation reaction can be carried out therewith, and examples thereof include water; alcohols such as methanol, ethanol, and propanol; ethers such as ethylene glycol monomethyl ether, ethylene glycol monoethyl ether, and ethylene glycol monopropyl ether; esters such as methyl acetate, ethyl acetate, butyl acetate, and propylene glycol monomethyl ether acetate; and ketones such as acetone, methyl ethyl ketone, methyl isobutyl ketone, and methyl isoamyl ketone.

As for the conditions (temperature, time, and amount of solvent) of the hydrolysis reaction and the condensation reaction, the optimum conditions are appropriately selected depending on the type of the material to be used.

The weight-average molecular weight of the siloxane resin is preferably 1,000 to 50,000, more preferably 2,000 to 45,000, still more preferably 2,500 to 25,000, and particularly preferably 3,000 to 25,000. In the case where the weight-average molecular weight is equal to or more than the above-specified lower limit value, the coatability to the substrate is particularly satisfactory and the surface state and flatness after coating are favorably maintained, which is therefore preferable.

The weight-average molecular weight is a value measured by using a known gel permeation chromatography (GPC) and converted into standard polystyrene. Unless otherwise specified, the GPC measurement is carried out as follows. WATERS 2695 and Shodex GPC column KF-805L (3 columns in tandem) are used as columns. To the column having a column temperature of 40° C., 50 μl of a tetrahydrofuran solution having a sample concentration of 0.5 mass % is poured. Tetrahydrofuran as an elution solvent is flowed at a flow rate of 1 mL per minute. A sample peak is detected using a refractive index (RI) detector (Waters 2414) and an ultraviolet (UV) detector (Waters 2996).

Examples of the material constituting the inorganic particles include silica (silicon oxide), lanthanum fluoride, calcium fluoride, magnesium fluoride, and cerium fluoride. As the inorganic particles, more specifically, silica particles, hollow silica particles, porous silica particles, and the like are preferable. The hollow particles are of a structure having a cavity inside and refer to particles having cavities enclosed in the shell. The porous particles refer to porous particles with multiple cavities.

The inorganic particles may be used alone or in combination of two or more thereof.

The particle diameter of the inorganic particles is not particularly limited, and the average particle diameter of the inorganic particles is preferably 1 nm or more and more preferably 10 nm or more from the viewpoint of handleability. The upper limit thereof is preferably 200 nm or less and more preferably 100 nm or less.

Here, the average particle diameter of the inorganic particles can be determined from the photograph obtained by observing the inorganic particles under a transmission electron microscope. The projected area of the inorganic particles is determined, from which the circle equivalent diameter is determined and taken as the average particle diameter. The average particle diameter in the present specification can be determined in such a manner that the projected area is measured for 300 or more inorganic particles, the circle equivalent diameter is determined, and the number average diameter is calculated.

The content of the inorganic particles in the antireflection layer 24 is not particularly limited, but it is often 70 mass % or more in many cases. From the viewpoint that the transmittance of the laminate in the visible light region is further increased and the solvent resistance of the laminate is excellent, the content of the inorganic particles is preferably 80 mass % or more, more preferably 90 mass % or more, and still more preferably 95 mass % or more. The upper limit thereof is not particularly limited and may be, for example, 100 mass %.

The refractive index of the inorganic particles is preferably 1.00 to 1.45, more preferably 1.10 to 1.40, still more preferably 1.15 to 1.35, and particularly preferably 1.15 to 1.30 from the viewpoint of further increasing the transmittance of the laminate in the visible light region.

In the present specification, the refractive index of inorganic particles can be measured by the following method. Mixed solution samples of a matrix resin and inorganic particles having a solid content concentration of 10% with the content of the inorganic particles being adjusted to 0 mass %, 20 mass %, 30 mass %, 40 mass %, and 50 mass % are prepared. Each sample is applied to a thickness of 0.3 to 1.0 μm onto a silicon wafer using a spin coater. This is followed by heating and drying on a hot plate at 200° C. for 5 minutes to obtain a coating film. Next, the refractive index at a wavelength of 633 nm (25° C.) is determined using, for example, an ellipsometer (VUV-vase [trade name] manufactured by J.A. Woollam Co.), followed by extrapolation of the value of 100 mass % of the inorganic particles.

The average thickness of the antireflection layer 24 is not particularly limited and is preferably 0.01 to 1.00 μm and more preferably 0.05 to 0.5 μm from the viewpoint of further increasing the transmittance of the laminate in the visible light region.

The average thickness is determined by measuring the thicknesses of arbitrary 10 or more points of the antireflection layer 24 and arithmetically averaging them.

If necessary, components other than the above-mentioned inorganic particles may be contained in the antireflection layer 24. For example, a so-called binder (particularly, a low refractive index binder) such as fluororesin or polysiloxane may be contained in the antireflection layer 24.

In FIG. 7, the antireflection layer 24 has a single layer structure, but may have a multilayer structure if necessary.

(Method for Producing Antireflection Layer)

The method for producing the antireflection layer 24 is not particularly limited, and examples thereof include a dry method (for example, a sputtering method or a vacuum evaporation method) and a wet method (for example, a coating method), among which a wet method is preferable from the viewpoint of productivity.

As the wet method, for example, a method of applying an antireflection layer-forming composition containing an inorganic material (preferably inorganic particles) onto a predetermined substrate and subjecting the applied composition to a drying treatment as necessary to produce an antireflection layer can be preferably mentioned.

The content of the inorganic particles in the antireflection layer-forming composition is not particularly limited and it is preferably 10 to 50 mass %, more preferably 15 to 40 mass %, and still more preferably 15 to 30 mass %.

In addition, the antireflection layer-forming composition contains a solvent (water or an organic solvent) as appropriate.

Examples of the application method include a spin coating method, a dip coating method, a roller blade method, and a spray method.

The method of drying treatment is not particularly limited, and examples thereof include heat treatment and air drying treatment, among which heat treatment is preferable. The conditions for the heat treatment are not particularly limited. The heating temperature is preferably 50° C. or higher, more preferably 65° C. or higher, and still more preferably 70° C. or higher. The upper limit of the heating temperature is preferably 200° C. or lower, more preferably 150° C. or lower, and still more preferably 120° C. or lower. The heating time is not particularly limited, and it is preferably 0.5 minutes or more and 60 minutes or less, and more preferably 1 minute or more and 10 minutes or less.

The method of heat treatment is not particularly limited, and the heat treatment can be carried out by a hot plate, an oven, a furnace, or the like.

The atmosphere during the heat treatment is not particularly limited, and an inert atmosphere, an oxidizing atmosphere, or the like can be applied. The inert atmosphere can be realized by an inert gas such as nitrogen, helium, or argon. The oxidizing atmosphere can be realized by a mixed gas of these inert gas and oxidizing gas, and air can also be used. Examples of the oxidizing gas include oxygen, carbon monoxide, and oxygen dinitride. The heating step can be carried out under any of pressurization, normal pressure, reduced pressure, and vacuum.

(Suitable Aspect)

As a suitable aspect of the antireflection layer 24, a layer formed using a particle aggregate in which a plurality of silica particles are connected in a chain (hereinafter, also referred to as beaded silica) can be mentioned from the viewpoint that the transmittance of the laminate in the visible light region is further increased and the solvent resistance of the laminate is excellent. More specifically, it is more preferable to use a composition (sol) in which beaded silica is dispersed in a solvent.

In general, as silica particles contained in the silica sol, spherical, needle-like or plate-like silica particles other than beaded silica particles are widely known. In the present embodiment, it is preferable to use a composition in which beaded silica particles are dispersed (silica sol). By using this beaded silica, pores are easily formed in the antireflection layer to be formed, and therefore the refractive index can be lowered.

The beaded silica is preferably one in which a plurality of silica particles having an average particle diameter of 5 to 50 nm (preferably 5 to 30 nm) are bonded by metal oxide-containing silica.

In addition, it is preferred for the beaded silica that the ratio D₁/D₂ of a number average particle diameter (D₁ nm) of the silica particles measured by a dynamic light scattering method to an average particle diameter (D₂ nm) determined by the equation of D₂=2720/S from a specific surface area Sm²/g of the silica particles measured by a nitrogen adsorption method is 3 or more, D₁ is 30 to 300 nm, and the silica particles are connected only within one plane. D₁/D₂ is preferably 3 to 20 in that particles are difficult to aggregate and an increase in haze of the antireflection layer can be suppressed. D₁ is preferably 35 to 150 nm.

As the metal oxide-containing silica that bonds silica particles, for example, amorphous silica is exemplified. Examples of the solvent in which beaded silica is dispersed are methanol, ethanol, isopropyl alcohol (IPA), ethylene glycol, propylene glycol monomethyl ether, and propylene glycol monomethyl ether acetate, and the concentration of SiO₂ in the solvent is preferably 5 to 40 mass %.

As such a beaded silica-containing composition (silica sol), for example, the silica sol or the like described in JP4328935B or JP2013-253145A can be used.

In addition, as for the method for producing an antireflection layer using the composition containing beaded silica, the above-mentioned wet method can be appropriately employed.

Further, the antireflection layer can also be formed using a commercially available low refractive index material. Examples of commercially available low refractive index materials include OPSTAR-TU series (manufactured by JSR Corporation), low refractive index polysiloxane LS series (manufactured by Toray Industries, Inc.), and fluorine-based resin CYTOP series (manufactured by Asahi Glass Co., Ltd.).

### Fourth Embodiment

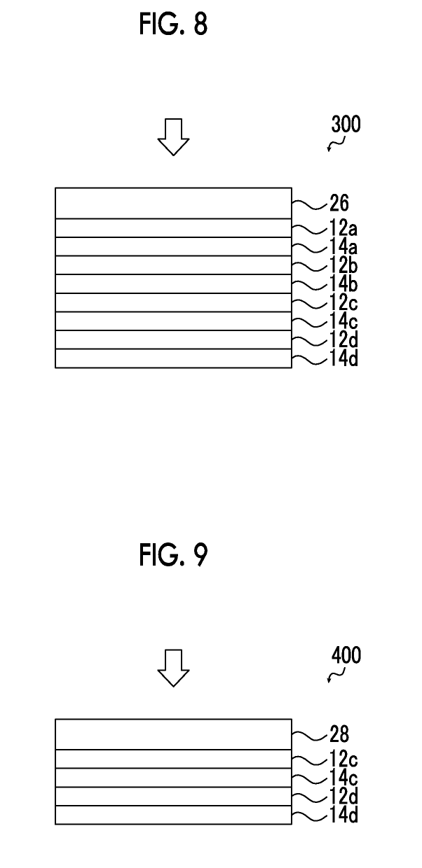

FIG. 8 shows a cross-sectional view of a fourth embodiment of the laminate of the present invention.

As shown in FIG. 8, a laminate 300 includes an infrared light absorbing layer 26, first reflective layers 12a to 12d, and second reflective layers 14a to 14d.

The laminate 300 of the fourth embodiment has the same members as the laminate 10 of the above-mentioned first embodiment except that the infrared light absorbing layer 26 is included. The same members are denoted by the same reference numerals and the description thereof will be omitted. Hereinafter, the aspect of the infrared light absorbing layer 26 will be mainly described below in detail.

(Infrared Light Absorbing Layer)

The infrared light absorbing layer 26 is a layer that absorbs infrared light. By including the infrared light absorbing layer 26, the angular dependence can be reduced. The angular dependence represents the difference between the transmission characteristics of light incident on the laminate from the front direction and the transmission characteristics of light incident on the laminate from the oblique direction. For example, the fact that the angular dependence is large means that the difference between them is large, that is, the difference in transmission characteristics depending on the incident direction of light is large, and the fact that the angular dependence is small means that the difference between them is small, that is, the difference in transmission characteristics depending on the incident direction of light is small.

In FIG. 8, the infrared light absorbing layer 26 is disposed closest to the light incident side, but it is not limited to this aspect. For example, the infrared light absorbing layer 26 may be disposed at a position farthest from the light incident side, or may be disposed between the reflective layers.

The infrared light absorbing layer 26 contains an infrared light absorber. The term “infrared light absorber” means a compound having absorption in the wavelength range in the infrared light region.

As the infrared light absorber, a compound having a maximum absorption wavelength in a wavelength range of 600 to 1,200 nm is preferable. The maximum absorption wavelength can be measured using, for example, a Cary 5000 UV-Vis-NIR (spectrophotometer, manufactured by Agilent Technologies Inc.).

The content of the infrared light absorber in the infrared light absorbing layer 26 is not particularly limited and it is preferably 1 to 80 mass % and more preferably 5 to 60 mass % with respect to the total mass of the infrared light absorbing layer 26.

In the present invention, the infrared light absorber is preferably an organic dye. The term “organic dye” as used herein means a coloring agent made of an organic compound.

The infrared light absorber is preferably at least one selected from a copper compound, a cyanine compound, a pyrrolopyrrole compound, a squarylium compound, a phthalocyanine compound, and a naphthalocyanine compound, and more preferably a copper compound, a cyanine compound, or a pyrrolopyrrole compound.

In the present invention, the infrared light absorber is preferably a compound which dissolves in 1 mass % or more in water at 25° C. and more preferably a compound which dissolves in 10 mass % or more in water at 25° C. Use of such a compound results in improved solvent resistance.

Hereinafter, the copper compound, the cyanine compound, and the pyrrolopyrrole compound, which are suitable aspects of the infrared light absorber, will be described in detail.

<Copper Compound>

The copper compound is preferably a copper compound having a maximum absorption wavelength within a wavelength range of 700 to 1,000 nm (near infrared region).

The copper compound may be a copper complex or may not be a copper complex, and is preferably a copper complex.

In the case where the copper compound used in the present invention is a copper complex, the ligand L coordinating to copper is not particularly limited as long as it is capable of forming a coordinate bond with a copper ion, and examples thereof include compounds having sulfonic acid, phosphoric acid, phosphoric acid ester, phosphonic acid, phosphonic acid ester, phosphinic acid, phosphinic acid ester, carboxylic acid, carbonyl (ester or ketone), amine, amide, sulfonamide, urethane, urea, alcohol, and thiol.

Specifically, as for the phosphorus-containing copper compound, reference can be made to the compounds described on page 5, line 27 to page 7, line 20 of W02005/030898A, the contents of which are incorporated herein by reference in its entirety.

In addition, the copper compound may be a compound represented by General Formula (A).

Cu(L)ₙ₁.(X)ₙ₂ General Formula (A)

In General Formula (A), L represents a ligand coordinating to copper, and X is absent or represents a counter ion as necessary so as to neutralize the charge of a copper complex. n1 and n2 each independently represent an integer of 0 or more.

The ligand L has a substituent containing a C atom, an N atom, an O atom, or an S atom as an atom capable of coordinating to copper, and more preferably has a group having a lone electron pair such as N, O, or S. The preferred ligand L is the same as in the above-mentioned ligand L. The group capable of coordination is not limited to one type in the molecule and may include two or more types, and may be dissociated or may not be dissociated.

Examples of the counter ion include counter ions contained in a copper complex described below, which will be described later in detail.

(Copper Complex)

The copper complex is preferably a compound having a maximum absorption wavelength in the wavelength range of 700 to 1,200 nm. The maximum absorption wavelength of the copper complex is more preferably in the wavelength range of 720 to 1,200 nm and still more preferably in the wavelength range of 800 to 1,100 nm.

The molar extinction coefficient of the copper complex at the maximum absorption wavelength in the above-mentioned wavelength range is preferably 120 (L/mol·cm) or more, more preferably 150 (L/mol·cm) or more, still more preferably 200 (L/mol·cm) or more, even still more preferably 300 (L/mol·cm) or more, and particularly preferably 400 (L/mol·cm) or more. The upper limit thereof is not particularly limited and can be, for example, 30,000 (L/mol·cm) or less. In the case where the molar extinction coefficient of the copper complex is 100 (L/mol·cm) or more, an infrared light absorbing layer having excellent infrared shielding properties can be formed even in the case where it is a thin film.

The gram extinction coefficient at 800 nm of the copper complex is preferably 0.11 (L/g·cm) or more, more preferably 0.15 (L/g·cm) or more, and still more preferably 0.24 (L/g·cm) or more.

In the present invention, the molar extinction coefficient and the gram extinction coefficient of the copper complex can be determined by dissolving the copper complex in a solvent to prepare a solution having a concentration of 1 g/L, and measuring the absorption spectrum of the solution in which the copper complex is dissolved. A UV-1800 (wavelength range: 200 to 1,100 nm, manufactured by Shimadzu Corporation), a Cary 5000 (wavelength range: 200 to 1300 nm, manufactured by Agilent Technologies Inc.), or the like can be used as the measurement apparatus. Examples of the measurement solvent include water, N,N-dimethylformamide, propylene glycol monomethyl ether, 1,2,4-trichlorobenzene, and acetone. In the present invention, among the above-mentioned measurement solvents, one capable of dissolving the copper complex to be measured is selected and used. Among them, in the case of a copper complex soluble in propylene glycol monomethyl ether, it is preferable to use propylene glycol monomethyl ether as the measurement solvent. The term “soluble” means a state in which the solubility of the copper complex in a solvent at 25° C. exceeds 0.01 g/100 g Solvent.

In the present invention, the molar extinction coefficient and the gram extinction coefficient of the copper complex are preferably values measured using any one of the above-mentioned measurement solvents, and more preferably values measured using propylene glycol monomethyl ether.

As a method for setting the molar extinction coefficient of the copper complex to 100 (L/mol·cm) or more, for example, a method using a pentacoordinate copper complex, a method using a ligand having a high π-donating ability, and a method using a copper complex having a low symmetry can be mentioned.

As for a mechanism by which a molar extinction coefficient of 100 (L/mol·cm) or more can be achieved by using a pentacoordinate copper complex, the following is presumed. That is, symmetry of the complex is lowered by taking a pentadentate configuration, preferably a pentacoordinate three-way bipyramidal structure or a pentacoordinate quadrangular pyramidal structure. This makes the p orbital more likely to mix in the d orbital in the interaction between the ligand and copper. At this time, the d-d transition (absorption in the infrared region) is not a pure d-d transition, and the contribution of the p-d transition which is an allowable transition is mixed. As a result, it is considered that the molar extinction coefficient is improved and therefore it is possible to achieve 100 (L/mol·cm) or more.

The pentacoordinate copper complex can be prepared, for example, by reacting two bidentate ligands (which may be the same or different) and one monodentate ligand with a copper ion, reacting one tridentate ligand and two bidentate ligands (which may be the same or different) with a copper ion, reacting one tridentate ligand and one bidentate ligand with a copper ion, reacting one tetradentate ligand and one monodentate ligand with a copper ion, or reacting one pentadentate ligand with a copper ion. At this time, a monodentate ligand coordinating with an unshared electron pair may be used as a reaction solvent. For example, in the case where two bidentate ligands are reacted with copper ions in a solvent containing water, a pentacoordinate complex in which the two bidentate ligands and water as a monodentate ligand are coordinated is obtained.

In addition, as for a mechanism by which a molar extinction coefficient of 100 (L/mol.cm) or more can be achieved by using a ligand having a high a-donating ability, the following is presumed. That is, by using a ligand having a high a-donating ability (a ligand in which π orbital or p orbital of the ligand is shallow energetically), the p orbital of the metal and the p orbital (or π orbital) of the ligand are likely to mix. At this time, the d-d transition is not a pure d-d transition, and the contribution of the Ligand to Metal Charge Transfer (LMCT) transition which is an allowable transition is mixed. As a result, it is considered that the extinction coefficient is improved and therefore it is possible to achieve 100 (L/mol·cm) or more.

Examples of the ligand having a high a-donating ability include a halogen ligand, an oxygen anion ligand, and a sulfur anion ligand. As the copper complex using a ligand having a high a-donating ability, for example, a copper complex having a Cl ligand as a monodentate ligand can be mentioned.

Further, a copper complex having a low symmetry can be obtained by using a ligand having a low symmetry, or asymmetrically introducing a ligand to a copper ion.

The copper complex preferably has a compound having at least two coordination sites (hereinafter, also referred to as compound (A)) as a ligand. The compound (A) more preferably has at least three coordination sites and still more preferably has 3 to 5 coordination sites. The compound (A) acts as a chelate ligand for the copper component. That is, it is considered that at least two coordination atoms of the compound (A) are chelate-coordinated with copper, whereby the structure of the copper complex is distorted, so that high permeability in the visible light region is obtained and the absorption capacity of the infrared light can be improved, and therefore the color value is also improved. As a result, even in the case where the laminate is used for a long period of time, its characteristics are not impaired, and it is also possible to stably produce a camera module.

The copper complex may have two or more compounds (A). In the case of having two or more compounds (A), the respective compounds (A) may be the same or different.

Examples of the coordination site possessed by the compound (A) include a coordination site coordinating with an anion and a coordination site coordinating with an unshared electron pair.

Examples of the copper complex include a tetracoordinate copper complex, a pentacoordinate copper complex, and a hexacoordinate copper complex, among which a tetracoordinate copper complex or a pentacoordinate copper complex is more preferable and a pentacoordinate copper complex is still more preferable.

Further, it is preferred that the copper complex has a 5-membered ring and/or a 6-membered ring formed by copper and a ligand. Such a copper complex exhibits a stable shape and an excellent complex stability.

The copper in the copper complex for use in the present invention can be obtained, for example, by mixing or reacting the compound (A) with a copper component (copper or a compound containing copper).

The copper component is preferably a compound containing divalent copper. Only one type or two or more types of copper components may be used.

For example, copper oxide or a copper salt can be used as the copper component. The copper salt is preferably, for example, copper carboxylate (for example, copper acetate, copper ethylacetoacetate, copper formate, copper benzoate, copper stearate, copper naphthenate, copper citrate, or copper 2-ethylhexanoate), copper sulfonate (for example, copper methanesulfonate), copper phosphate, copper phosphoric acid ester, copper phosphonate, copper phosphonic acid ester, copper phosphinate, amide copper, sulfonamide copper, imide copper, acyl sulfonimide copper, bissulfonimide copper, methide copper, alkoxy copper, phenoxy copper, copper hydroxide, copper carbonate, copper sulfate, copper nitrate, copper perchlorate, copper fluoride, copper chloride, or copper bromide; more preferably copper carboxylate, copper sulfonate, sulfonamide copper, imide copper, acyl sulfonimide copper, bissulfonimide copper, alkoxy copper, phenoxy copper, copper hydroxide, copper carbonate, copper fluoride, copper chloride, copper sulfate, or copper nitrate; still more preferably copper carboxylate, acylsulfonimide copper, phenoxy copper, copper chloride, copper sulfate, or copper nitrate; and particularly preferably copper carboxylate, acylsulfonimide copper, copper chloride, or copper sulfate.

The amount of the copper component to be reacted with the compound (A) is preferably 1:0.5 to 1:8 and more preferably 1:0.5 to 1:4 in terms of molar ratio (compound (A):copper component).

The reaction conditions for reacting the copper component with the compound (A) are preferably, for example, 20° C. to 100° C. for 0.5 hours or more.

The copper complex used in the present invention may have a ligand other than the compound (A). The ligand other than the compound (A) may be, for example, a monodentate ligand coordinating with an anion or an unshared electron pair.

The type and number of the monodentate ligand can be appropriately selected depending on the compound (A) coordinating to the copper complex.

Specific examples of the monodentate ligand used as a ligand other than the compound (A) include, but are not limited to, the following ligands. In the following, Ph represents a phenyl group and Me represents a methyl group.

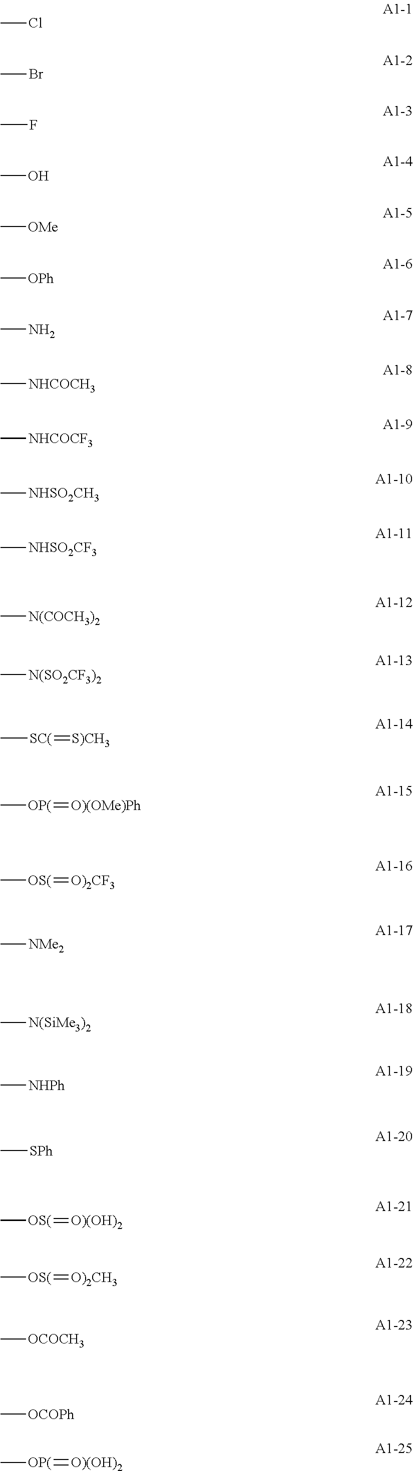

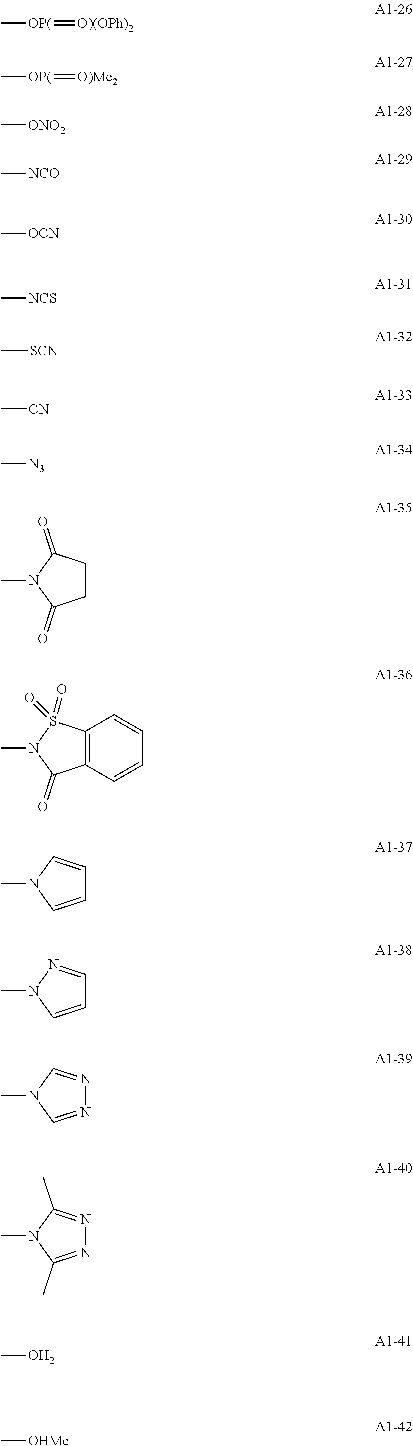

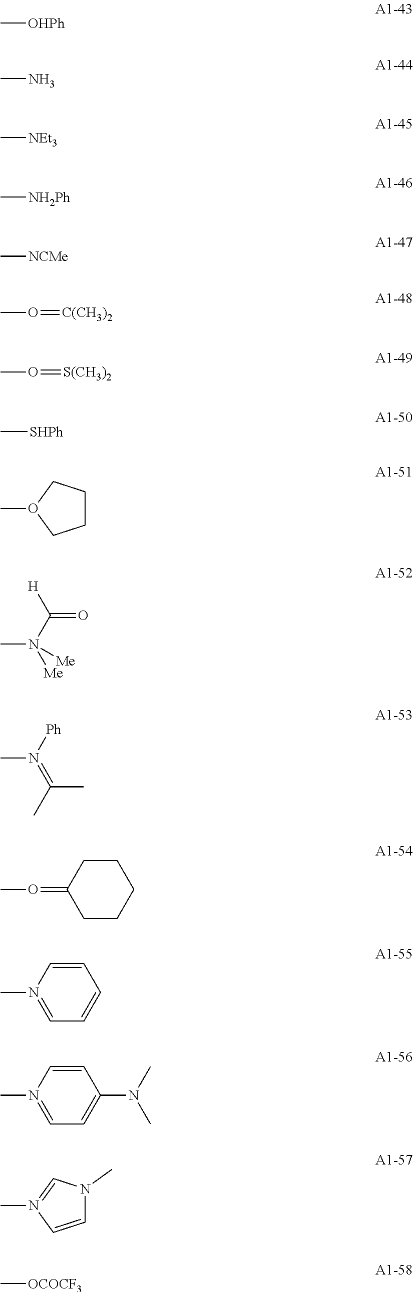

In the case where the compound (A) forming a ligand has a coordination site coordinating with an anion, the copper complex may become a cationic complex or an anionic complex in addition to a neutral complex having no charge depending on the number of coordination sites coordinating with an anion. In this case, a counter ion is present as necessary so as to neutralize the charge of the copper complex.

In the case where the counter ion is a negative counter ion, it may be, for example, an inorganic anion or an organic anion. Specific examples thereof include a hydroxide ion, a halogen anion (for example, a fluoride ion, a chloride ion, a bromide ion, or an iodide ion), a substituted or unsubstituted alkylcarboxylate ion (an acetate ion, a trifluoroacetate ion, or the like), a substituted or unsubstituted arylcarboxylate ion (a benzoate ion or the like), a substituted or unsubstituted alkylsulfonate ion (a methanesulfonate ion, a trifluoromethanesulfonate ion, or the like), a substituted or unsubstituted arylsulfonate ion (for example, a p-toluenesulfonate ion or a p-chlorobenzenesulfonate ion), an aryldisulfonate ion (for example, a 1,3-benzenedisulfonate ion, 1,5-naphthalenedisulfonate ion, or 2,6-naphthalenedisulfonate ion), an alkylsulfate ion (for example, a methylsulfate ion), a sulfate ion, a thiocyanate ion, a nitrate ion, a perchlorate ion, a tetrafluoroborate ion, a tetraarylborate ion, a hexafluorophosphate ion, a picrate ion, an amide ion (including an amide substituted with an acyl group or a sulfonyl group), and a methide ion (including a methide substituted with an acyl group or a sulfonyl group). Among them, a halogen anion, a substituted or unsubstituted alkylcarboxylate ion, a sulfate ion, a nitrate ion, a tetrafluoroborate ion, a tetraarylborate ion, a hexafluorophosphate ion, an amide ion (including an amide substituted with an acyl group or a sulfonyl group), or a methide ion (including a methide substituted with an acyl group or a sulfonyl group) is preferable.

In the case where the counter ion is a positive counter ion, examples thereof include an inorganic or organic ammonium ion (for example, a tetraalkylammonium ion such as a tetrabutylammonium ion, a triethylbenzylammonium ion, or a pyridinium ion), a phosphonium ion (for example, a tetraalkylphosphonium ion such as a tetrabutylphosphonium ion, an alkyltriphenylphosphonium ion, or a triethylphenylphosphonium ion), and an alkali metal ion or a proton.

Further, the counter ion may be a metal complex ion, and in particular, the counter ion may be a salt of a copper complex, that is, a cationic copper complex and an anionic copper complex.

As for copper complexes, for example, the following aspects (1) to (5) are preferable examples, among which aspects (2) to (5) are more preferable, aspects (3) to (5) are still more preferable, and aspect (4) is particularly preferable.

(1) a copper complex having one or two compounds having two coordination sites as a ligand

(2) a copper complex having a compound having three coordination sites as a ligand

(3) a copper complex having a compound having three coordination sites and a compound having two coordination sites as a ligand

(4) a copper complex having a compound having four coordination sites as a ligand

(5) a copper complex having a compound having five coordination sites as a ligand

Specific examples of the copper complex include, for example, the following.

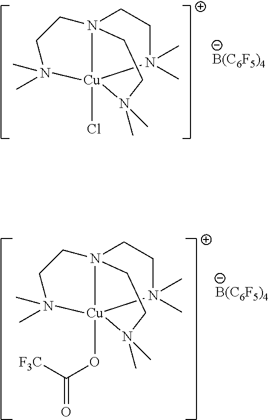

The copper complex may be supported on a polymer.

(Pyrrolopyrrole compound: compound represented by General Formula 1)

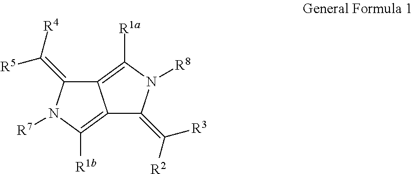

In General Formula 1, R^{1a} and R^{1b} each independently represent an alkyl group, an aryl group, or a heteroaryl group,

R² to R⁵ each independently represent a hydrogen atom or a sub stituent, and R² and R³, and R⁴ and R⁵ may be bonded to each other to form a ring,

R⁶ and R⁷ each independently represent a hydrogen atom, an alkyl group, an aryl group, a heteroaryl group, —BR^{A}R^{B}, or a metal atom, and R^{A} and R^{B} each independently represent a hydrogen atom or a substituent, and

R⁶ may be covalently bonded or coordinately bonded to R^{1a} or R³ and R⁷ may be covalently bonded or coordinately bound to R^{1b} or R⁵.

In General Formula 1, R^{1a} and R^{1b} each independently represent an alkyl group, an aryl group, or a heteroaryl group, preferably an aryl group or a heteroaryl group, and more preferably an aryl group.

The number of carbon atoms in the alkyl group represented by R^{1a} and R^{1b} is preferably 1 to 40, more preferably 1 to 30, and still more preferably 1 to 25. The alkyl group may be linear, branched, or cyclic, preferably linear or branched, and more preferably branched.

The number of carbon atoms in the aryl group represented by R^{1a} and R^{1b} is preferably 6 to 30, more preferably 6 to 20, and still more preferably 6 to 12. The aryl group is preferably a phenyl group.

The heteroaryl group represented by R^{1a} and R^{1b} is preferably a monocyclic ring or a fused ring, more preferably a monocyclic ring or a fused ring having a condensation number of 2 to 8, and still more preferably a monocyclic ring or a fused ring having a condensation number of 2 to 4. The number of hetero atoms constituting the ring of the heteroaryl group is preferably 1 to 3. The hetero atom constituting the ring of the heteroaryl group is preferably a nitrogen atom, an oxygen atom, or a sulfur atom. The number of carbon atoms constituting the heteroaryl group is preferably 3 to 30, more preferably 3 to 18, still more preferably 3 to 12, and particularly preferably 3 to 10. The heteroaryl group is preferably a 5-membered ring or a 6-membered ring.

The above-mentioned aryl group and heteroaryl group may have a substituent and may be unsubstituted. From the viewpoint that the solubility in a solvent can be improved, it is preferable to have a substituent.

The substituent which the aryl group and the heteroaryl group may have is preferably a group having a branched alkyl structure. According to this aspect, the solvent solubility is further improved. Further, the substituent is preferably a hydrocarbon group which may contain an oxygen atom, and more preferably a hydrocarbon group containing an oxygen atom. The hydrocarbon group containing an oxygen atom is preferably a group represented by —O—R^{x1}. R^{x1} is preferably an alkyl group or an alkenyl group, more preferably an alkyl group, and particularly preferably a branched alkyl group. That is, the substituent is more preferably an alkoxy group, and still more preferably a branched alkoxy group. In the case where the substituent is an alkoxy group, it is possible to obtain an infrared light absorber having excellent heat resistance and light fastness. In the case where the substituent is a branched alkoxy group, the solvent solubility is satisfactory.

The number of carbon atoms in the alkoxy group is preferably 1 to 40. The lower limit thereof is more preferably 3 or more, still more preferably 5 or more, even still more preferably 8 or more, and particularly preferably 10 or more. The upper limit thereof is more preferably 35 or less and still more preferably 30 or less. The alkoxy group may be linear, branched, or cyclic, preferably linear or branched, and more preferably branched. The number of carbon atoms in the branched alkoxy group is preferably 3 to 40. The lower limit thereof is, for example, more preferably 5 or more, still more preferably 8 or more, and even still more preferably 10 or more. The upper limit thereof is more preferably 35 or less and still more preferably 30 or less. The number of branching in the branched alkoxy group is preferably 2 to 10 and more preferably 2 to 8.

R² to R⁵ each independently represent a hydrogen atom or a substituent. Examples of the sub stituent include an alkyl group, an alkenyl group, an alkynyl group, an aryl group, a heteroaryl group, an amino group (including an alkylamino group, an arylamino group, and a heterocyclic amino group), an alkoxy group, an aryloxy group, a heteroaryloxy group, an acyl group, an alkylcarbonyl group, an arylcarbonyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a heteroarylthio group, an alkylsulfonyl group, an arylsulfonyl group, a sulfinyl group, a ureido group, a phosphoric acid amide group, a hydroxy group, a mercapto group, a halogen atom, a cyano group, a sulfo group, a carboxyl group, a nitro group, a hydroxamic acid group, a sulfino group, a hydrazino group, an imino group, and a silyl group.

It is preferred that one of R² and R³ and one of R⁴ and R⁵ are an electron withdrawing group.

A substituent having a positive Hammett's ap value (sigma para value) functions as an electron withdrawing group.

In the present invention, a substituent having a Hammett's ap value of 0.2 or more can be exemplified as an electron withdrawing group. The ap value is preferably 0.25 or more, more preferably 0.3 or more, and still more preferably 0.35 or more. The upper limit thereof is not particularly limited, and is preferably 0.80.

Specific examples of the electron withdrawing group include a cyano group (0.66), a carboxyl group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), and an arylsulfonyl group (—SO₂Ph: 0.68). The electron withdrawing group is preferably a cyano group. Here, Me represents a methyl group and Ph represents a phenyl group.

As for the Hammett's σp value, reference can be made to, for example, paragraphs [0024] and [0025] of JP2009-263614A, the contents of which are incorporated herein by reference in its entirety.

One of R² and R³ and one of R⁴ and R⁵ are preferably a heteroaryl group.

In General Formula 1, R² and R³, and R⁴ and R⁵ each may be bonded to each other to form a ring. In the case where R² and R³, and R⁴ and R⁵ are bonded to each other to form a ring, it is preferable to form a 5- to 7-membered ring (preferably a 5- or 6-membered ring). The ring to be formed is preferably a merocyanine dye which is used as an acidic nucleus. Specific examples thereof include the structures described in, for example, paragraph [0026] of JP2010-222557A, the contents of which are incorporated herein by reference in its entirety.

R⁶ and R⁷ each independently represent a hydrogen atom, an alkyl group, an aryl group, a heteroaryl group, —BR^{A}R^{B}, or a metal atom, and more preferably —BR^{A}R^{B}.

In the group represented by —BR^{A}R^{B}, R^{A} and R^{B} each independently represent a hydrogen atom or a sub stituent.

As the sub stituent represented by R^{A} and R^{B}, the sub stituents represented by the above-mentioned R² to R⁵ can be mentioned. Among these, a halogen atom, an alkyl group, an alkoxy group, an aryl group, or a heteroaryl group is preferable.

As for the pyrrolopyrrole compound represented by General Formula 1, reference can be made to the compounds D-1 to D-162 described in paragraphs [0049] to [0062] of JP2010-222557A, the contents of which are incorporated herein by reference in its entirety.

As a suitable aspect of the pyrrolopyrrole compound represented by General Formula 1, a pyrrolopyrrole compound represented by General Formula 1-1 can be mentioned.

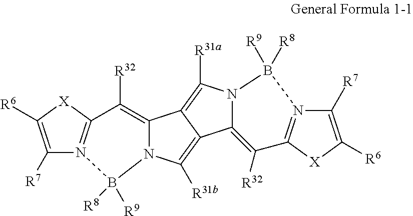

In the formula, R^{31a} and R^{31b} each independently represent an alkyl group having 1 to 20 carbon atoms, an aryl group having 6 to 20 carbon atoms, or a heteroaryl group having 3 to 20 carbon atoms. R³² represents a cyano group, an acyl group having 1 to 6 carbon atoms, an alkoxycarbonyl group having 1 to 6 carbon atoms, an alkyl- or arylsulfinyl group having 1 to 10 carbon atoms, or a nitrogen-containing heteroaryl group having 3 to 10 carbon atoms. R⁶ and R⁷ each independently represent a hydrogen atom, an alkyl group having 1 to 10 carbon atoms, an aryl group having 6 to 10 carbon atoms, or a heteroaryl group having 4 to 10 carbon atoms, and R⁶ and R⁷ may be bonded to each other to form a ring, in which the ring to be formed is an alicyclic ring having 5 to 10 carbon atoms, an aryl ring having 6 to 10 carbon atoms, or a heteroaryl ring having 3 to 10 carbon atoms. R⁸ and R⁹ each independently represent an alkyl group having 1 to 10 carbon atoms, an alkoxy group having 1 to 10 carbon atoms, an aryl group having 6 to 20 carbon atoms, or a heteroaryl group having 3 to 10 carbon atoms. X represents an oxygen atom, a sulfur atom, —NR—, —CRR′—, or —CH═CH—, and R and R′ represent a hydrogen atom, an alkyl group having 1 to 10 carbon atoms, or an aryl group having 6 to 10 carbon atoms.

The following compounds are exemplified as the pyrrolopyrrole compound.

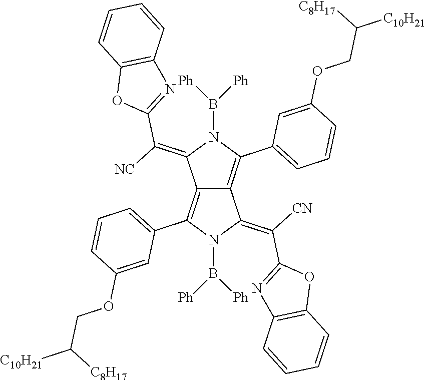

(Cyanine Compound: Compound Represented by General Formula 2); General Formula 2

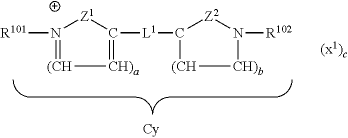

In General Formula 2, Z¹ and Z² are each independently a non-metallic atom group forming a 5- or 6-membered nitrogen-containing heterocyclic ring which may be condensed,

R¹⁰¹ and R¹⁰² each independently represent an alkyl group, an alkenyl group, an alkynyl group, an aralkyl group, or an aryl group,

L¹ represents a methine chain consisting of an odd number of methines,

a and b are each independently 0 or 1,

in the case where a is 0, a carbon atom and a nitrogen atom are bonded by a double bond, and in the case where b is 0, a carbon atom and a nitrogen atom are bonded by a single bond, and

in the case where the moiety represented by Cy in the formula is a cation moiety, X¹ represents an anion and c represents a number necessary for balancing the charge; in the case where the moiety represented by Cy in the formula is an anion moiety, X¹ represents a cation and c represents the number necessary for balancing the charge; and in the case where the charge of the site represented by Cy in the formula is neutralized in the molecule, c is 0.

In General Formula 2, Z¹ and Z² each independently represent a non-metallic atom group forming a 5- or 6-membered nitrogen-containing heterocyclic ring which may be condensed.

In General Formula 2, a and b are each independently 0 or 1. In the case where a is 0, a carbon atom and a nitrogen atom are bonded by a double bond, and in the case where b is 0, a carbon atom and a nitrogen atom are bonded by a single bond. It is preferred that both a and b are 0. In the case where both a and b are 0, General Formula 2 is represented as follows.

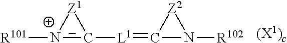

In General Formula 2, in the case where the moiety represented by Cy in the formula is a cation moiety, X¹ represents an anion and c represents the number necessary for balancing the charge. Examples of the anion include a halide ion (Cl⁻, Br⁻, or I⁻), a p-toluenesulfonate ion, an ethylsulfate ion, PF₆⁻, BF₄⁻, C10₄⁻, a tris(halogenoalkylsulfonyl)methide anion (for example, (CF₃SO₂)₃C⁻), a di(halogenoalkylsulfonyl) imide anion (for example, (CF₃SO₂)₂N—), and a tetracyanoborate anion.

In General Formula 2, in the case where the moiety represented by Cy in the formula is an anion moiety, X¹ represents a cation and c represents the number necessary for balancing the charge. Examples of the cation include an alkali metal ion (Li⁺, Na⁺, K⁺, or the like), an alkaline earth metal ion (Mg²⁺, Ca²⁺, Ba²⁺, Sr²⁺, or the like), a transition metal ion (Ag⁺, Fe²⁺, Co²⁺, Ni²⁺, Cu²⁺, Zn²⁺, or the like), other metal ions (Al³⁺ or the like), an ammonium ion, a triethylammonium ion, a tributylammonium ion, a pyridinium ion, a tetrabutylammonium ion, a guanidinium ion, a tetramethylguanidinium ion, and diazabicycloundecenium. The cation is preferably Na⁺, K⁻, Mg²⁺, Ca²⁺, Zn²⁺, or diazabicycloundecenium.

In General Formula 2, in the case where the charge of the site represented by Cy in the formula is neutralized in the molecule, X¹ does not exist. That is, c is 0.

The compound represented by General Formula 2 is also preferably a compound represented by General Formula (3-1) or (3-2). This compound exhibits an excellent heat resistance.

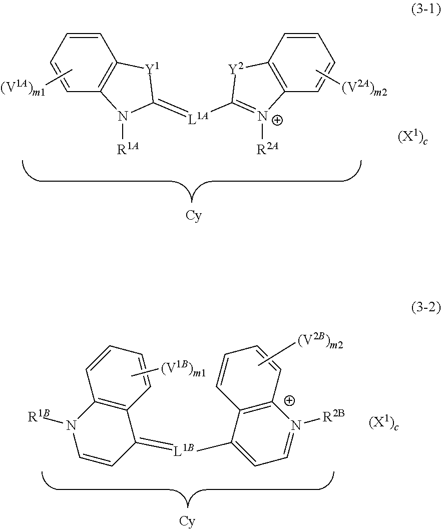

In General Formulae (3-1) and (3-2), R1A, _{R}2A_{, R}IB_{,} and R^{2B} each independently represent an alkyl group, an alkenyl group, an alkynyl group, an aralkyl group, or an aryl group,

L^{1A} and L^{1B} each independently represent a methine chain consisting of an odd number of methine groups,

Y¹ and Y² each independently represent —S—, —O—, —NR^{X1} or —CR^{X2}R^{X3}—,

R^{X1}, R^{X2}, and R^{X3} each independently represent a hydrongen atom or an alkyl group,

V^{1A}, V^{2A}, V^{1B}, and V^{2B} each independently represent a halogen atom, a cyano group, a nitro group, an alkyl group, an alkenyl group, an alkynyl group, an aralkyl group, an aryl group, a heteroaryl group, —OR^{c1}, —COR^{c2}, —COOR^{c3}, —OCOR^{c4}, —NR^{c5}R^{c6} , —NHCOR^{c7}, —CONR^{c8}R^{c9}, —NHCONR^{c10}R^{c11}, —NHCOOR^{c12}, —SR^{c13}, —SO₂R^{c14}, —SO₂OR^{c15}, —NHSO₂R^{c16}, or —SO₂NR^{c17}R^{c18}, and V^{1A}, V^{2A}, V^{1B}, and V^{2B} may form a fused ring,

R^{c1} to R^{c18} each independently represent a hydrogen atom, an alkyl group, an alkenyl group, an alkynyl group, an aryl group, or a heteroaryl group,

in the case where R^{c3} of —COOR^{c3} is a hydrogen atom and in the case where R^{c15} of —SO₂OR^{c15} is a hydrogen atom, the hydrogen atom may be dissociated or may be in a salt state,

m1 and m2 each independently represent an integer of 0 to 4,

in the case where the moiety represented by Cy in the formula is a cation moiety, X¹ represents an anion and c represents the number necessary for balancing the charge,

in the case where the moiety represented by Cy in the formula is an anion moiety, X¹ represents a cation and c represents the number necessary for balancing the charge, and

in the case where the charge of the site represented by Cy in the formula is neutralized in the molecule, X¹ does not exist.

As for the compound represented by General Formula 2, reference can be made to the compounds described in paragraphs [0044] and [0045] of JP2009-108267A, the contents of which are incorporated herein by reference in its entirety.

In addition, specifically, the following compounds are exemplified.

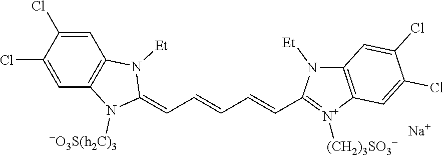

(Squarylium Dye)

In the present invention, the squarylium dye is preferably a compound represented by General Formula (1).

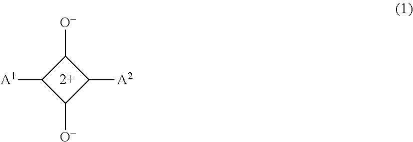

In General Formula (1), A¹ and A² each independently represent an aryl group, a heterocyclic group, or a group represented by General Formula (2).

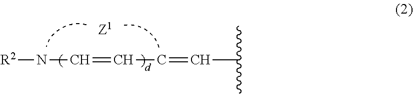

In General Formula (2), Z¹ represents a non-metallic atom group forming a nitrogen-containing heterocyclic ring, R² represents an alkyl group, an alkenyl group, or an aralkyl group, d represents 0 or 1, and a wavy line represents a link to General Formula (1).

A¹ and A² in General Formula (1) each independently represent an aryl group, a heterocyclic group, or a group represented by General Formula (2) and preferably a group represented by General Formula (2).

The number of carbon atoms in the aryl group represented by A¹ and A² is preferably 6 to 48, more preferably 6 to 24, and still more preferably 6 to 12. Specific examples of the aryl group include a phenyl group and a naphthyl group. In the case where the aryl group has a substituent, the number of carbon atoms in the aryl group means a number excluding the number of carbon atoms in the substituent.

The heterocyclic group represented by A¹ and A² is preferably a 5-membered ring or a 6-membered ring. The heterocyclic group is preferably a monocyclic ring or a fused ring, more preferably a monocyclic ring or a fused ring having a condensation number of 2 to 8, still more preferably a monocyclic ring or a fused ring having a condensation number of 2 to 4, and particularly preferably a monocyclic ring or a fused ring having a condensation number of 2 or 3. Examples of the hetero atom contained in the heterocyclic group include a nitrogen atom, an oxygen atom, and a sulfur atom, among which a nitrogen atom or a sulfur atom is preferable. The number of hetero atoms is preferably 1 to 3 and more preferably 1 to 2. Specifically, a heterocyclic group derived from a monocyclic or polycyclic aromatic ring such as a 5-membered ring or 6-membered ring containing at least one of a nitrogen atom, an oxygen atom, or a sulfur atom, and the like can be mentioned.

The aryl group and the heterocyclic group may have a substituent. As the substituent, for example, the following substituent group T can be mentioned.

(Substituent Group T)

The following can be mentioned: a halogen atom, a linear or branched alkyl group, a cycloalkyl group, a linear or branched alkenyl group, a cycloalkenyl group, an alkynyl group, a heteroaryl group, a cyano group, a hydroxyl group, a nitro group, a carboxyl group, an alkoxy group, an aryloxy group, a silyloxy group, a heteroaryloxy group, an acyloxy group, a carbamoyloxy group, an alkoxycarbonyloxy group, an aryloxycarbonyloxy group, an amino group, an acylamino group, an aminocarbonylamino group, an alkoxycarbonylamino group, an aryloxycarbonylamino group, a sulfamoylamino group, an alkyl- or arylsulfonylamino group, a mercapto group, an alkylthio group, a heteroarylthio group, a sulfamoyl group, a sulfo group, an alkyl- or arylsulfinyl group, an alkyl- or arylsulfonyl group, an acyl group, an aryloxycarbonyl group, an alkoxycarbonyl group, a carbamoyl group, an aryl- or heteroarylazo group, an imide group, a phosphino group, a phosphinyl group, a phosphinyloxy group, a phosphinylamino group, and a silyl group.

Next, the group represented by General Formula (2) represented by A¹ and A² will be described.

In General Formula (2), R² represents an alkyl group, an alkenyl group, or an aralkyl group, among which an alkyl group is preferable.

The number of carbon atoms in the alkyl group is preferably 1 to 30, more preferably 1 to 20, still more preferably 1 to 12, and particularly preferably 2 to 8.

The number of carbon atoms in the alkenyl group is preferably 2 to 30, more preferably 2 to 20, and still more preferably 2 to 12.

The alkyl group and the alkenyl group may be linear, branched, or cyclic, and is preferably linear or branched.

The number of carbon atoms in the aralkyl group is preferably 7 to 30 and more preferably 7 to 20.

The group represented by General Formula (2) is preferably a group represented by General Formula (3) or (4).

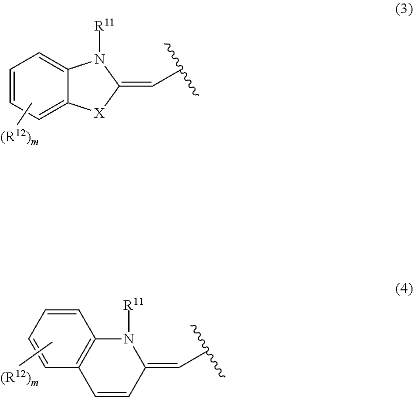

In General Formulae (3) and (4), R¹¹ represents an alkyl group, an alkenyl group, or an aralkyl group, R¹² represents a substituent and in the case where m is 2 or more, R^{12,}s may be bonded to each other to form a ring, X represents a nitrogen atom or CR¹³R¹⁴ in which R¹³ and R¹⁴ each independently represent a hydrogen atom or a substituent, m represents an integer of 0 to 4, and a wavy line represents a link to General Formula (1).

R¹¹ in General Formulae (3) and (4) has the same definition as R² in General Formula (2), and the same will also apply to a preferred range thereof.

R¹² in General Formulae (3) and (4) represents a substituent. Examples of the sub stituent include the groups described for the sub stituent group T described above.

In the case where m is 2 or more, R^{12,}s may be bonded to each other to form a ring. Examples of the ring to be formed include an alicyclic ring (a non-aromatic hydrocarbon ring), an aromatic ring, and a heterocyclic ring. The ring may be monocyclic or polycyclic. In the case where the substituents are bonded to each other to form a ring, the substituents can be bonded by a divalent linking group selected from the group consisting of —CO—, —O—, —NH—, a divalent aliphatic group, a divalent aromatic group, and a combination thereof. For example, it is preferred that R^{12,}s are bonded to each other to form a benzene ring.

X in General Formula (3) represents a nitrogen atom or CR¹³R¹⁴ in which R¹³ and R¹⁴ each independently represent a hydrogen atom or a substituent. Examples of the substituent include the groups described for the substituent group T described above. For example, an alkyl group or the like can be mentioned. The number of carbon atoms in the alkyl group is preferably 1 to 20, more preferably 1 to 10, still more preferably 1 to 5, particularly preferably 1 to 3, and most preferably 1. The alkyl group is preferably linear or branched and particularly preferably linear.

m represents an integer of 0 to 4 and preferably 0 to 2. [0184] In General Formula (1), cations are delocalized and present as follows.

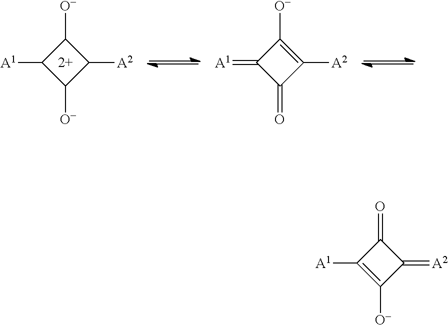

The infrared light absorbing layer 26 may contain components other than the infrared light absorber. With respect to the other components, there may be mentioned components which may be contained in an infrared light absorbing composition to be described later, which will be described later in detail.

(Method for Producing Infrared Light Absorbing Layer 26)

A method for producing the infrared light absorbing layer 26 is not particularly limited. For example, the infrared light absorbing layer 26 can be produced by applying an infrared light absorbing composition containing the above-mentioned infrared light absorber onto a predetermined substrate, followed by drying if necessary.

The infrared light absorbing composition contains the above-mentioned infrared light absorber, and may further contain a binder (for example, resin or gelatin), a polymerizable compound, an initiator, a surfactant, or the like.

Examples of the binder (resin) include a (meth)acrylic resin, a styrene resin, an epoxy resin, an ene thiol resin, a polycarbonate resin, a polyether resin, a polyarylate resin, a polysulfone resin, a polyethersulfone resin, a polyparaphenylene resin, a polyarylene ether phosphine oxide resin, polyimide resin, polyamide imide resin, polyolefin resin, cyclic olefin resin, and polyester resin. These resins may be used alone or in combination of two or more thereof.

The weight-average molecular weight (Mw) of the resin is preferably 2,000 to 2,000,000. The upper limit thereof is more preferably 1,000,000 or less and still more preferably 500,000 or less. The lower limit thereof is more preferably 3,000 or more and still more preferably 5,000 or more.

In the case of an epoxy resin, the weight-average molecular weight (Mw) of the epoxy resin is preferably 100 or more and more preferably 200 to 2,000,000. The upper limit thereof is more preferably 1,000,000 or less and particularly preferably 500,000 or less.

The above-mentioned resin preferably has a 5% thermal mass reduction temperature elevated from 25° C. at 20° C./min of preferably 200° C. or higher and more preferably 260° C. or higher.

Further, a polymer having one type selected from a repeating unit represented by General Formula (MX2-1), a repeating unit represented by General Formula (MX2-2), and a repeating unit represented by General Formula (MX2-3) may also be used as the resin.

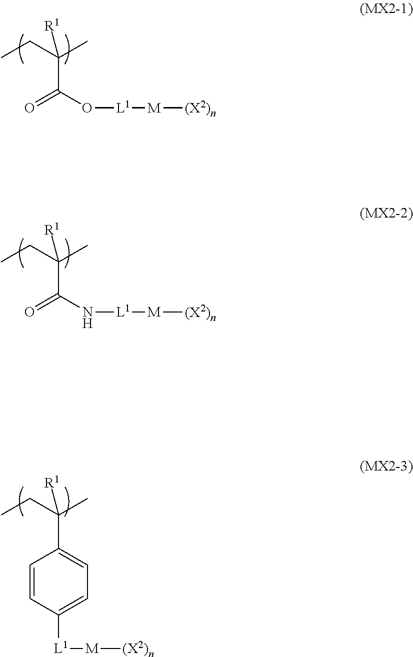

M represents an atom selected from Si, Ti, Zr, and Al, X² represents a substituent or a ligand, at least one of an n number of X^{2,}s is one selected from a hydroxy group, an alkoxy group, an acyloxy group, a phosphoryloxy group, a sulfonyloxy group, an amino group, an oxime group, and O═C(R^{a})(R^{b}), X^{2,}s may be bonded to each other to form a ring, R^{a} and R^{b} each independently represent a monovalent organic group, le represents a hydrogen atom or an alkyl group, L¹ represents a single bond or a divalent linking group, and n represents the number of bonds to X² of M.

M is an atom selected from Si, Ti, Zr, and Al, among which Si, Ti, or Zr is preferable, and Si is more preferable.

X² represents a substituent or a ligand, at least one of an n number of X^{2,}s is one selected from a hydroxy group, an alkoxy group, an acyloxy group, a phosphoryloxy group, a sulfonyloxy group, an amino group, an oxime group, and O═C(R^{a})(R^{b}), and X^{2,}s may be bonded to each other to form a ring.

It is preferred that at least one of an n number of X^{2,}s is one selected from an alkoxy group, an acyloxy group, and an oxime group, it is more preferred that at least one of an n number of X^{2,}s is an alkoxy group, and it is still more preferred that all of X^{2,}s are alkoxy groups. In the case where X² is O═C(R^{a})(R^{b}), it is bonded to M by an unshared electron pair of the oxygen atom of the carbonyl group (—CO—). R^{a} and R^{b} each independently represent a monovalent organic group.

The above-mentioned polymer may contain other repeating units in addition to the repeating units represented by General Formulae (MX2-1), (MX2-2), and (MX2-3).

As for the components constituting other repeating units, reference can be made to the description of polymerization components disclosed in paragraphs [0068] to [0075] of JP2010-106268A (paragraphs <0112> to <0118> of corresponding US2011/0124824A), the contents of which are incorporated herein by reference in its entirety.

Preferred examples of other repeating units include repeating units represented by General Formulae (MX3-1) to (MX3-4).

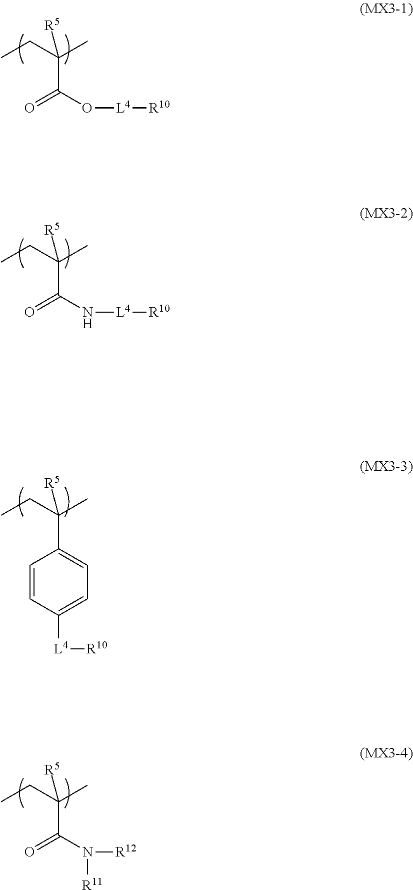

In General Formulae (MX3-1) to (MX3-4), R⁵ represents a hydrogen atom or an alkyl group, L⁴ represents a single bond or a divalent linking group, and It^{m} represents an alkyl group or an aryl group. R¹¹ and R¹² each independently represent a hydrogen atom, an alkyl group, or an aryl group.

R⁵ has the same definition as le of General Formulae (MX2-1) to (MX2-3), and the same will also apply to a preferred range thereof.

L⁴ has the same definition as L¹ of General Formulae (MX2-1) to (MX2-3), and the same will also apply to a preferred range thereof.

The alkyl group represented by R¹⁰ may be linear, branched, or cyclic and preferably cyclic. The number of carbon atoms in the alkyl group is preferably 1 to 30, more preferably 1 to 20, and still more preferably 1 to 10. The alkyl group may have a substituent, and examples of the substituent include those described above.

The aryl group represented by R¹⁰ may be monocyclic or polycyclic, but is preferably monocyclic. The number of carbon atoms in the aryl group is preferably 6 to 18, more preferably 6 to 12, and still more preferably 6.

R¹⁰ is preferably a cyclic alkyl group or an aryl group.

R¹¹ and R¹² each independently represent a hydrogen atom, an alkyl group, or an aryl group. As the alkyl group and the aryl group, the same groups as those for R¹⁰ can be mentioned. An alkyl group is preferred. The alkyl group is preferably linear. The number of carbon atoms in the alkyl group is preferably 1 to 30, more preferably 1 to 20, still more preferably 1 to 10, and particularly preferably 1 to 5.

In the case where the polymer contains other repeating units (preferably repeating units represented by General Formulae (MX3-1) to (MX3-4)), the molar ratio of the sum of the repeating units represented by General Formulae (MX2-1) to (MX2-3) to the sum of the other repeating units is preferably 95:5 to 20:80 and more preferably 90:10 to 30:70. By increasing the content of the repeating units represented by General Formula (MX2-1) to (MX2-3) within the above-specified range, humidity resistance and solvent resistance tend to be further improved. By lowering the content of the repeating units represented by General Formulae (MX2-1) to (MX2-3) within the above-specified range, the heat resistance tends to be further improved.

Specific examples of the above-mentioned polymer include the following.

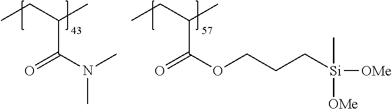

The weight-average molecular weight of the polymer is preferably 500 to 300,000. The lower limit thereof is more preferably 1,000 or more and still more preferably 2,000 or more. The upper limit thereof is more preferably 250,000 or less and still more preferably 200,000 or less.

The (meth)acrylic resin may be, for example, a polymer containing a constitutional unit derived from (meth)acrylic acid and/or an ester thereof. Specific examples thereof include polymers obtained by polymerizing at least one selected from (meth)acrylic acid, (meth)acrylic acid esters, (meth)acrylamide, and (meth)acrylonitrile.

Examples of the polyester resin include polymers obtained by the reaction of a polyol (for example, ethylene glycol, propylene glycol, glycerin, or trimethylolpropane) with a polybasic acid (for example, an aromatic dicarboxylic acid such as terephthalic acid, isophthalic acid, or naphthalenedicarboxylic acid, an aromatic dicarboxylic acid in which the hydrogen atom of the nucleus is substituted with a methyl group, an ethyl group, a phenyl group, or the like, an aliphatic dicarboxylic acid having 2 to 20 carbon atoms such as adipic acid, sebacic acid, or dodecanedicarboxylic acid, or an alicyclic dicarboxylic acid such as cyclohexanedicarboxylic acid), and polymers obtained by ring-opening polymerization of a cyclic ester compound such as a caprolactone monomer (for example, polycaprolactone).

Examples of the epoxy resin include a bisphenol A type epoxy resin, a bisphenol F type epoxy resin, a phenol novolak type epoxy resin, a cresol novolak type epoxy resin, and an aliphatic epoxy resin. Examples of commercially available epoxy resin products include the following.

Examples of the bisphenol A type epoxy resin include JER 827, JER 828, JER 834, JER 1001, JER 1002, JER 1003, JER 1055, JER 1007, JER 1009, and JER 1010 (all manufactured by Japan Epoxy Resins Co., Ltd.), and EPICLON 860, EPICLON 1050, EPICLON 1051, and EPICLON 1055 (all manufactured by DIC Corporation).

Examples of the bisphenol F type epoxy resin include JER 806, JER 807, JER 4004, JER 4005, JER 4007, and JER 4010 (all manufactured by Japan Epoxy Resins Co., Ltd.), EPICLON 830 and EPICLON 835 (both manufactured by DIC Corporation), and LCE-21 and RE-602S (both manufactured by Nippon Kayaku Co., Ltd.).

Examples of the phenol novolak type epoxy resin include JER 152, JER 154, JER 157S70, and JER 157S65 (all manufactured by Japan Epoxy Resins Co., Ltd.), and EPICLONN-740, EPICLONN-740, EPICLONN-770, and EPICLONN-775 (all manufactured by DIC Corporation).

Examples of the cresol novolak type epoxy resin include EPICLONN-660, EPICLONN-665, EPICLONN-670, EPICLONN-673, EPICLONN-680, EPICLONN-690, and EPICLONN-695 (all manufactured by DIC Corporation), and EOCN-1020 (manufactured by Nippon Kayaku Co., Ltd.).

Examples of the aliphatic epoxy resin include ADEKA RESIN EP-4080S, ADEKA RESIN EP-4085S, and ADEKA RESIN EP-4088S (all manufactured by ADEKA Corporation), CELLOXIDE 2021P, CELLOXIDE 2081, CELLOXIDE 2083, CELLOXIDE 2085, EHPE 3150, EPOLEAD PB 3600, and EPOLEAD PB 4700 (all manufactured by Daicel Chemical Industries, Ltd.), and DENACOL EX-212L, EX-214L, EX-216L, EX-321L, and EX-850L (all manufactured by Nagase ChemteX Corporation).

Further examples of commercially available epoxy resin products include ADEKA RESIN EP-4000S, ADEKA RESIN EP-4003S, ADEKA RESIN EP-4010S, and ADEKA RESIN EP-4011S (all manufactured by ADEKA Corporation), NC-2000, NC-3000, NC-7300, XD-1000, EPPN-501, and EPPN-502 (all manufactured by ADEKA Corporation), and JER1031S (manufactured by Japan Epoxy Resins Co., Ltd.).

Further, the resin may have an acid group. Examples of the acid group include a carboxyl group, a phosphate group, a sulfonate group, and a phenolic hydroxyl group. These acid groups may be used alone or in combination of two or more thereof.

The resin having an acid group is preferably a polymer having a carboxyl group in the side chain. Examples thereof include a methacrylic acid copolymer, an acrylic acid copolymer, an itaconic acid copolymer, a crotonic acid copolymer, a maleic acid copolymer, a partially esterified maleic acid copolymer, an alkali soluble phenol resin such as a novolak type resin, an acidic cellulose derivative having a carboxyl group in the side chain, and a polymer obtained from a polymer having a hydroxyl group with addition of an acid anhydride. In particular, (meth)acrylic acid and a copolymer of (meth)acrylic acid and another monomer copolymerizable therewith are suitable. Examples of the monomer copolymerizable with (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyltoluene, glycidyl methacrylate, acrylonitrile, vinyl acetate, N-vinylpyrrolidone, tetrahydrofurfuryl methacrylate, a polystyrene macromonomer, and a polymethyl methacrylate macromonomer. Examples of the N-substituted maleimide monomer described in JP1998-300922A (JP-H10-300922A) include N-phenylmaleimide and N-cyclohexylmaleimide. These monomers copolymerizable with (meth)acrylic acid may be used alone or in combination of two or more thereof.

The resin having an acid group is preferably a benzyl (meth)acrylate/(meth)acrylic acid copolymer, a benzyl (meth)acrylate/(meth)acrylic acid/2-hydroxyethyl (meth)acrylate copolymer, and a multicomponent copolymer made of benzyl (meth)acrylate/(meth)acrylic acid/another monomer are preferred. In addition, a copolymer of 2-hydroxyethyl (meth)acrylate, and a 2-hydroxypropyl (meth)acrylate/polystyrene macromonomer/benzyl methacrylate/methacrylic acid copolymer, a 2-hydroxy-3-phenoxypropyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, a 2-hydroxyethyl methacrylate/polystyrene macromonomer/benzyl methacrylate/methacrylic acid copolymer described in JP1995-140654A (JP-H07-140654A), and the like are also preferred.

As the resin having an acid group, a polymer (a) obtained by polymerizing a monomer component containing a compound represented by General Formula (EDI) and/or a compound represented by General Formula (ED2) (hereinafter, these compounds are sometimes referred to as “ether dimer”) is also preferred.

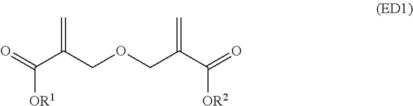

In General Formula (ED1), R¹ and R² each independently represent a hydrogen atom or a hydrocarbon group having 1 to 25 carbon atoms which may have a substituent.

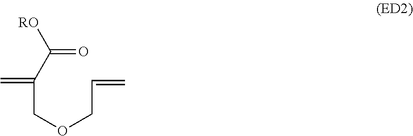

In General Formula (ED2), R represents a hydrogen atom or an organic group having 1 to 30 carbon atoms. As for specific examples of General Formula (ED2), reference can be made to the description of JP2010-168539A.

In General Formula (ED1), the hydrocarbon group having 1 to 25 carbon atoms which may have a substituent, represented by R¹ and R², is not particularly limited. Examples thereof include a linear or branched alkyl group such as a methyl group, an ethyl group, an n-propyl group, an isopropyl group, an n-butyl group, an isobutyl group, a tert-butyl group, a tert-amyl group, a stearyl group, a lauryl group, or a 2-ethylhexyl group; an aryl group such as a phenyl group; an alicyclic group such as a cyclohexyl group, a tert-butylcyclohexyl group, a dicyclopentadienyl group, a tricyclodecanyl group, an isobornyl group, an adamantyl group, or a 2-methyl-2-adamantyl group; an alkyl group substituted by an alkoxy group such as a 1-methoxyethyl group or 1-ethoxyethyl group; and an alkyl group substituted by an aryl group such as a benzyl group. Among them, from the viewpoint of heat resistance, preferred is a primary or secondary carbon substituent which is not likely to leave due to an acid or heat, such as a methyl group, an ethyl group, a cyclohexyl group, or a benzyl group.

As for specific examples of the ether dimer, reference can be made to, for example, paragraph [0317] of JP2013-29760A, the contents of which are incorporated herein by reference in its entirety. The ether dimers may be used alone or in combination of two or more thereof. The structure derived from the compound represented by General Formula (ED) may be subjected to copolymerization with other monomers.

The resin having an acid group may contain a structural unit derived from a compound represented by General Formula (X).

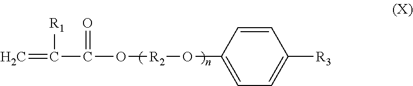

In General Formula (X), R₁ represents a hydrogen atom or a methyl group, R₂ represents an alkylene group having 2 to 10 carbon atoms, R₃ represents a hydrogen atom or an alkyl group having 1 to 20 carbon atoms which may contain a benzene ring, and n represents an integer of 1 to 15.

In General Formula (X), the number of carbon atoms in the alkylene group of R₂ is preferably 2 to 3. The number of carbon atoms in the alkyl group of R₃ is 1 to 20 and preferably 1 to 10, and the alkyl group of R₃ may contain a benzene ring. Examples of the benzene ring-containing alkyl group represented by R₃ include a benzyl group and a 2-phenyl(iso)propyl group.

Specific examples of the resin having an acid group include the following structures.

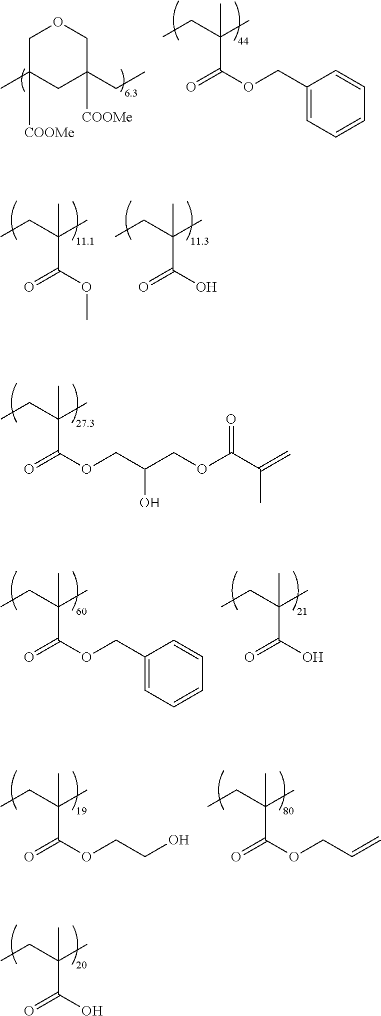

As for the resin having an acid group, reference can be made to the description of paragraphs [0558] to [0571] of JP2012-208494A (paragraphs <0685> to <0700> of corresponding US2012/0235099A) and the description of paragraphs [0076] to [0099] of JP2012-198408A, the contents of both which are incorporated herein by reference in its entirety.

The acid value of the resin having an acid group is preferably 30 to 200 mgKOH/g. The lower limit thereof is more preferably 50 mgKOH/g or more and still more preferably 70 mgKOH/g or more. The upper limit thereof is more preferably 150 mgKOH/g or less and still more preferably 120 mgKOH/g or less.

Further, the resin may have a polymerizable group. In the case where the resin has a polymerizable group, a film having hardness can be formed.

Examples of the polymerizable group include a (meth)allyl group and a (meth)acryloyl group. Examples of the resin containing a polymerizable group include DIANAL NR series (manufactured by Mitsubishi Rayon Co., Ltd.), Photomer 6173 (COOH-containing polyurethane acrylic oligomer, manufactured by Diamond Shamrock Co., Ltd.), VISCOAT R-264 and KS RESIST 106 (both manufactured by Osaka Organic Chemical Industry Co., Ltd.), CYCLOMER P series (for example, ACA 230AA) and PLACCEL CF200 series (both manufactured by Daicel Chemical Industries Ltd.), Ebecryl 3800 (manufactured by Daicel-UCB Co., Ltd.), and ACRYCURE RD-F8 (manufactured by Nippon Shokubai Co., Ltd). Further, the above-mentioned epoxy resins and the like can also be mentioned.

The content of the resin is preferably 15 mass % or more, more preferably 20 mass % or more, and still more preferably 25 mass % or more with respect to the total solid content of the infrared light absorbing composition. The upper limit thereof is preferably 80 mass % or less, more preferably 70 mass % or less, and still more preferably 50 mass % or less.

The infrared light absorbing composition preferably contains at least one selected from a resin, gelatin, and a polymerizable compound, and particularly preferably contains at least one selected from gelatin and a polymerizable compound. According to this aspect, it is easy to produce an infrared light absorbing layer having excellent heat resistance and solvent resistance. In the case where a polymerizable compound is used, it is preferable to use a polymerizable compound and a photopolymerization initiator in combination.

(Gelatin)

The infrared light absorbing composition preferably contains gelatin. Incorporation of gelatin makes it easy to form an infrared light absorbing layer having excellent heat resistance. Although the detailed mechanism for such an effect is unknown, it is presumed that it is because it is easy to form an aggregate with the infrared light absorber and gelatin. In particular, in the case where a cyanine compound is used as the infrared light absorber, it is easy to form an infrared light absorbing layer having excellent heat resistance.

With respect to gelatin, there are acid-treated gelatin and alkali-treated gelatin (lime-treated gelatin or the like) depending on a synthesis method thereof, and any of them can be preferably used. The molecular weight of the gelatin is preferably 10,000 to 1,000,000. Modified gelatin which has been subjected to a modification treatment using an amino group or a carboxyl group of gelatin can also be used (for example, phthalated gelatin). As the gelatin, inert gelatin (for example, NITTA GELATIN 750), phthalated gelatin (for example, NITTA GELATIN 801), or the like can be used.

In order to improve the water resistance and mechanical strength of the infrared light absorbing layer, it is preferable to cure the gelatin using various compounds. Conventionally known curing agents can be used, and examples thereof include aldehyde-based compounds such as formaldehyde and glutaraldehyde; compounds having reactive halogens described in U.S. Pat. No. 3,288,775A and the like; compounds having reactive ethylenically unsaturated bonds described in U.S. Pat. No. 3,642,486A, JP1974-13563B (JP-S49-13563B), and the like; aziridine-based compounds described in U.S. Pat. No. 3,017,280A and the like; epoxy-based compounds described in U.S. Pat. No. 3,091,537A and the like; halogen carboxyl aldehydes such as mucochloric acid; dioxanes such as dihydroxy dioxane and dichlorodioxane; and inorganic hardeners such as chromium alum and zirconium sulfate.

The content of gelatin in the infrared light absorbing composition is preferably 1 to 99 mass % with respect to the total solid content of the infrared light absorbing composition. The lower limit thereof is more preferably 10 mass % or more and still more preferably 20 mass % or more. The upper limit thereof is more preferably 95 mass % or less and still more preferably 90 mass % or less.

(Dispersant)

The infrared light absorbing composition may contain a dispersant as a resin. As will be described in detail later, the visible light absorbing composition may also contain such a dispersant.

Examples of the dispersant include polymer dispersants [for example, a resin having an amine group (polyamide amine and a salt thereof), an oligoimine-based resin, a polycarboxylic acid and a salt thereof, a high molecular weight unsaturated acid ester, a modified polyurethane, a modified polyester, a modified poly(meth)acrylate, a (meth)acrylic copolymer, and a naphthalenesulfonic acid-formalin condensate].

The polymer dispersant may be further classified into a linear polymer, a terminal-modified polymer, a graft-type polymer, and a block-type polymer, on the basis of the structure.

As the polymer dispersant, a resin having an acid value of 60 mgKOH/g or more (more preferably, an acid value of 60 mgKOH/g or more and 300 mgKOH/g or less) is also suitable.

Examples of the terminal-modified polymer having an anchor moiety to the surface include polymers having a phosphate group at the terminal described in JP1991-112992A (JP-H03-112992A) and JP2003-533455A, polymers having a sulfonate group at the terminal described in JP2002-273191A, and polymers having an organic dye partial skeleton or a heterocyclic ring described in JP1997-77994A (JP-H09-77994A). A polymer in which two or more anchor moieties (for example, acid group, basic group, organic dye partial skeleton, or heterocyclic ring) to the pigment surfaces are introduced into the polymer terminal, described in JP2007-277514A is also preferred because of having an excellent dispersion stability.

Examples of the graft-type polymer include reaction products of a poly(lower alkyleneimine) and a polyester described in JP1979-37082A (JP-S54-37082A), JP1996-507960A (JP-H08-507960A), and JP2009-258668A, reaction products of a polyallylamine and a polyester described in JP1997-169821A (JP-H09-169821A), copolymers of a macromonomer and a nitrogen atom-containing monomer described in JP1998-339949A (JP-H10-339949A) and JP2004-37986A, graft-type polymers having an organic dye partial skeleton or a heterocyclic ring described in JP2003-238837A, JP2008-9426A, and JP2008-81732A, and copolymers of a macromonomer and an acid group-containing monomer

A known macromonomer may be used as the macromonomer used in the case of producing a graft-type polymer by radical polymerization, and examples thereof include MACROMONOMER AA-6 (a polymethyl methacrylate with the terminal group being a methacryloyl group), AS-6 (a polystyrene with the terminal group being a methacryloyl group), AN-6S (a copolymer of a styrene and an acrylonitrile with the terminal group being a methacryloyl group), and AB-6 (a polybutyl acrylate with the terminal group being a methacryloyl group), all of which manufactured by Toagosei Co., Ltd.; PLACCEL FM5 (a 5 molar equivalent adduct of c-caprolactone with 2-hydroxyethyl methacrylate) and FA10L (a 10 molar equivalent adduct of c-caprolactone with 2-hydroxyethyl acrylate), both of which manufactured by Daicel Chemical Industries, Ltd.; and a polyester-based macromonomer described in JP1990-272009A (JP-H02-272009A). Among them, in particular, a polyester-based macromonomer having excellent flexibility and excellent solvent affinity is preferable from the viewpoint of the dispersibility of the pigment dispersion, the dispersion stability, and the developability exhibited by the coloring composition using the pigment dispersion, and a polyester-based macromonomer represented by the polyester-based macromonomer described in JP1990-272009A (JP-H02-272009A) is most preferable.

As for the block-type polymer, the block-type polymers described in JP2003-49110A and JP2009-52010A are preferable.

A graft copolymer containing a structural unit represented by any one of General Formulae (1) to (4) can also be used as the resin.

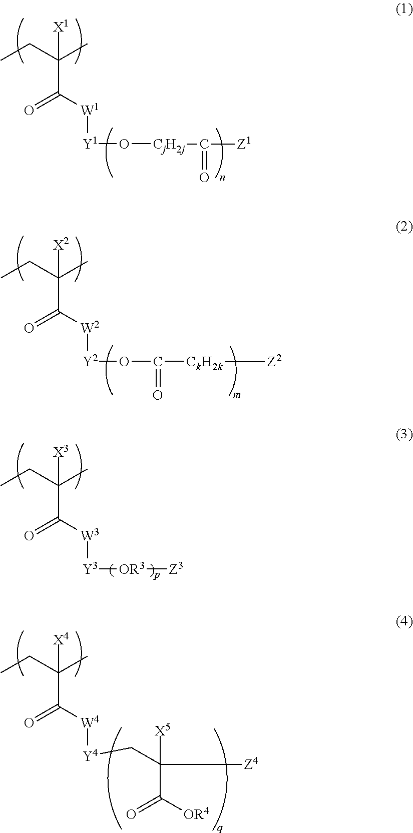

In General Formulae (1) to (4), Z¹, Z², Z³, and Z⁴ each independently represent a monovalent organic group, the structure of which is not particularly limited, and specific examples thereof include an alkyl group, a hydroxyl group, an alkoxy group, an aryloxy group, a heteroaryloxy group, an alkylthioether group, an arylthioether group, a heteroarylthioether group, and an amino group. Among them, the monovalent organic group represented by Z¹, Z², Z³, and Z⁴ preferably has a steric repulsion effect, particularly from the viewpoint of improving dispersibility. The organic groups represented by Z¹ to Z³ are each independently preferably an alkyl group having 5 to 24 carbon atoms or an alkoxy group having 5 to 24 carbon atoms, among which the organic groups represented by Z¹ to Z³ are each independently particularly preferably an alkoxy group having a branched alkyl group having 5 to 24 carbon atoms or an alkoxy group having a cyclic alkyl group having 5 to 24 carbon atoms. The organic groups represented by Z⁴ are each independently preferably an alkyl group having 5 to 24 carbon atoms, among which the organic groups represented by Z⁴ are each independently more preferably a branched alkyl group having 5 to 24 carbon atoms or a cyclic alkyl group having 5 to 24 carbon atoms.

In General Formulae (1) to (4), n, m, p, and q are each an integer of 1 to 500.

In General Formulae (1) and (2), j and k each independently represent an integer of 2 to 8. From the viewpoint of dispersion stability and developability, j and k in General Formulae (1) and (2) are preferably an integer of 4 to 6 and more preferably 5.

X¹, X², X³, X⁴, and X⁵ each independently represent a hydrogen atom or a monovalent organic group. X¹, X², X³, X⁴, and X⁵ are each independently preferably a hydrogen atom or an alkyl group having 1 to 12 carbon atoms, more preferably a hydrogen atom or a methyl group, and still more preferably a methyl group.

W¹, W², W³, and W⁴ each independently represent an oxygen atom or NH, among which an oxygen atom is preferable.

R³ represents a branched or linear alkylene group (preferably having 1 to 10 carbon atoms, more preferably 2 or 3), and from the viewpoint of dispersion stability, a group represented by —CH₂—CH(CH₃)—, or a group represented by —CH(CH₃)—CH₂— is preferable.

Y¹, Y², Y³, and Y⁴ are each independently a divalent linking group, and are not particularly restricted in terms of structure.

As for the graft copolymer, reference can be made to the description of paragraphs [0025] to [0069] of JP2012-255128A, the contents of which are incorporated herein by reference in its entirety.

Specific examples of the graft copolymer include the following compounds. Further, the resins described in paragraphs [0072] to [0094] of JP2012-255128A can be used.

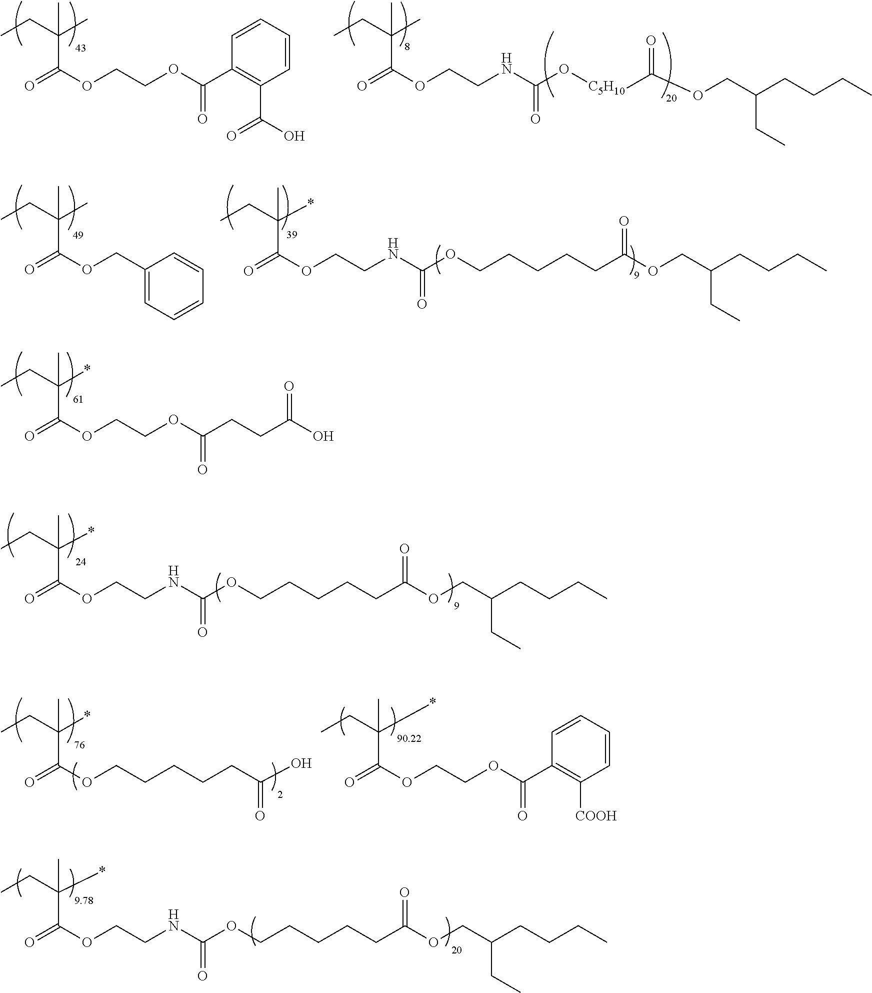

An oligoimine-based dispersant containing a nitrogen atom in at least one of the main chain or the side chain may also be used as the resin. As the oligoimine-based dispersant, preferred is a resin having a structural unit having a partial structure X having a functional group having a pKa of 14 or less and a side chain containing a side chain Y having 40 to 10,000 atoms and having a basic nitrogen atom in at least one of the main chain or the side chain. The basic nitrogen atom is not particularly limited as long as it is a nitrogen atom showing basicity.

The oligoimine-based dispersant may be, for example, a dispersant containing a structural unit represented by General Formula (I-1), a structural unit represented by General Formula (I-2) and/or a structural unit represented by General Formula (I-2a).

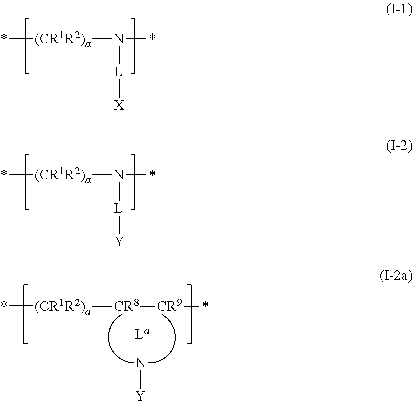

R¹ and R² each independently represent a hydrogen atom, a halogen atom, or an alkyl group (preferably having 1 to 6 carbon atoms). a′s each independently represent an integer of 1 to 5. * represents a connection between structural units.

R⁸ and R⁹ are the same groups as

L represents a single bond, an alkylene group (preferably having 1 to 6 carbon atoms), an alkenylene group (preferably having 2 to 6 carbon atoms), an arylene group (preferably having 6 to 24 carbon atoms), a heteroarylene group (preferably having 1 to 6 carbon atoms), an imino group (preferably having 0 to 6 carbon atoms), an ether group, a thioether group, a carbonyl group, or a linking group formed by combination thereof. Among them, a single bond or —CR⁵R⁶—NR⁷— (the imino group becomes X or Y) is preferable. Here, R⁵ and R⁶ each independently represent a hydrogen atom, a halogen atom, or an alkyl group (preferably having 1 to 6 carbon atoms). R⁷ is a hydrogen atom or an alkyl group having 1 to 6 carbon atoms.

L^{a} is a structural moiety which forms a ring structure together with CR⁸CR⁹ and N atom and is preferably a structural moiety which forms a non-aromatic heterocyclic ring having 3 to 7 carbon atoms taken together with the carbon atom of CR⁸CR⁹. L^{a} is more preferably a structural moiety which forms a 5- to 7-membered non-aromatic heterocyclic ring having 3 to 7 carbon atoms taken together with the carbon atom of CR⁸CR⁹ and the N atom (nitrogen atom), still more preferably a structural moiety which forms a 5-membered non-aromatic heterocyclic ring, and particularly preferably a structural moiety forming pyrrolidine. This structural moiety may further have a substituent such as an alkyl group.

X represents a group having a functional group having a pKa of 14 or less.

Y represents a side chain having 40 to 10,000 atoms.

The dispersant (oligoimine-based dispersant) may further contain, as a copolymerization component, one or more members selected from the structural units represented by General Formulae (I-3), (I-4), and (I-5). In the case where the dispersant contains such a structural unit, the dispersing performance can be further improved.

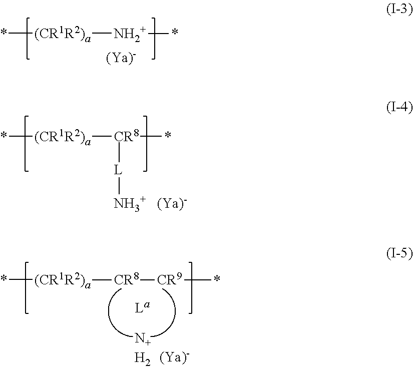

R¹, R², R⁸, R⁹, L, L^{a}, a, and * have the same definition as in General Formulae (I-1), (I-2), and (I-2a).

Ya represents a side chain having 40 to 10,000 atoms and having an anion group. The structural unit represented by General Formula (I-3) can be formed by adding and reacting an oligomer or a polymer having a group capable of reacting with an amine to form a salt, with a resin having a primary or secondary amino group in the main chain portion.

As for the oligoimine-based dispersant, reference can be made to the description of paragraphs [0102] to [0166] of JP2012-255128A, the contents of which are incorporated herein by reference in its entirety.

Specific examples of the oligoimine-based dispersant include the following compounds. In addition, the resins described in paragraphs [0168] to [0174] of JP2012-255128A can be used.

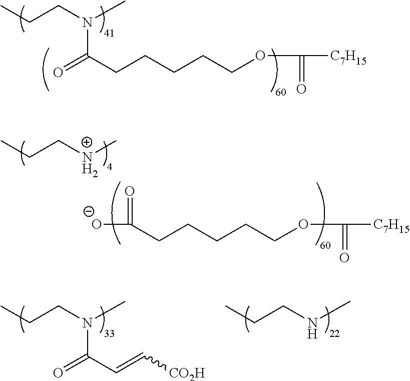

(Polymerizable Compound)

The infrared light absorbing composition preferably contains a polymerizable compound.

As the polymerizable compound, it is preferable to use an addition polymerizable compound having at least one ethylenically unsaturated double bond, and it is more preferable to use a compound having at least one terminal ethylenically unsaturated bond, preferably two or more terminal ethylenically unsaturated bonds. Such compounds are widely known in the art to which the present invention pertains, and these compounds can be used without particular limitation in the present invention.

Radical polymerizable compounds represented by General Formulae (MO-1) to (MO-5) can also be suitably used. In the formulae, in the case where T is an oxyalkylene group, the terminal on the carbon atom side is bonded to R.

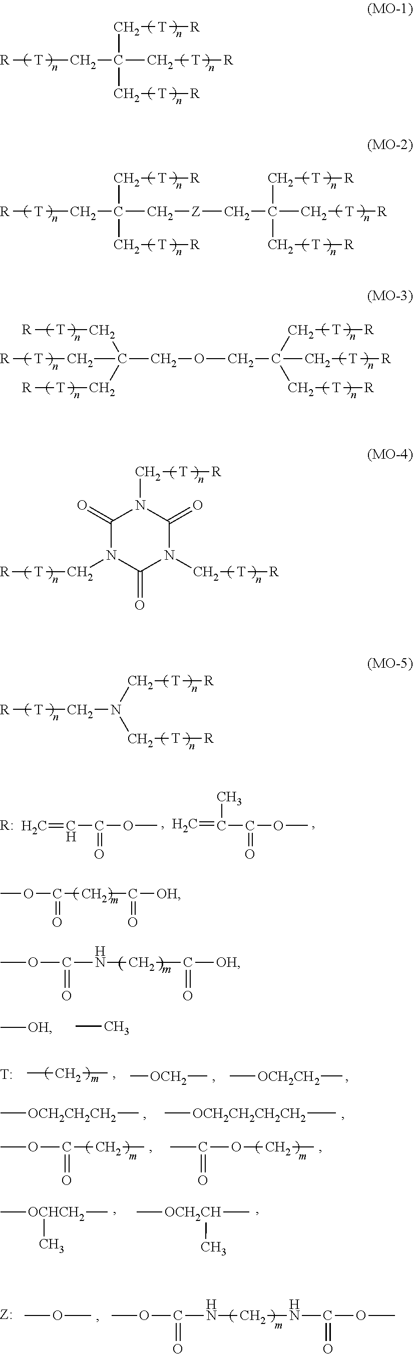

In the general formulae, n is an integer of 0 to 14 and m is an integer of 1 to 8. In the case where a plurality of R's or a plurality of T′s are present in one molecule, the plurality of R′s or the plurality of T's may be the same as or different from each other.

In each of the radical polymerizable compounds represented by General Formulae (MO-1) to (MO-5), at least one of the plurality of R's represents a group represented by —OC(═O)CH═CH₂ or —OC(═O)C(CH₃)═CH₂.

As to specific examples of the radical polymerizable compounds represented by General Formulae (MO-1) to (MO-5), the compounds described in paragraphs [0248] to [0251] of JP2007-269779A may also be suitably used in the present invention.

The compound obtained by adding ethylene oxide or propylene oxide to a polyfunctional alcohol, followed by (meth)acrylation, described together with specific examples of General Formulae (1) and (2) in JP1998-62986A (JP-H10-62986A) can also be used as the polymerizable compound.

Among them, pentaerythritol tetraacrylate (as a commercially available product, A-TMMT, manufactured by Shin-Nakamura Chemical Co., Ltd.), dipentaerythritol triacrylate (as a commercially available product, KAYARAD D-330, manufactured by Nippon Kayaku Co., Ltd.), dipentaerythritol tetraacrylate (as a commercially available product, KAYARAD D-320, manufactured by Nippon Kayaku Co., Ltd.), dipentaerythritol penta(meth)acrylate (as a commercially available product, KAYARAD D-310, manufactured by Nippon Kayaku Co., Ltd.), or dipentaerythritol hexa(meth)acrylate (as a commercially available product, KAYARAD DPHA, manufactured by Nippon Kayaku Co., Ltd.) is preferred as the polymerizable compound. More preferred is pentaerythritol tetraacrylate.

The polymerizable compound may have an acid group such as a carboxyl group, a sulfonate group, or a phosphate group. For example, ethylenically unsaturated compounds having an acid group can be suitably exemplified. The ethylenically unsaturated compounds having an acid group is obtained by a method of (meth)acrylating a part of hydroxyl groups of a polyfunctional alcohol and subjecting the remaining hydroxyl groups to an addition reaction with an acid anhydride to convert into carboxyl groups.

In the case where the ethylenic compound is a mixture as described above, it can be used as it is in the case where it has an unreacted carboxyl group, but, if desired, a non-aromatic carboxylic acid anhydride may be reacted with a hydroxyl group of the ethylenic compound to introduce an acid group. In this case, specific examples of the non-aromatic carboxylic acid anhydride to be used include a tetrahydrophthalic acid anhydride, an alkylated tetrahydrophthalic acid anhydride, a hexahydrophthalic acid anhydride, an alkylated hexahydrophthalic acid anhydride, a succinic acid anhydride, and a maleic acid anhydride.

The monomer having an acid group is an ester of an aliphatic polyhydroxy compound and an unsaturated carboxylic acid, preferably a polyfunctional monomer obtained by reacting a non-aromatic carboxylic acid anhydride with an unreacted hydroxyl group of the aliphatic polyhydroxy compound to introduce an acid group, and more preferably the ester described above where the aliphatic polyhydroxy compound is pentaerythritol and/or dipentaerythritol. The commercially available product thereof includes, for example, polybasic acid-modified acryl oligomers M-510 and M-520 manufactured by Toagosei Co., Ltd.

These polymerizable compounds may be used alone, but may be used in combination of two or more thereof, because it is difficult to use a single compound in production. Further, as the monomer, a polyfunctional monomer having no acid group and a polyfunctional monomer having an acid group may be used in combination, if desired.

The acid value of the polyfunctional monomer having an acid group is preferably 0.1 to 40 mgKOH/g and more preferably 5 to 30 mgKOH/g. In the case where the acid value of the polyfunctional monomer is too low, the development dissolution characteristics deteriorate. In the case where the acid value of the polyfunctional monomer is too high, it becomes difficult to prepare or handle the monomer so that the photopolymerization performance deteriorates, thereby leading to deterioration in the curability such as the surface smoothness of a pixel. Accordingly, in the case where the polyfunctional monomers having different acid groups are used in combination of two or more thereof, or in the case where the polyfunctional monomers having no acid group are used in combination, it is preferred that the acid group as the total polyfunctional monomer is adjusted to fall within the above-specified range.

Also, it is preferred to contain a polyfunctional monomer having a caprolactone structure as the polymerizable compound.

The polyfunctional monomer having a caprolactone structure is not particularly limited as long as it has a caprolactone structure in the molecule thereof, and may be, for example, an ε-caprolactone-modified polyfunctional (meth)acrylate which is obtained by esterification of a polyhydric alcohol, such as trimethylolethane, ditrimethylolethane, trimethylolpropane, ditrimethylolpropane, pentaerythritol, dipentaerythritol, tripentaerythritol, glycerin, diglycerol, or trimethylolmelamine, with (meth)acrylic acid and ε-caprolactone.

It is also preferred that the polymerizable compound is at least one selected from the group consisting of compounds represented by General Formulae (i) and (ii).

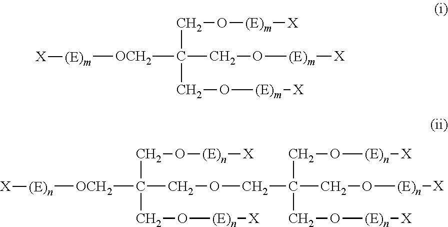

In General Formulae (i) and (ii), E's each independently represent —((CH₂)_{y}CH₂O)— or —((CH₂)_{y}CH(CH₃)O)—, y's each independently represent an integer of 0 to 10, and X's each independently represent an acryloyl group, a methacryloyl group, a hydrogen atom, or a carboxyl group.

In General Formula (i), the total number of acryloyl groups and methacryloyl groups is 3 or 4, m's each independently represent an integer of 0 to 10, and the total of each m is an integer of 0 to 40, provided that in the case where the total of each m is 0, any one of X's is a carboxyl group.

In General Formula (ii), the total number of acryloyl groups and methacryloyl groups is 5 or 6, n's each independently represent an integer of 0 to 10, and the total of each n is an integer of 0 to 60, provided that in the case where the total of each n is 0, any one of X′s is a carboxyl group.

In General Formula (i), m is preferably an integer of 0 to 6 and more preferably an integer of 0 to 4.

The total of each m is preferably an integer of 2 to 40, more preferably an integer of 2 to 16, and still more preferably an integer of 4 to 8.

In General Formula (ii), n is preferably an integer of 0 to 6 and more preferably an integer of 0 to 4.

The total of each n is preferably an integer of 3 to 60, more preferably an integer of 3 to 24, and still more preferably an integer of 6 to 12.

In a preferred embodiment, —((CH₂)_{y}CH₂O)— or —((CH₂)_{y}CH(CH₃)O)— in General Formula (i) or (ii) is bonded to X at its terminal on the oxygen atom side.

The compounds represented by General Formula (i) or (ii) may be used alone or in combination of two or more thereof. In particular, preferred is an embodiment where all of six X's in General Formula (ii) are acryloyl groups.

The total content of the compound represented by General Formula (i) or (ii) in the polymerizable compound is preferably 20 mass % or more and more preferably 50 mass % or more.

The compound represented by General Formula (i) or (ii) can be synthesized through a process of bonding a ring-opened skeleton of ethylene oxide or propylene oxide to pentaerythritol or dipentaerythritol by a ring-opening addition reaction, and a process of introducing a (meth)acryloyl group into the terminal hydroxyl group of the ring-opened skeleton by reacting, for example, (meth)acryloyl chloride therewith, which are conventionally known processes. Each of the processes is a well-known process, and the compound represented by General Formula (i) or (ii) can be easily synthesized by those skilled in the art.

Among the compounds represented by General Formulae (i) and (ii), a pentaerythritol derivative and/or a dipentaerythritol derivative is preferred.

As a commercially available product of the polymerizable compound represented by General Formula (i) or (ii), for example, SR-494 which is a tetrafunctional acrylate having four ethyleneoxy chains, (manufactured by Sartomer Company Inc.), and DPCA-60 which is a hexafunctional acrylate having six pentyleneoxy chains and TPA-330 which is a trifunctional acrylate having three isobutyleneoxy chains, (both manufactured by Nippon Kayaku Co., Ltd.) are exemplified.

Further, urethane acrylates as described in JP1973-41708B (JP-S48-41708B), JP1976-37193A (JP-S51-37193A), JP1990-32293B (JP-H02-32293B), and JP1990-16765B (JP-H02-16765B), and urethane compounds having an ethylene oxide-based skeleton described in JP1983-49860B (JP-S58-49860B), JP1981-17654B (JP-S56-17654B), JP1987-39417B (JP-S62-39417B), and JP1987-39418B (JP-S62-39418B) are also suitable as the polymerizable compound. In addition, by using addition polymerizable compounds having an amino structure or a sulfide structure in the molecules thereof described in JP1988-277653A (JP-S63-277653A), JP1988-260909A (JP-S63-260909A), and JP1989-105238A (JP-H01-105238A) as the polymerizable compound, it is possible to obtain a curable composition which exhibits a very excellent photosensitizing speed.

As a commercially available product of the polymerizable compound, for example, urethane oligomers UAS-10 and UAB-140 (manufactured by Sanyo-Kokusaku Pulp Co., Ltd.), U-4HA, U-6LPA, UA-32P, U-10HA, U-10PA, UA-122P, UA-1100H, and UA-7200 (manufactured by Shin-Nakamura Chemical Co., Ltd.), DPHA-40H (manufactured by Nippon Kayaku Co., Ltd.), UA-306H, UA-306T, UA-306I, AH-600, T-600, and AI-600 (manufactured by Kyoeisha Chemical Co., Ltd.), and UA-9050 and UA-9048 (manufactured by BASF Corporation) are exemplified.

With respect to these polymerizable compounds, the details of the usage thereof, such as the structure, use alone or in combination, or addition amount, can be arbitrarily set according to the final performance design of the infrared light absorbing composition. For example, from the viewpoint of the sensitivity, a structure having a large content of unsaturated groups per molecule is preferable, and in many cases, a difunctional or higher functional compound is preferable. From the viewpoint of increasing the strength of the cured film, a trifunctional or higher functional compound is preferred. A combination use of compounds having different functionalities and/or different polymerizable groups (for example, an acrylic acid ester, a methacrylic acid ester, a styrene-based compound, and a vinyl ether-based compound) is an effective method for controlling both the sensitivity and the strength. Further, a combination use of trifunctional or higher functional polymerizable compound having different ethylene oxide chain lengths is preferable from the viewpoint that the developability of the photosensitive composition can be controlled and excellent pattern formation can be achieved. The selection of the polymerizable compound is also an important factor for the compatibility and dispersibility with other components (for example, a photopolymerization initiator or an alkali-soluble resin) contained in the infrared light absorbing composition. For example, the compatibility may be improved by using a polymerizable compound of low purity or using two or more polymerizable compounds in combination. In addition, a specific structure may be selected from the viewpoint of improving the adhesiveness to a hard surface such as a support.

Specific examples of the polymerizable compound are shown below, but the present invention is not limited thereto.

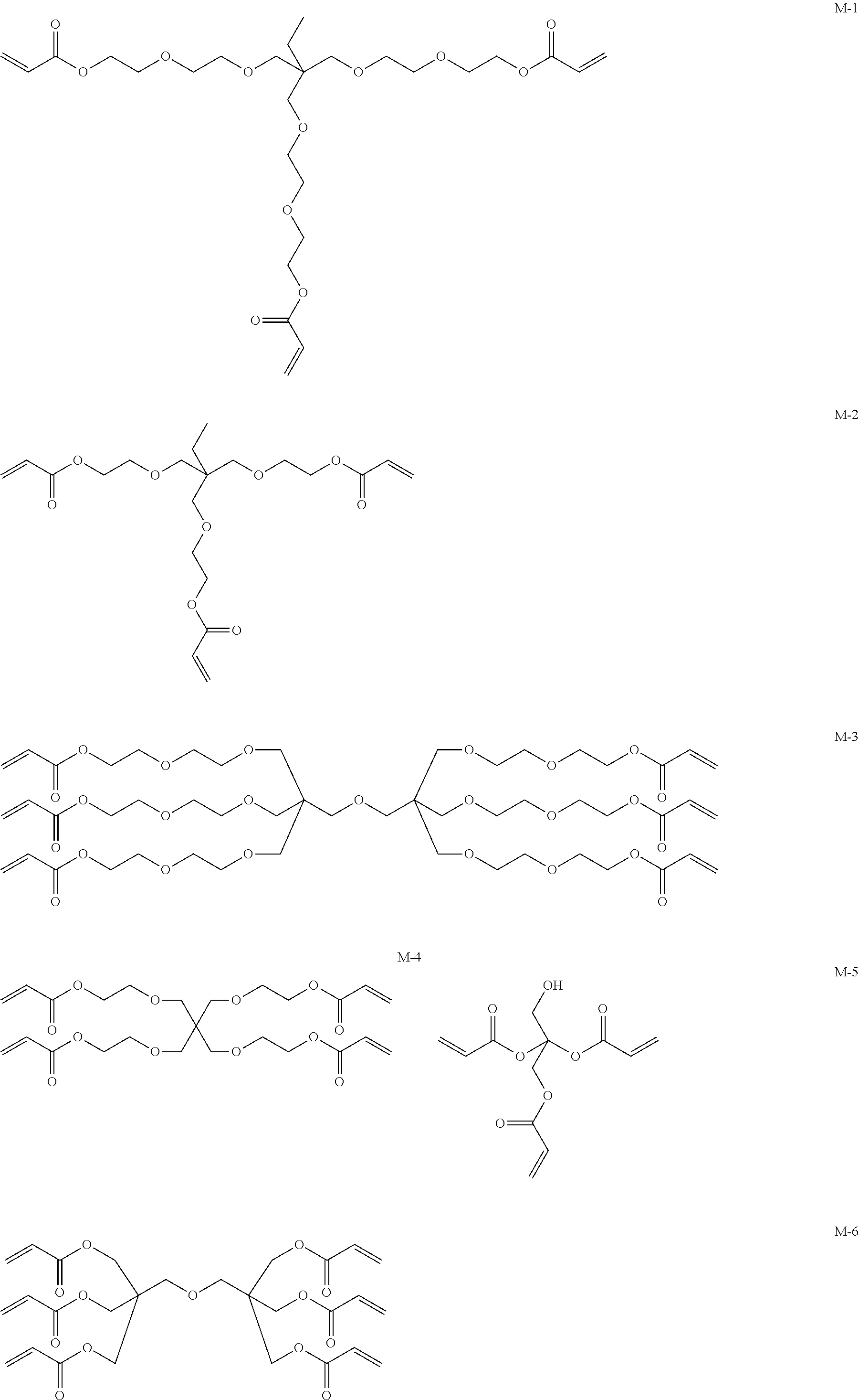

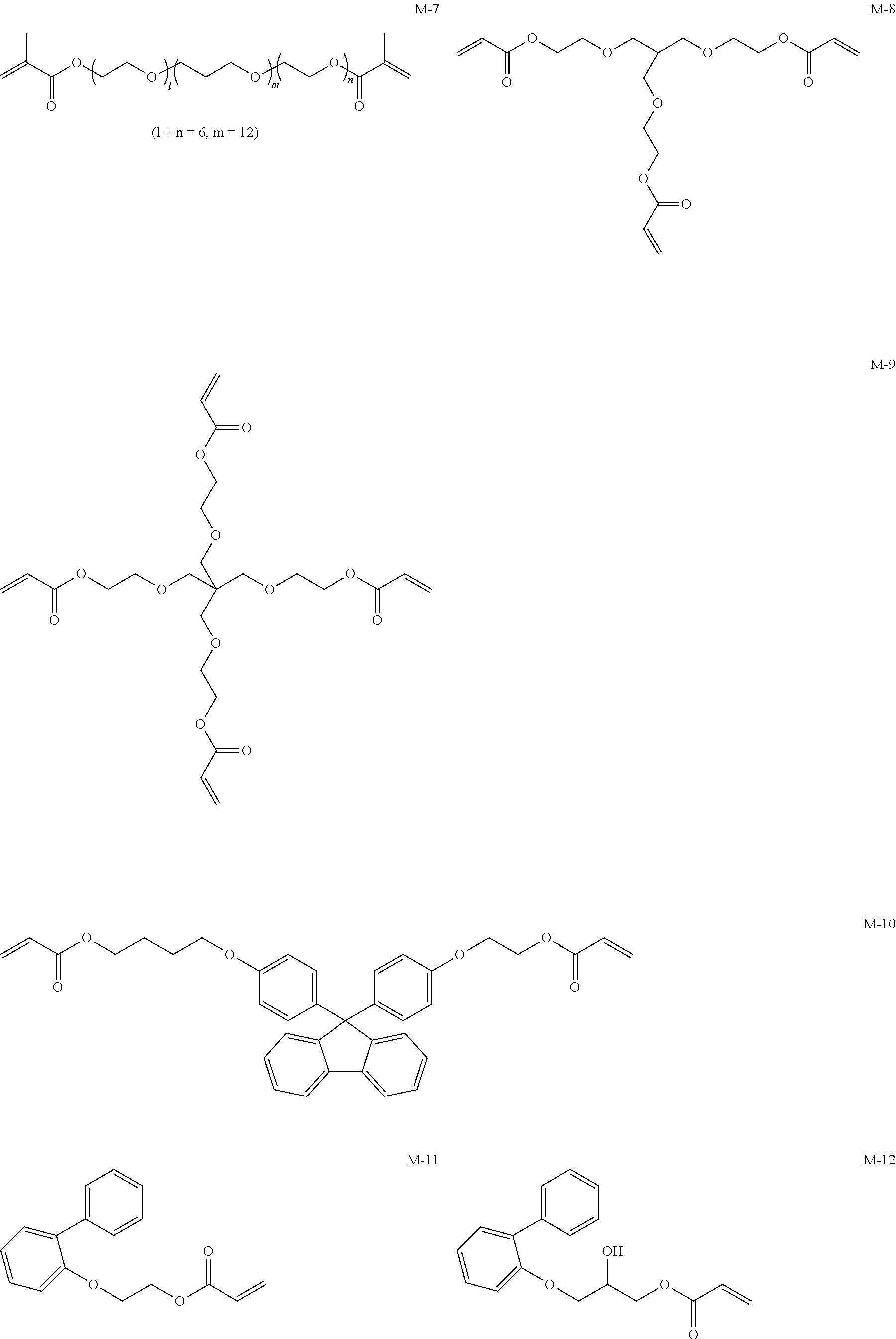

In addition, the polymerizable compound may be a compound having a polymerizable group and a silyl group (hereinafter, also referred to as a silyl compound). In the case where a photosensitive composition containing the silyl compound is applied (for example, coated) onto a support, the adhesiveness between the infrared light absorbing composition and the support is improved by the interaction between the Si atom of the silyl compound and the component constituting the support.

From the viewpoint of improving interaction and compatibility with the support, the silyl compound is preferably a compound represented by General Formula (a) (hereinafter, also referred to as a “specific silyl compound”).

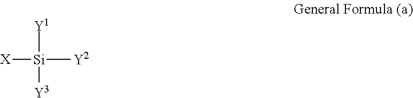

In General Formula (a), X is a hydrogen atom or an organic group, and is preferably an organic group having one or more polymerizable groups and an amino group. Y¹, Y², and Y³ each independently represent an alkyl group, an alkenyl group, an alkynyl group, an aryl group, a hydroxyl group, an alkoxy group, a halogen atom, an aryloxy group, an amino group, a silyl group, a heterocyclic group, or a hydrogen atom, among which an alkyl group or an alkoxy group is preferable.

In General Formula (a), X, Y², and Y³ may have a polymerizable group (for example, a (meth)acrylate group, a (meth)acrylamide group, or a styryl group).

Examples of the silyl compound include the silyl compounds having a polymerizable group in paragraphs [0056] to [0066] of JP2009-242604A.

As the polymerizable compound, it is also possible to use the thio(meth)acrylate compounds described in paragraphs [0024] to [0031] of JP4176717B (paragraphs [0027] to of US2005/0261406A), the contents of which are incorporated herein by reference in its entirety.

(Polymerization Initiator)

The infrared light absorbing composition may contain a polymerization initiator. The polymerization initiator may be, for example, a thermal polymerization initiator or a photopolymerization initiator, among which a photopolymerization initiator is preferable. Hereinafter, the photopolymerization initiator will be mainly described in detail.

The photopolymerization initiator is not particularly limited as long as it has an ability to initiate polymerization of a polymerizable compound, and can be appropriately selected from known photopolymerization initiators. For example, a photopolymerization initiator having photosensitivity to light from an ultraviolet region to a visible light region is preferred. Also, the photopolymerization initiator may be an activator which causes some action with a photo-excited sensitizer to generate an active radical or it may be an initiator which initiates cationic polymerization depending on the type of monomer.

Further, it is preferred that the photopolymerization initiator contains at least one compound having a molar extinction coefficient of at least about 50 in the range of about 300 to 800 nm (more preferably 330 to 500 nm).

Examples of the photopolymerization initiator include a halogenated hydrocarbon derivative (for example, a compound having a triazine skeleton or a compound having an oxadiazole skeleton); an acylphosphine compound such as an acylphosphine oxide; a hexaarylbiimidazole; an oxime compound such as an oxime derivative; an organic peroxide; a thio compound; a ketone compound; an aromatic onium salt; a ketoxime ether; an aminoacetophenone compound; and a hydroxyacetophenone. Examples of the halogenated hydrocarbon compound having a triazine skeleton include the compounds described in Wakabayashi et al., Bull. Chem. Soc. Japan, 42, 2924 (1969), the compounds described in British Patent 1388492, the compounds described in JP1978-133428A (JP-553-133428A), the compounds described in German Patent 3337024, the compounds described in F. C. Schaefer et al., J. Org. Chem., 29, 1527 (1964), the compounds described in JP1987-58241A (JP-562-58241A), the compounds described in JP1993-281728A (JP-H05-281728A), the compounds described in JP1993-34920A (JP-H05-34920A), and the compounds described in U.S. Pat. No. 4,212,976A.

From the viewpoint of exposure sensitivity, preferred is a compound selected from the group consisting of a trihalomethyltriazine compound, a benzyl dimethyl ketal compound, an α-hydroxyketone compound, an α-aminoketone compound, an acyl phosphine compound, a phosphine oxide compound, a metallocene compound, an oxime compound, a triallylimidazole dimer, an onium compound, a benzothiazole compound, a benzophenone compound, an acetophenone compound and a derivative thereof, a cyclopentadiene-benzene-iron complex and a salt thereof, a halomethyloxadiazole compound, and a 3-aryl-substituted coumarin compound.

More preferred is a trihalomethyltriazine compound, an a-aminoketone compound, an acyl phosphine compound, a phosphine oxide compound, an oxime compound, a triallylimidazole dimer, an onium compound, a benzophenone compound or an acetophenone compound, and particularly preferred is at least one compound selected from the group consisting of a trihalomethyltriazine compound, an α-aminoketone compound, an oxime compound, a triallylimidazole dimer, and a benzophenone compound.

In particular, in the case where the laminate of the present invention is used for a solid-state imaging device, it is preferable that a fine pattern is formed in a sharp shape in some cases, so that it is developed with no residue in the unexposed area as well as achieving curability. From this viewpoint, it is preferable to use an oxime compound as the photopolymerization initiator. In particular, in the case where a fine pattern is formed in a solid-state imaging device, stepper exposure is used for curing exposure, but this exposure machine may be damaged by halogen. Therefore, it is also necessary to keep the addition amount of the photopolymerization initiator low. Taking these points into consideration, it is preferable to use an oxime compound as the photopolymerization initiator, in the case of forming a fine pattern such as a solid-state imaging device. Further, use of an oxime compound can further improve color transferability.

As for specific examples of the photopolymerization initiator, reference can be made to, for example, paragraphs [0265] to [0268] of JP2013-29760A, the contents of which are incorporated herein by reference in its entirety.

As the photopolymerization initiator, a hydroxyacetophenone compound, an aminoacetophenone compound, and an acylphosphine compound can also be suitably used. More specifically, for example, an aminoacetophenone-based initiator described in JP1998-291969A (JP-H10-291969A) and an acylphosphine-based initiator described in JP4225898B can also be used.

As the hydroxyacetophenone-based initiator, IRGACURE-184, DAROCUR-1173, IRGACURE-500, IRGACURE-2959, and IRGACURE-127 (trade names, all manufactured by BASF Corporation) can be used.

As the aminoacetophenone-based initiator, commercially available products of IRGACURE-907, IRGACURE-369, and IRGACURE-379 EG (trade names, all manufactured by BASF Corporation) can be used. As the aminoacetophenone-based initiator, compounds described in JP2009-191179A, where the absorption wavelength matches the light source with a long wavelength of, for example, 365 nm or 405 nm, can also be used.

As the acylphosphine-based initiator, commercially available products of IRGACURE-819 and DAROCUR-TPO (trade names, all manufactured by BASF Corporation) can be used.

The photopolymerization initiator may be more preferably an oxime compound.

As specific examples of the oxime compound, compounds described in JP2001-233842A, compounds described in JP2000-80068A and compounds described in JP2006-342166A can be used.

Examples of the oxime compound that can be suitably used in the present invention include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3 -(4-toluenesulfonyloxyl)iminobutan-2-one, and 2-ethoxycarbonyloxyimino-1-phenylpropan-1-one.

Further examples of the oxime compound include compounds described in J. C. S. Perkin II (1979) pp. 1653-1660, J. C. S. Perkin II (1979) pp. 156-162, Journal of Photopolymer Science and Technology (1995) pp 202-232, JP2000-66385A, JP2000-80068A, JP2004-534797A, and JP2006-342166A.

As the commercially available product, IRGACURE-OXE01 (manufactured by BASF Corporation) and IRGACURE-OXE02 (manufactured by BASF Corporation) are also suitably used.

In addition, as the oxime compound other than the oxime compounds described above, compounds described in JP2009-519904A, in which oxime is connected to the N-position of carbazole, compounds described in U.S. Pat. No. 7,626,957B, in which a hetero-substituent is introduced into the benzophenone moiety, compounds described in JP2010-15025A and US2009-292039A, in which a nitro group is introduced into the dye moiety, ketoxime compounds described in WO02009/131189A, compounds containing a triazine skeleton and an oxime skeleton in the same molecule described in U.S. Pat. No. 7,556,910B, and compounds having an absorption maximum at 405 nm and exhibiting good sensitivity for a g-line light source described in JP2009-221114A may also be used.

Preferably, reference can be made to, for example, paragraphs [0274] to [0275] of JP2013-29760A, the contents of which are incorporated herein by reference in its entirety.

Specifically, a compound represented by General Formula (OX-1) is preferable as the oxime compound. Note that the N—O bond of the oxime may be an (E) form of an oxime compound, a (Z) form of an oxime compound, or a mixture of the (E) form and the (Z) form.

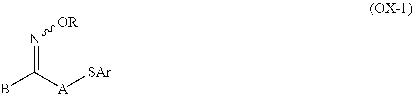

In General Formula (OX-1), R and B each independently represent a monovalent substituent, A represents a divalent organic group, and Ar represents an aryl group.

In General Formula (OX-1), the monovalent substituent represented by R is preferably a monovalent non-metallic atomic group.

Examples of the monovalent non-metallic atomic group include an alkyl group, an aryl group, an acyl group, an alkoxycarbonyl group, an aryloxycarbonyl group, a heterocyclic group, an alkylthiocarbonyl group, and an arylthiocarbonyl group. Further, these groups may have one or more substituents. Further, the above-mentioned substituent may be further substituted with another substituent.

Examples of the substituent include a halogen atom, an aryloxy group, an alkoxycarbonyl group, an aryloxycarbonyl group, an acyloxy group, an acyl group, an alkyl group, and an aryl group.

In General Formula (OX-1), the monovalent substituent represented by B is preferably an aryl group, a heterocyclic group, an arylcarbonyl group, or a heterocyclic carbonyl group. These groups may have one or more substituents. As the substituent, the above-mentioned substituents can be exemplified.

In General Formula (OX-1), the divalent organic group represented by A is preferably an alkylene group, cycloalkylene group, or alkynylene group having 1 to 12 carbon atoms. These groups may have one or more substituents. As the substituent, the above-mentioned substituents can be exemplified.

An oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A. The contents of those patent publications are incorporated herein by reference in its entirety.

In the present invention, it is also possible to use an oxime compound having a nitro group as the oxime compound. Specific examples of the oxime compound having a nitro group include compounds described in paragraphs [0031] to [0047] of JP2013-114249A, compounds described in paragraphs [0008] to [0012] and [0070] to [0079] of JP2014-137466A, and ADEKA ARKLS NCI-831 (manufactured by ADEKA Corporation).

In the present invention, a compound represented by General Formula (1) or (2) can also be used as the photopolymerization initiator.

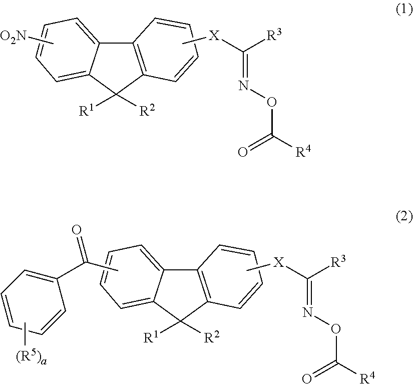

In General Formula (1), R¹ and R² each independently represent an alkyl group having 1 to 20 carbon atoms, an alicyclic hydrocarbon group having 4 to 20 carbon atoms, an aryl group having 6 to 30 carbon atoms, or an arylalkyl group having 7 to 30 carbon atoms, and in the case where le and R² are phenyl groups, the phenyl groups may be bonded to each other to form a fluorene group, R³ and R⁴ each independently represent a hydrogen atom, an alkyl group having 1 to 20 carbon atoms, an aryl group having 6 to 30 carbon atoms, an arylalkyl group having 7 to 30 carbon atoms, or a heterocyclic group having 4 to 20 carbon atoms, and X represents a direct bond or a carbonyl group.

In General Formula (2), R¹, R², R³, and R⁴ have the same definition as R¹, R², R³, and R⁴ in General Formula (1), R⁵ represents —R⁶, —OR⁶, —SR⁶, —COR^{E}, —CONR⁶R⁶, —NR⁶COR⁶, —OCOR⁶, —COOR⁶, —SCOR⁶, —OCSR⁶, —COSR⁶, —CSOR⁶, —CN, a halogen atom, or a hydroxyl group, R⁶ represents an alkyl group having 1 to 20 carbon atoms, an aryl group having 6 to 30 carbon atoms, an arylalkyl group having 7 to 30 carbon atoms, or a heterocyclic group having 4 to 20 carbon atoms, X represents a direct bond or a carbonyl group, and a represents an integer of 0 to 5.

Specific examples of the compounds represented by General Formulae (1) and (2) include compounds described in paragraphs [0076] to [0079] of JP2014-137466A, the contents of which are incorporated herein by reference in its entirety.

Specific examples of the oxime compound preferably used in the present invention are shown below, but the present invention is not limited thereto.

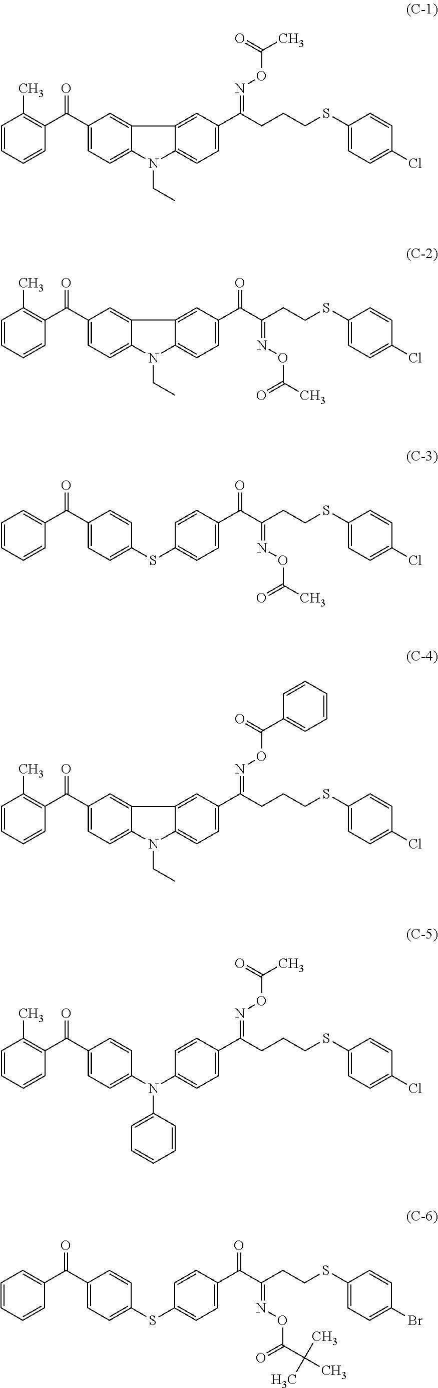 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

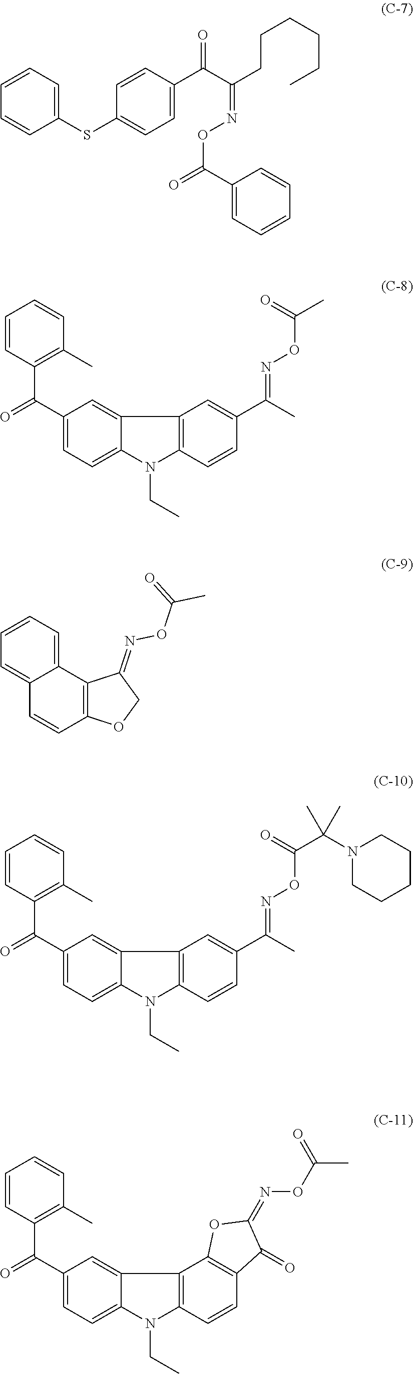 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

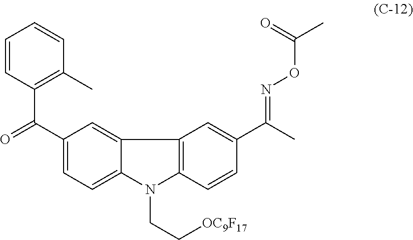

The oxime compound preferably has a maximum absorption wavelength in a wavelength range of 350 to 500 nm, more preferably has an absorption wavelength in a wavelength range of 360 to 480 nm, and still more preferably exhibits a high absorbance at 365 nm and 455 nm.

From the viewpoint of sensitivity, the oxime compound has a molar extinction coefficient at 365 nm or 405 nm of preferably 1,000 to 300,000, more preferably 2,000 to 300,000, and still more preferably 5,000 to 200,000.

The molar extinction coefficient of the compound can be measured using a known method. For example, the molar extinction coefficient of the compound is preferably measured at a concentration of 0.01 g/L using an ethyl acetate solvent in a UV-Vis spectrophotometer (Cary-5 spectrophotometer, manufactured by Varian Medical Systems, Inc.).

The photopolymerization initiators used in the present invention may be used in combination of two or more thereof, if necessary.

The content of the photopolymerization initiator is preferably 0.1 to 50 mass %, more preferably 0.5 to 30 mass %, and still more preferably 1 to 20 mass %, with respect to the total solid content of the infrared light absorbing composition. Within this range, better sensitivity and pattern formability are obtained. The infrared light absorbing composition of the present invention may contain one photopolymerization initiator or may contain two or more photopolymerization initiators. In the case where two or more photopolymerization initiators are contained, the total amount thereof is preferably within the above-specified range.

(Solvent)

The infrared light absorbing composition may contain a solvent. The solvent is not particularly limited and may be appropriately selected according to the purpose as long as it can uniformly dissolve or disperse each component of the infrared light absorbing composition. For example, water or an organic solvent can be used, and an organic solvent is preferable.

Suitable examples of the organic solvent include alcohols (for example, methanol), ketones, esters, ethers, aromatic hydrocarbons, halogenated hydrocarbons, dimethylformamide, dimethylacetamide, dimethyl sulfoxide, and sulfolane. These solvents may be used alone or in combination of two or more thereof. In the case where two or more solvents are used in combination, preferred is a mixed solution made of two or more solvents selected from methyl 3-ethoxypropionate, ethyl 3-ethoxypropionate, ethylcellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, ethylene glycol monobutyl ether acetate, propylene glycol monomethyl ether, and propylene glycol monomethyl ether acetate.

Specific examples of alcohols, aromatic hydrocarbons, and halogenated hydrocarbons include those described in paragraph [0136] of JP2012-194534A, the contents of which are incorporated herein by reference in its entirety. Specific examples of esters, ketones, and ethers include those described in paragraph [0497] of JP2012-208494A (paragraph <0609> of corresponding US2012/0235099A) and further include n-amyl acetate, ethyl propionate, dimethyl phthalate, ethyl benzoate, methyl sulfate, acetone, methyl isobutyl ketone, diethyl ether, and ethylene glycol monobutyl ether acetate.

The amount of the solvent in the infrared light absorbing composition is preferably such that the solid content is 10 to 90 mass %. The lower limit thereof is preferably 20 mass % or more. The upper limit thereof is preferably 80 mass % or less.

(Surfactant)

From the viewpoint of further improving the coatability, the infrared light absorbing composition may contain various surfactants.

Various surfactants such as a fluorine-based surfactant, a nonionic surfactant, a cationic surfactant, an anionic surfactant, and a silicone-based surfactant can be used as the surfactant.

Inclusion of a fluorine-based surfactant in the infrared light absorbing composition leads to a further improvement of liquid properties (in particular, fluidity) in the case of being prepared as a coating liquid, so that the coating thickness uniformity and liquid saving properties can be further improved.

That is, in the case of forming a film using a coating liquid to which a composition containing a fluorine-based surfactant is applied, the interfacial tension between the surface to be coated and the coating liquid is lowered and the wettability to the surface to be coated is improved, whereby the coatability on the surface to be coated is improved. Therefore, it is possible to more suitably form a uniform thickness film with less thickness unevenness.

The fluorine-based surfactant preferably has a fluorine content of 3 to 40 mass %. The lower limit of the fluorine content is more preferably 5 mass % or more and still more preferably 7 mass % or more. The upper limit of the fluorine content is more preferably 30 mass % or less and still more preferably 25 mass % or less. The case of the fluorine content within the above-specified range is effective in terms of coating film thickness uniformity and liquid saving properties and also provides satisfactory solubility.

Specific examples of the fluorine-based surfactant include surfactants described in paragraphs [0060] to [0064] of JP2014-41318A (paragraphs [0060] to [0064] of corresponding WO2014/17669A), the contents of which are incorporated herein by reference in its entirety. Examples of commercially available fluorine-based surfactant include MEGAFACE F-171, MEGAFACE F-172, MEGAFACE F-173, MEGAFACE F-176, MEGAFACE F-177, MEGAFACE F-141, MEGAFACE F-142, MEGAFACE F-143, MEGAFACE F-144, MEGAFACE R30, MEGAFACE F-437, MEGAFACE F-475, MEGAFACE F-479, MEGAFACE F-482, MEGAFACE F-554, and MEGAFACE F-780 (all manufactured by DIC Corporation), FLUORAD FC430, FLUORAD FC431, and FLUORAD FC171 (all manufactured by Sumitomo 3M Ltd.), and SURFLON S-382, SURFLON SC-101, SURFLON SC-103, SURFLON SC-104, SURFLON SC-105, SURFLON SC-1068, SURFLON SC-381, SURFLON SC-383, SURFLON S-393, and SURFLON KH-40 (all manufactured by Asahi Glass Co., Ltd.).

In addition, the following compounds are also exemplified as the fluorine-based surfactant used in the present invention.

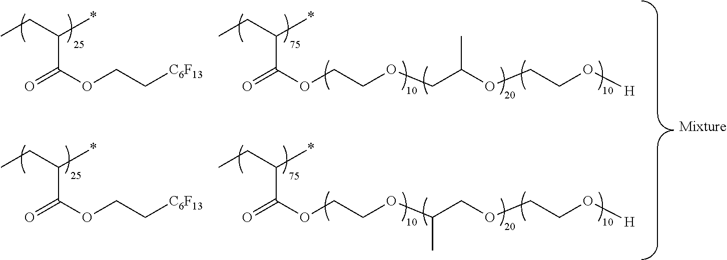

The weight-average molecular weight of the above compound is preferably 3,000 to 50,000, for example, 14,000.

A fluorine-containing polymer having an ethylenically unsaturated group in the side chain can also be used as the fluorine-based surfactant. Specific examples include compounds described in paragraphs [0050] to [0090] and paragraphs [0289] to [0295] of JP2010-164965A, for example, MEGAFACE RS-101, RS-102, and RS-718K (manufactured by DIC Corporation).

Specific examples of the nonionic surfactant include glycerol, trimethylolpropane, trimethylol ethane and ethoxylates and propoxylates thereof (for example, glycerol propoxylate and glycerin ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, sorbitan fatty acid ester (PLURONIC L10, L31, L61, L62, 10R5, 17R2, and 25R2, and TETRONIC 304, 701, 704, 901, 904, and 150R1, manufactured by BASF Corporation), and SOLSPERSE 20000 (manufactured by Nippon Lubrizol Corporation). In addition, NCW-101, NCW-1001, and NCW-1002 (manufactured by Wako Pure Chemical Industries, Ltd.) can also be used.

Specific examples of the cationic surfactant include phthalocyanine derivatives (trade name: EFKA-745, manufactured by Morishita Industry Co., Ltd.), organosiloxane polymer KP-341 (manufactured by Shin-Etsu Chemical Co., Ltd.), (meth)acrylic acid-based (co)polymer POLYFLOW No. 75, No. 90, and No. 95 (manufactured by Kyoeisha Chemical Co., Ltd.), and W001 (manufactured by Yusho Co., Ltd.).

Specific examples of the anionic surfactant include W004, W005, and W017 (manufactured by Yusho Co., Ltd.), and SANDED BL (manufactured by Sanyo Chemical Industries, Ltd.).

Examples of the silicone-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Toray Co., Ltd.), TSF-4440, TSF-4300, TSF-4445, TSF-4460, and TSF-4452 (all manufactured by Momentive Performance Materials Co., Ltd.), KP-341, KF6001, and KF6002 (all manufactured by Shin-Etsu Silicone Co., Ltd.), and BYK307, BYK323, and BYK330 (all manufactured by BYK Chemie GmbH).

The surfactants may be used alone or in combination of two or more thereof.

The content of the surfactant is preferably 0.001 to 2.0 mass % and more preferably 0.005 to 1.0 mass % with respect to the total solid content of the composition.

Further, the surfactant may be contained not only in the infrared light absorbing layer but also in other layers.

The infrared light absorbing composition may further contain, for example, a dispersant, a sensitizer, a crosslinking agent, a curing accelerator, a filler, a thermal curing accelerator, a thermal polymerization inhibitor, a plasticizer, an adhesion promoter, and other auxiliaries (for example, conductive particles, a bulking agent, an antifoaming agent, a flame retardant, a leveling agent, a release promoter, an antioxidant, a perfume, a surface tension regulator, and a chain transfer agent), in addition to the foregoing components.

The infrared light absorbing composition can be applied by a method such as a dropping method (drop cast), a spin coater, a slit spin coater, a slit coater, a screen printing, or an applicator coating method.

Drying conditions vary depending on each component, type of solvent, usage ratio, and the like, but drying is carried out at a temperature of 60° C. to 150° C. for about 30 seconds to 15 minutes.

In the method of forming an infrared light absorbing layer, other steps may be included. The other steps are not particularly limited and may be appropriately selected depending on the purpose. For example, a pre-heating step (pre-baking step), a curing treatment step, a post-heating step (post-baking step), and the like can be mentioned.

The heating temperature in the pre-heating step and the post-heating step is usually 80° C. to 200° C. and preferably 90° C. to 150° C. The heating time in the pre-heating step and the post-heating step is usually 30 to 240 seconds and preferably 60 to 180 seconds.

The curing treatment step is a step of subjecting the formed film to a curing treatment as necessary, and such a treatment results in improved mechanical strength of the infrared light absorbing layer. In the case where an infrared light absorbing composition containing a polymerizable compound is used, it is preferable to carry out a curing treatment step.

The curing treatment step is not particularly limited and may be appropriately selected depending on the intended purpose. For example, an entire surface exposure treatment or an entire surface heating treatment can be suitably mentioned. The term “exposure” as used herein is used to include not only exposure to light of various wavelengths but also exposure to radiation such as electron beams or X-rays.

Exposure is preferably carried out by exposure to radiation, and as the radiation that can be used for exposure, electron beams, KrF, ArF, ultraviolet light such as g-line, h-line, or i-line, visible light, or the like is particularly preferably used.

As the exposure method, stepper exposure, exposure by a high pressure mercury lamp, or the like can be mentioned.

The exposure amount is preferably 5 to 3,000 mJ/cm², more preferably 10 to 2,000 mJ/cm², and particularly preferably 50 to 1,000 mJ/cm².

As a method of the entire surface exposure treatment, for example, a method of exposing the entire surface of the formed film may be mentioned. In the case where the infrared light absorbing composition contains a polymerizable compound, curing of the polymerization component in the film is promoted by the entire surface exposure and the curing of the film further proceeds, whereby the solvent resistance and heat resistance of the infrared light absorbing layer are improved.

The apparatus for carrying out the entire surface exposure is not particularly limited and can be appropriately selected according to the purpose. For example, an ultraviolet (UV) exposure apparatus such as an ultra-high pressure mercury lamp can be suitably mentioned.

In addition, as a method of the entire surface heating treatment, a method of heating the entire surface of the formed film may be mentioned. The entire surface heating results in improved solvent resistance and heat resistance of the infrared light absorbing layer.

The heating temperature in the entire surface heating is preferably 120° C. to 250° C. and more preferably 160° C. to 220° C. In the case where the heating temperature is 120° C. or higher, the film strength is improved by the heating treatment, and in the case where the heating temperature is 250° C. or lower, the decomposition of the film components can be suppressed.

The heating time in the entire surface heating is preferably 3 to 180 minutes and more preferably 5 to 120 minutes.

The apparatus for carrying out the entire surface heating is not particularly limited and can be appropriately selected according to the purpose from known apparatuses, examples of which include a dry oven and a hot plate.

### Fifth Embodiment

FIG. 9 shows a cross-sectional view of a fifth embodiment of the laminate of the present invention.

As shown in FIG. 9, a laminate 400 includes a visible light absorbing layer 28, first reflective layers 12c and 12d, and second reflective layers 14c and 14d.

The laminate 400 of the fifth embodiment has the same members as the laminate 10 of the above-described first embodiment except that the visible light absorbing layer 28 is included and the first reflective layers 12a and 12b and the second reflective layers 14a and 14b are not included. The same members are denoted by the same reference numerals and the description thereof will be omitted. Hereinafter, an aspect of the visible light absorbing layer 28 will be mainly described in detail.

(Visible Light Absorbing Layer)

The visible light absorbing layer 28 is a layer that absorbs visible light. By including the visible light absorbing layer 28, light in a predetermined visible light region can be blocked (shielded) in the laminate. Therefore, by disposing this layer in the laminate, a plurality of reflective layers (the first reflective layers 12a and 12b and the second reflective layers 14a and 14b) disposed for reflecting the visible light region can be excluded, and as a result, it is possible to achieve thinning of the laminate.

The visible light absorbing layer 28 is a layer that absorbs light in at least the visible light region, and may absorb light in other wavelength ranges (for example, ultraviolet light region and infrared light region).

In FIG. 9, the visible light absorbing layer 28 is disposed closest to the light incident side, but it is not limited to this aspect. For example, the visible light absorbing layer 28 may be disposed at a position farthest from the light incident side, or may be disposed between the reflective layers.

The material used for the visible light absorbing layer 28 is not particularly limited, and a known material can be used.

The visible light absorbing layer 28 preferably contains a colorant (dye and pigment). As the colorant, a known colorant used for producing a so-called red (R), green (G), or blue (B) color filter can be mentioned. More specifically, it is preferred that the visible light absorbing layer 28 contains a chromatic colorant or an organic black colorant.

(Chromatic Colorant)

In the present invention, the chromatic colorant is preferably a colorant selected from a red colorant, a green colorant, a blue colorant, a yellow colorant, a violet colorant, and an orange colorant.

In the present invention, the chromatic colorant may be a pigment or a dye. Preferably, it is a pigment.

The average particle diameter (r) of the pigment preferably satisfies 20 nm≤r≤300 nm, more preferably 25 nm≤r≤250 nm, and still more preferably 30 nm≤r≤200 nm. The term “average particle diameter” as used herein means an average particle diameter of secondary particles in which primary particles of a pigment are aggregated.

The particle size distribution of secondary particles (hereinafter, also simply referred to as “particle size distribution”) of a usable pigment is such that the secondary particles falling within the (average particle diameter±100) nm preferably account for 70 mass % or more and more preferably 80 mass % or more. The particle size distribution of the secondary particles can be measured using the scattering intensity distribution.

The pigment having the secondary particle diameter and the particle size distribution of secondary particles described above may be prepared by mixing and dispersing a commercially available pigment with an optionally used other pigment (the average particle diameter of secondary particles is usually greater than 300 nm) while pulverizing them, for example, using a pulverizer such as a beads mill or a roll mill, preferably as a pigment mixed liquid in admixture with a resin and an organic solvent. The pigment thus obtained usually takes the form of a pigment dispersion liquid.

The pigment is preferably an organic pigment, and the following can be mentioned without being limited thereto.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, and the like (all of which are yellow pigments),

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments),

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, and the like (all of which are red pigments),

C. I. Pigment Green 7, 10, 36, 37, 58, 59, and the like (all of which are green pigments),

C. I. Pigment Violet 1, 19, 23, 27, 32, 37, 42, and the like (all of which are violet pigments), and

C. I. Pigment Blue 1, 2, 15, 15:1, 15:2, 15:3, 15:4, 15:6, 16, 22, 60, 64, 66, 79, 80, and the like (all of which are blue pigments).

These organic pigments may be used alone or in various combinations.

The dye is not particularly limited, and a known dye can be used. From the viewpoint of chemical structure, dyes such as a pyrazole azo-based dye, an anilino azo-based dye, a triphenylmethane-based dye, an anthraquinone-based dye, an anthrapyridone-based dye, a benzylidene-based dye, an oxonol-based dye, a pyrazolotriazole azo-based dye, a pyridone azo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethene-based dye can be used. Multimers of these dyes may also be used. In addition, dyes described in JP2015-028144A and JP2015-34966A can also be used.

An acidic dye and/or a derivative thereof may be suitably used as a dye in some cases.

In addition, a direct dye, a basic dye, a mordant dye, an acidic mordant dye, an azoic dye, a disperse dye, an oil-soluble dye, a food dye and/or derivatives thereof can also be usefully used.

Specific examples of the acidic dye are listed below without being limited thereto. For example, the following dyes and derivatives of these dyes can be mentioned.

Acid alizarin violet N,

Acid blue 1, 7, 9, 15, 18, 23, 25, 27, 29, 40 to 45, 62, 70, 74, 80, 83, 86, 87, 90, 92, 103, 112, 113, 120, 129, 138, 147, 158, 171, 182, 192, 243, and 324:1,

Acid chrome violet K,

Acid Fuchsin,

Acid green 1, 3, 5, 9, 16, 25, 27, and 50,

Acid orange 6, 7, 8, 10, 12, 50, 51, 52, 56, 63, 74, and 95,

Acid red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 183, 198, 211, 215, 216, 217, 249, 252, 257, 260, 266, and 274,

Acid violet 6B, 7, 9, 17, and 19,

Acid yellow 1, 3, 7, 9, 11, 17, 23, 25, 29, 34, 36, 42, 54, 72, 73, 76, 79, 98, 99, 111, 112, 114, 116, 184, and 243, and

Food Yellow 3.

In addition, an azo-based acidic dye, a xanthene-based acidic dye, and a phthalocyanine-based acidic dye other than those above are also preferable, and acidic dyes such as C.I. Solvent Blue 44 and 38, C.I. Solvent Orange 45, Rhodamine B, and Rhodamine 110, and derivatives of these dyes are also preferably used.

In particular, the dye is preferably at least one selected from a triarylmethane-based dye, an anthraquinone-based dye, an azomethine-based dye, a benzylidene-based dye, an oxonol-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, a pyrazole azo-based dye, an anilinoazo-based dye, a pyrazolotriazole azo-based dye, a pyridone azo-based dye, an anthrapyridone-based dye, and a pyrromethene-based dye.

Further, a combination of a pigment and a dye may be used.

(Organic Black Colorant)

In the present invention, examples of the organic black colorant include a bisbenzofuranone compound, an azomethine compound, a perylene compound, and an azo-based compound, among which a bisbenzofuranone compound or a perylene compound is preferable.

Examples of the bisbenzofuranone compound include those described in JP2010-534726A, JP2012-515233A, and JP2012-515234A, which are available as, for example, “Irgaphor Black” (manufactured by BASF Corporation).

Examples of the perylene compound include C. I. Pigment Black 31 and 32. Examples of the azomethine compound include those described in JP1989-170601A (JP-H01-170601A) and JP1990-34664A (JP-H02-34664A), which are available as, for example, “CHROMOFINE BLACK A1103” (manufactured by Dainichiseika Color & Chemicals Mfg. Co., Ltd.).

In addition to the foregoing colorant, other components (for example, various binders, and various additives) may be contained in the visible light absorbing layer 28.

The method for producing the visible light absorbing layer 28 is not particularly limited and may be, for example, a known method for producing a color filter. From the viewpoint of excellent producibility such as easy adjustment of a thickness, there is a method in which a visible light absorbing composition containing a colorant and other components (for example, a polymerizable compound, a polymerization initiator, a dispersant, a binder, a surfactant, and a solvent) is applied onto a predetermined surface to be coated, and a curing treatment is carried out if necessary. With respect to the types of the polymerizable compound, the polymerization initiator, the dispersant, the binder, the surfactant, the solvent, and the like, the various materials described in the infrared light absorbing composition described above are suitably used.

Although suitable aspects (first to fifth embodiments) of each laminate have been described above, these suitable aspects may be used in combination. For example, the substrate and the underlayer described in the second embodiment and the antireflection layer described in the third embodiment may be used simultaneously.

Further, each laminate may further have an ultraviolet-infrared light reflection film or an ultraviolet absorbing layer. By including the ultraviolet/infrared light reflection film, an effect of improving the incident angular dependence is obtained. As for the ultraviolet/infrared light reflective film, reference can be made to, for example, the reflective layer described in paragraphs [0033] to [0039] of JP2013-68688A and paragraphs [0110] to of WO2015/099060A, the contents of which are incorporated herein by reference in its entirety. By including the ultraviolet absorbing layer, it is possible to obtain a near infrared cut filter having excellent ultraviolet shielding properties. As for the ultraviolet absorbing layer, reference can be made to, for example, the absorbing layer described in paragraphs

to [0070] and [0119] to [0145] of WO2015/099060A, the contents of which are incorporated herein by reference in its entirety.

<Use of Laminate>

The laminate can be applied to various uses, examples of which include a filter for an optical sensor using a near-infrared ray such as a proximity sensor, and a filter for a solid-state imaging device having both a function of an optical sensor such as a proximity sensor and a function of an image sensor.

Alternatively, the optical sensor may be produced by combining the laminate with a light source emitting light having a peak wavelength located within the first transmission band of the laminate. For example, in the case where the transmission band of the laminate is an infrared light region, it is preferable to use a light source that emits infrared light.

In the case where the laminate has the second transmission band, a light source emitting light having a peak wavelength located within the second transmission band of the laminate may be further combined.

The solid-state imaging device of the present invention includes the laminate of the present invention. For details of the solid-state imaging device including the laminate, reference can be made to the description of paragraphs [0106] and [0107] of JP2015-044188A and the description of paragraphs [0010] to [0012] of JP2014-132333A, the contents of which are incorporated herein by reference in its entirety.

### EXAMPLES

Hereinafter, the present invention will be described more specifically with reference to the Examples. The materials, amount of use, proportion, treatment content, treatment procedure, and the like shown in the following Examples can be appropriately modified without departing from the spirit of the present invention. Accordingly, the scope of the present invention is not limited to the following specific examples. Unless otherwise specified, “%” and “parts” are on a mass basis.

<Preparation of Cholesteric Liquid Crystalline Mixture (Coating Liquid (R 450))>

Compound 1, Compound 2, Compound 3, a fluorine-based horizontal alignment agent, a dextrorotatory chiral agent, a polymerization initiator, and cyclohexanone were mixed to prepare a coating liquid having the following composition. The obtained coating liquid was used as a coating liquid (R450) which is a cholesteric liquid crystalline mixture.

| | |
|---|---|
| Compound 1 | 83 parts by mass |
| Compound 2 | 15 parts by mass |
| Compound 3 | 2 parts by mass |
| Fluorine-based horizontal alignment agent 1 | 0.1 parts by mass |
| Dextrorotatory chiral agent LC756 (manufactured by BASF Corporation) | 7.2 parts by mass |
| Polymerization initiator IRGACURE OXE01 (manufactured by BASF Corporation) | 4 parts by mass |
| Solvent (cyclohexanone) amount which gives a solute concentration of 40 mass % | |

Compound 1 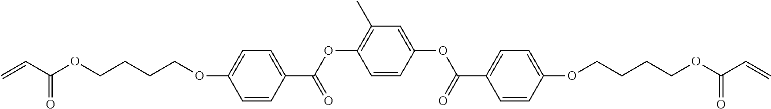 [SMILES: C=CC(=O)OCCCCOc1ccc(C(=O)Oc2ccc(OC(=O)c3ccc(OCCCCOC(=O)C=C)cc3)c(C)c2)cc1]
Compound 2 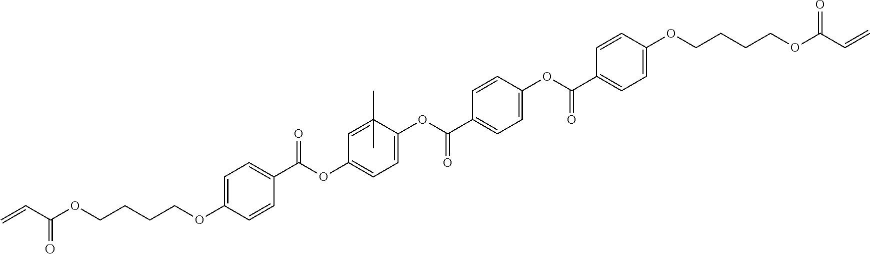
Compound 3 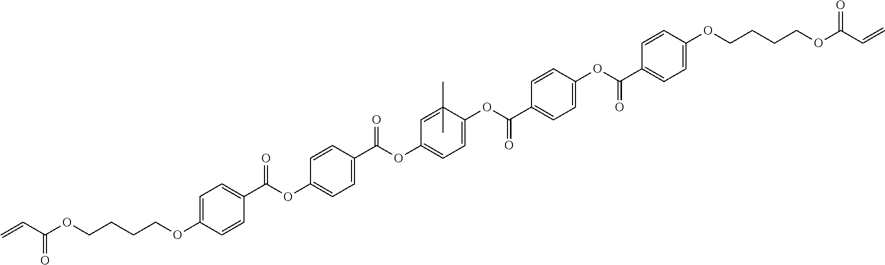
Fluorine-based horizonatal alignment agent 1

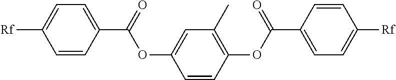

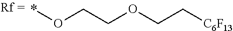

<Preparation of Cholesteric Liquid Crystalline Mixture (Coating Liquid (L450))>

Compound 1, Compound 2, Compound 3, a fluorine-based horizontal alignment agent, a levorotatory chiral agent, a polymerization initiator, and cyclohexanone were mixed to prepare a coating liquid having the following composition. The obtained coating liquid was used as a coating liquid (L450) which is a cholesteric liquid crystalline mixture. In the following formulae, “Bu” represents a butyl group.

| | |
|---|---|
| Compound 1 | 83 parts by mass |
| Compound 2 | 15 parts by mass |
| Compound 3 | 2 parts by mass |
| Fluorine-based horizontal alignment agent 1 | 0.1 parts by mass |
| Levorotatory chiral agent (A) | 11.2 parts by mass |
| Polymerization initiator IRGACURE OXE01 | 4 parts by mass |
| (manufactured by BASF Corporation) | |
| Solvent (cyclohexanone) amount which gives a | |
| solute concentration of 40 mass % | |

Levorotatory chiral agent (A)

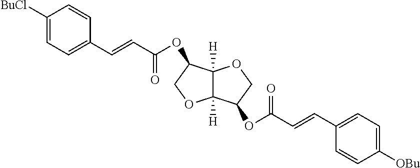

<Preparation of Cholesteric Liquid Crystalline Mixtures>

The following cholesteric liquid crystalline mixtures (coating liquids (R400) to (R1100) and coating liquids (L400) to (L1100)) were prepared in the same manner as in the preparation of the cholesteric liquid crystalline mixtures (coating liquids (R450) and (L450)), except that the amount of each chiral agent was changed according to the table below.

TABLE 1

| | LC756 | | Chiral agent A |
|---|---|---|---|
| Coating liquid | (parts by mass) | Coating liquid | (parts by mass) |
| R400 | 8.1 | L400 | 12.1 |
| R450 | 7.2 | L450 | 11.2 |
| R500 | 6.1 | L500 | 9.2 |
| R550 | 5.5 | L550 | 8.4 |
| R600 | 5.1 | L600 | 7.5 |
| R650 | 4.6 | L650 | 6.9 |
| R700 | 4.1 | L700 | 6.3 |
| R750 | 3.8 | L750 | 5.9 |
| R800 | 3 | L800 | 5.7 |
| R850 | 2.6 | L850 | 5.5 |
| R900 | 2.55 | L900 | 5.2 |
| R950 | 2.5 | L950 | 5 |
| R1000 | 2.45 | L1000 | 4.7 |
| R1050 | 2.4 | L1050 | 4.5 |
| R1100 | 2.35 | L1100 | 4.2 |

<Preparation of Coating Liquid (R1)>

Compound 2-11, a fluorine-based horizontal alignment agent, a chiral agent, a polymerization initiator, and a solvent were mixed to prepare a coating liquid (R1) having the following composition. The refractive index anisotropy An of Compound 2-11 below was 0.375.

| | |
|---|---|
| Compound 2-11 | 100 parts by mass |
| Fluorine-based horizontal alignment agent 1 | 0.1 parts by mass |
| Fluorine-based horizontal alignment agent 2 | 0.007 parts by mass |
| Dextrorotatory chiral agent LC756 (manufactured by BASF Corporation) | 2.2 parts by mass |
| Polymerization initiator: ADEKA ARKLS NCI-831 (manufactured by ADEKA Corporation) | 4 parts by mass |
| Solvent (cyclohexanone) amount which gives a solute concentration of 40 mass % | |

Compound 2-11 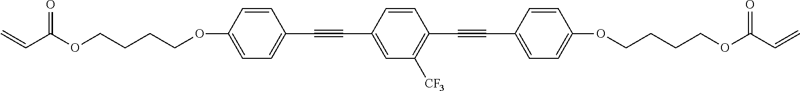 [SMILES: C=CC(=O)OCCCCOc1ccc(C#Cc2ccc(C#Cc3ccc(OCCCCOC(=O)C=C)cc3)c(C(F)(F)F)c2)cc1]
Fluorine-based horizontal alignment agent 2

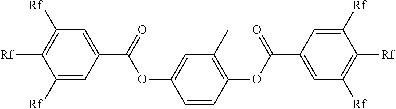

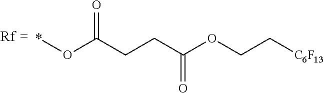

<Preparation of Coating Liquid (L1)>

Compound 2-11, a fluorine-based horizontal alignment agent, a chiral agent, a polymerization initiator, and a solvent were mixed to prepare a coating liquid (L1) having the following composition.

| | | |
|---|---|---|
| Compound 2-11 | 100 | parts by mass |
| Fluorine-based horizontal alignment | 0.1 | parts by mass |
| agent 1 | | |
| Fluorine-based horizontal alignment | 0.007 | parts by mass |
| agent 2 | | |
| Levorotatory chiral agent (A) shown | 3.3 | parts by mass |
| below | | |
| Polymerization initiator: ADEKA ARKLS | 4 | parts by mass |
| NCI-831 (manufactured by ADEKA | | |
| Corporation) | | |

| | |
|---|---|
| Solvent (cyclohexanone) | amount which gives a solute |
| | concentration of 40 mass % |

<Preparation of Composition 1 for Underlayer>

The following components were mixed to prepare Composition 1 for underlayer.

| | |
|---|---|
| CYCLOMER P (Daicel Chemical Industries, Ltd.) | 20.3 parts by mass |
| Fluorine-based surfactant | 0.8 parts by mass |
| Propylene glycol monomethyl ether | 78.9 parts by mass |

<Production of Cholesteric Liquid Crystal Layer>

Composition 1 for underlayer prepared above was applied to a thickness of 0.1 μm onto a glass substrate using a spin coater (manufactured by Mikasa Co., Ltd.) to form a coating film. Next, the glass substrate having a coating film was pre-heated (pre-baked) at 100° C. for 120 seconds. Subsequently, the glass substrate having a coating film was post-heated (post-baked) at 220° C. for 300 seconds to obtain an underlayer 1.

The coating liquid (R450) was applied onto the glass substrate on which the underlayer 1 was formed at room temperature by a spin coater so that the film thickness after drying was 5 μm, thereby forming a coating film. Next, the glass substrate having a coating film was dried at room temperature for 30 seconds to remove the solvent from the coating film, and then heated in an atmosphere at 90° C. for 2 minutes to bring into a cholesteric liquid crystal phase. Next, the coating film was subjected to UV (ultraviolet light) irradiation by an electrodeless lamp “D BULB” (90 mW/cm, manufactured by Fusion UV Systems, Inc.) at an output of 60% for 6 to 12 seconds to immobilize a cholesteric liquid crystal phase, whereby a cholesteric liquid crystal film (FR450) obtained by immobilizing a cholesteric liquid crystal phase on a glass substrate was produced.

Next, the coating liquid (L450) was applied onto the cholesteric liquid crystal film (FR450) at room temperature by a spin coater so that the film thickness after drying was 5 μm, thereby forming a coating film. Next, the glass substrate having a coating film was dried at room temperature for 30 seconds to remove the solvent from the coating film, and then heated in an atmosphere at 90° C. for 2 minutes, after which the coating film was brought into the cholesteric liquid crystal phase at 35° C. Next, the coating film was subjected to UV irradiation by an electrodeless lamp “D BULB” (90 mW/cm, manufactured by Fusion UV Systems, Inc.) at an output of 60% for 6 to 12 seconds to immobilize a cholesteric liquid crystal phase, thereby producing a cholesteric liquid crystal film (FL450).

Through the above treatment, a cholesteric liquid crystal laminate (FRL-450) in which two cholesteric liquid crystal phases are immobilized was produced on a glass substrate. The produced cholesteric liquid crystal laminate (FRL-450) had no significant defects and streaks and thus exhibited a satisfactory surface state.

In the case where the transmission spectra of the cholesteric liquid crystal films (FR450) and (FL450) were measured, the selective reflection wavelength of each thereof was 450 nm. Further, in the case where the transmission spectrum of the cholesteric liquid crystal laminate (FRL-450) was measured, one strong peak was observed around 450 nm. From these findings, it was found that the cholesteric liquid crystal layers obtained by applying the coating liquid (R450) and the coating liquid (L450) had selective reflection wavelengths equal to each other.

Next, in the case where the haze value of the cholesteric liquid crystal laminate (FRL-450) was measured using a haze meter, the average value of three measurements was 0.3 (%).

Further, HTP of the chiral agents used in the coating liquid (R450) and the coating liquid (L450) was calculated according to the following equation, and as a result, it was 54 μm⁻¹ and 35 μm⁻¹, respectively, and HTP was 30 μm⁻¹ or more in both cases.

The chiral agents used in the coating liquids (R450 to R1050 and L450 to L1050) were similarly calculated for HTP, and as a result, HTP was 30 μm⁻¹ or more.

Equation: HTP=1/{(helical pitch length (μm))×(mass % concentration of chiral agent in solid content)} (the helical pitch length (μm) is calculated by (selective reflection wavelength (μm))/(average refractive index of solid content), assuming that the average refractive index of the solid content is 1.5).

Further, cholesteric liquid crystal films (FR400), (FR500), (FR550), (FR600), (FR650), (FR700), (FR750), (FR800), (FR850), (FR900), (FR950), (FR1000), (FR1050), (FR1100), (FL400), (FL500), (FL550), (FL600), (FL650), (FL700), (FL750), (FL800), (FL850), (FL900), (FL950), (FL1000), (FL1050), and (FL1100) were prepared in the same manner as in the preparation of the cholesteric liquid crystal film (FR450), except that a coating liquid (R400, R500, R550, R600, R650, R700, R750, R850, R950, R1000, R1050, R1100, L400, L500, L550, L600, L650, L700, L750, L850, L950, L1000, L1050, or L1100) was used in place of the coating liquid (R450). In the above description, for example, the cholesteric liquid crystal film formed using the coating liquid (R550) corresponds to the cholesteric liquid crystal film (FR550).

The selective reflection wavelengths of the cholesteric liquid crystal films containing a dextrorotatory chiral agent (FR400), (FR500), (FR550), (FR600), (FR650), (FR700), (FR750), (FR800), (FR850), (FR900), (FR950), (FR1000), (FR1050), and (FR1100) were respectively the same as the selective reflection wavelengths of the cholesteric liquid crystal films containing a levorotatory chiral agent (FL400), (FL500), (FL550), (FL600), (FL650), (FL700), (FL750), (FL800), (FL850), (FL900), (FL950), (FL1000), (FL1050), and (FL1100). The selective reflection wavelength of each film corresponds to the numerical value (nm) in the above ( ) and for example, the selective reflection wavelength of the cholesteric liquid crystal film (FR550) is 550 nm.

Next, in the same manner as in the cholesteric liquid crystal laminate (FRL-450), coating liquid (R400) and coating liquid (L400), coating liquid (R500) and coating liquid (L500), coating liquid (R550) and coating liquid (L550), coating liquid (R600) and coating liquid (L600), coating liquid (R650) and coating liquid (L650), coating liquid (R700) and coating liquid (L700), coating liquid (R750) and coating liquid (L750), coating liquid (R800) and coating liquid (L800), coating liquid (R850) and coating liquid (L850), coating liquid (R900) and coating liquid (L900), coating liquid (R950) and coating liquid (L950), coating liquid (R1000) and coating liquid (L1000), coating liquid (R1050) and coating liquid (L1050), and coating liquid (R1100) and coating liquid (L1100) were respectively combined to produce cholesteric liquid crystal laminates (FRL-400, 500, 550, 600, 650, 700, 750, 850, 950, 1000, 1050, and 1100). In the case where the haze values of the produced laminates were measured using a haze meter, the average value of three measurements was 0.3 (%) in each case.

A cholesteric liquid crystal film (FR1) was produced in the same manner as in the production of the cholesteric liquid crystal film (FR450), except that the coating liquid (R1) was used in place of the coating liquid (R450).

A cholesteric liquid crystal film (FL1) was produced in the same manner as in the production of the cholesteric liquid crystal film (FL450), except that the coating liquid (L1) was used in place of the coating liquid (L450).

The reflection wavelength bands of (FR1) and (FL1) were all 960 nm to 1140 nm, and a wide reflection wavelength band was shown for (FR1100) and (FL1100).

Next, in the same manner as the cholesteric liquid crystal laminate (FRL-450), the coating liquid (R1) and the coating liquid (L1) were combined to produce a cholesteric liquid crystal laminate (FRL-1). In the case where the haze value of the produced laminate was measured using a haze meter, the average value of three measurements was 0.3 (%) in each case.

<Preparation of Pigment Dispersion Liquid 1-1>

A mixed liquid having the following composition was mixed and dispersed in a beads mill (high-pressure dispersing machine equipped with a pressure-reducing mechanism, NANO-3,000-10, manufactured by Nippon BEE Chemical Co., Ltd.) using zirconia beads having a diameter of 0.3 mm until the IR (infrared light) colorant had the average particle diameter shown in Table 2, thereby preparing a pigment dispersion liquid. The table shows the used amount (unit: parts by mass) of the corresponding component.

The average particle diameter of the pigment in the pigment dispersion liquid was measured in terms of volume using a MICROTRAC UPA150 (manufactured by Nikkiso Co., Ltd.).

<Preparation of Pigment Dispersion Liquids 2-1 to 2-4>

A mixed liquid having the following composition was mixed and dispersed for 3 hours in a beads mill (high-pressure dispersing machine equipped with a pressure-reducing mechanism, NANO-3,000-10, manufactured by Nippon BEE Chemical Co., Ltd.) using zirconia beads having a diameter of 0.3 mm, thereby preparing a pigment dispersion liquid. The table shows the used amount (unit: parts by mass) of the corresponding component.

TABLE 2

| | Colorant | | | | |
|---|---|---|---|---|---|
| | IR colorant | | | | |
| | | Average | | | |
| | | particle | | | |
| | | diameter | | | |
| | Type | (nm) | Second colorant | Resin | Organic solvent |
| Pigment | Diketopyrrolopyrrole | 75 | | Dispersion resin 1 (4.0) | PGMEA |
| dispersion | pigment 1 | | | | (82.5) |
| liquid 1-1 | (13.5) | | | | |
| Pigment | | | PR254 (13.5) | Dispersion resin 2 (2.0) | PGMEA |
| dispersion | | | | Alkali-soluble resin 1 | (82.5) |
| liquid 2-1 | | | | (2.0) | |
| Pigment | | | PB15:6 (13.5) | Dispersion resin 3 (4.0) | PGMEA |
| dispersion | | | | | (82.5) |
| liquid 2-2 | | | | | |
| Pigment | | | PY139 (14.8) | Dispersion resin 1 (3.0) | PGMEA |
| dispersion | | | | Alkali-soluble resin 1 | (80.0) |
| liquid 2-3 | | | | (2.2) | |
| Pigment | | | PV23(14.8) | Dispersion resin 1 (3.0) | PGMEA |
| dispersion | | | | Alkali-soluble resin 1 | (80.0) |
| liquid 2-4 | | | | (2.2) | |

Abbreviations of individual components in the table are as follows.

[IR Colorant]

Diketopyrrolopyrrole pigment 1: structure shown below (synthesized according to the method described in JP2009-263614A) (a colorant having an absorption maximum in the wavelength range of 800 to 900 nm)

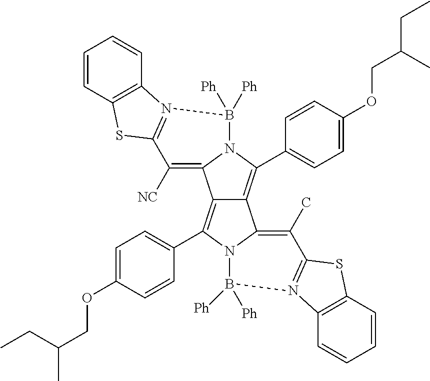

[Second Colorant (a Colorant Having an Absorption Maximum in the Wavelength Range of 400 to 700 nm)]

PR254: C. I. Pigment Red 254

PB15:6: C. I. Pigment Blue 15:6

PY139: Pigment Yellow 139

PV23: Pigment Violet 23

[Resin]

Dispersion resin 1: BYK-111 (manufactured by BYK)

Dispersion resin 2: structure shown below (Mw: 7,950)

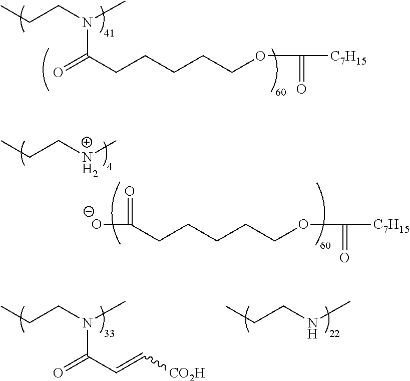

Dispersion resin 3: structure shown below (Mw: 30,000)

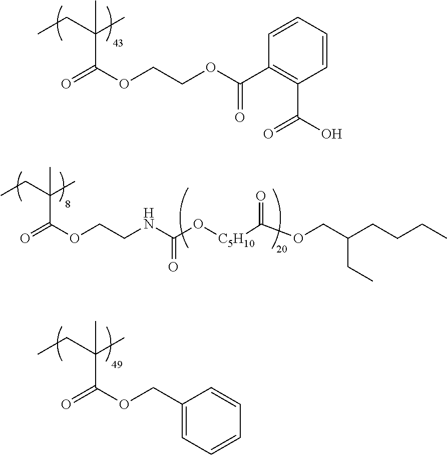

Alkali-soluble resin 1: structure shown below

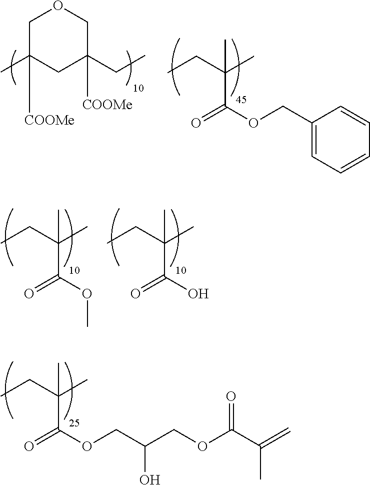

PGMEA: propylene glycol monomethyl ether acetate

<Preparation of Visible Light Absorbing Composition A>

The components shown in the following table were mixed in the proportions (unit: parts by mass) shown in the following table to prepare a visible light absorbing composition A.

TABLE 3

| | Visible light absorbing composition A |
|---|---|
| Pigment dispersion liquid 1-1 | 22.67 |
| Pigment dispersion liquid 2-1 | 11.33 |
| Pigment dispersion liquid 2-2 | 22.67 |
| Pigment dispersion liquid 2-3 | 10.34 |
| Pigment dispersion liquid 2-4 | 6.89 |
| Polymerizable compound 1 | 1.37 |
| Alkali-soluble resin 1 | 3.52 |
| Photopolymerization initiator 1 | 0.86 |
| Surfactant 1 | 0.42 |
| Polymerization inhibitor 1 | 0.001 |
| Organic solvent 1 | 19.93 |

Polymerizable compound 1: M-305 (with 55 to 63 mass % of triacrylate) (manufactured by Toagosei Co., Ltd.)

Structure shown below

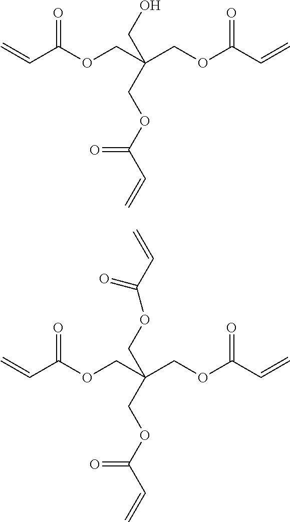

Photopolymerization initiator 1: Irgacure OXE01 (manufactured by BASF Corporation)

Structure shown below

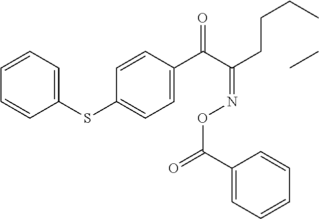

Surfactant 1: mixture shown below (weight-average molecular weight=14,000)

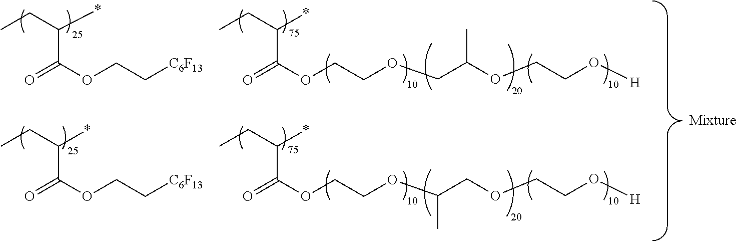

Polymerization inhibitor 1: p-methoxyphenol

Organic solvent 1: propylene glycol methyl ether acetate

<Production of Visible Light Absorbing Layer A>

The visible light absorbing composition A was spin-coated on a glass substrate so as to have a film thickness of 3.0 μm after post-baking, and dried on a hot plate at 100° C. for 120 seconds. After drying, a heat treatment (post-baking) was further carried out using a hot plate at 200° C. for 300 seconds.

Using a spectrophotometer (ref. glass substrate) of a UV-VIS-NIR spectrophotometer (U-4100, manufactured by Hitachi High-Technologies Corporation), the transmittance of the substrate having the obtained visible light absorbing layer A in the wavelength range of 400 to 1,100 nm was measured.

<Preparation of Pigment Dispersion Liquid B-1>

A mixed liquid having the following composition was mixed and dispersed for 3 hours in a beads mill (high-pressure dispersing machine equipped with a pressure-reducing mechanism, NANO-3,000-10, manufactured by Nippon BEE Chemical Co., Ltd.) using zirconia beads having a diameter of 0.3 mm, thereby preparing a pigment dispersion liquid B-1.

| | |
|---|---|
| Mixed pigment made of red pigment (C.I. Pigment | 11.8 parts by mass |
| Red 254) and yellow pigment (C.I. Pigment | |
| Yellow 139) | |
| Dispersant: BYK-111 (manufactured by BYK) | 9.1 parts by mass |
| Organic solvent: propylene glycol methyl ether | 79.1 parts by mass |
| acetate | |

<Preparation of pigment dispersion liquid B-2>

A mixed liquid having the following composition was mixed and dispersed for 3 hours in a beads mill (high-pressure dispersing machine equipped with a pressure-reducing mechanism, NANO-3,000-10, manufactured by Nippon BEE Chemical Co., Ltd.) using zirconia beads having a diameter of 0.3 mm, thereby preparing a pigment dispersion liquid B-2.

| | |
|---|---|
| Mixed pigment composed of blue pigment (CI | 12.6 parts by mass |
| Pigment Blue 15:6) and violet pigment (CI | |
| Pigment Violet 23) | |
| Dispersant: BYK-111 (manufactured by made | 2.0 parts by mass |
| by BYK) | |
| Dispersion resin 4 shown below | 3.3 parts by mass |
| Organic solvent: cyclohexanone | 31.2 parts by mass |
| Organic solvent: propylene glycol methyl ether | 50.9 parts by mass |
| acetate (PGMEA) | |

Dispersion Resin 4

As the dispersion resin 4, the following compounds (the ratio in the repeating unit is a molar ratio) were used.

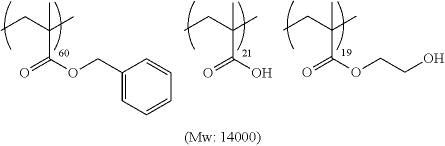

<Preparation of Visible Light Absorbing Composition B>

The following components were mixed to prepare a visible light absorbing composition B.

| | |
|---|---|
| Pigment dispersion liquid B-1 | 46.5 parts by mass |
| Pigment dispersion liquid B-2 | 37.1 parts by mass |
| Alkali-soluble resin 1 shown above | 1.1 parts by mass |
| Polymerizable compound 2 shown below | 1.8 parts by mass |
| Polymerizable compound 3 shown below | 0.6 parts by mass |
| Photopolymerization initiator: polymerization initiator 2 shown below | 0.9 parts by mass |
| Surfactant 1 shown above | 4.2 parts by mass |
| Polymerization inhibitor: p-methoxyphenol | 0.001 parts by mass |
| Organic solvent 1: PGMEA | 7.8 parts by mass |

Polymerizable compound 2: The molar ratio between the left side compound and the right side compound is 7:3. 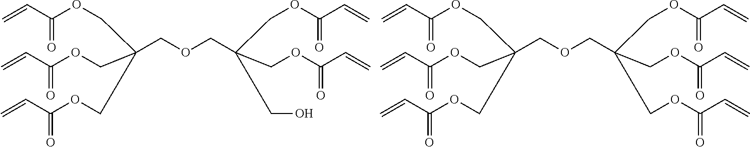
Polymerizable compound 3 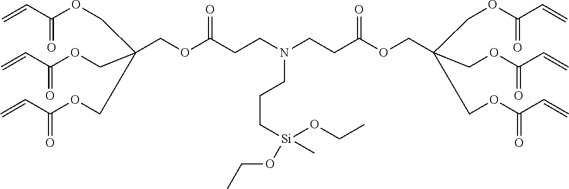 [SMILES: C=CC(=O)OCC(COC(=O)C=C)(COC(=O)C=C)COC(=O)CCN(CCC[Si](C)(OCC)OCC)CCC(=O)OCC(COC(=O)C=C)(COC(=O)C=C)COC(=O)C=C]
Photopolymerization initiator 2

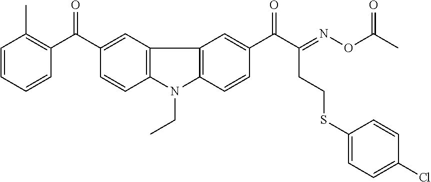 [SMILES: CCn1c2ccc(C(=O)/C(CCSc3ccc(Cl)cc3)=N/OC(C)=O)cc2c2cc(C(=O)c3ccccc3C)ccc21]

<Production of Visible Light Absorbing Layer B>

The visible light absorbing composition B was spin-coated on a glass substrate so as to have a film thickness of 1.0 μm after post-baking, and dried on a hot plate at 100° C. for 120 seconds. After drying, a heat treatment (post-baking) was further carried out using a hot plate at 200° C. for 300 seconds.

Using a spectrophotometer (ref. glass substrate) of a UV-VIS-NIR spectrophotometer (U-4100, manufactured by Hitachi High-Technologies Corporation), the transmittance of the substrate having the obtained visible light absorbing layer B in the wavelength range of 400 to 1,100 nm was measured.

<Production of Visible Light Absorbing Layer C>

A color filter (visible light absorbing layer C) was produced according to the description (Example 1) of paragraphs [0255] to [0259] of JP2013-077009A.

Using a spectrophotometer (ref. glass substrate) of a UV-VIS-NIR spectrophotometer (U-4100, manufactured by Hitachi High-Technologies Corporation), the transmittance of the substrate having the obtained visible light absorption layer C in the wavelength range of 400 to 1,100 nm was measured.

<Preparation of Infrared Light Absorbing Composition 1>

8.04 parts by mass of a resin A shown below, 1.4 parts by mass of an infrared light absorber 1 (maximum absorption wavelength: 760 nm) shown below, 0.07 parts by mass of KAYARAD DPHA (manufactured by Nippon Kayaku Co., Ltd.) as a polymerizable compound, 0.265 parts by mass of MEGAFACE RS-72K (a fluorine-containing polymer having an ethylenically unsaturated group in the side chain, manufactured by DIC Corporation), 0.38 parts by mass of a compound shown below as a photopolymerization initiator, and 82.51 parts by mass of propylene glycol monomethyl ether acetate (PGMEA) as a solvent were mixed and stirred and then filtered through a nylon filter having a pore size of 0.5 μm (manufactured by Nihon Pall Ltd.) to prepare an infrared light absorbing composition 1.

Resin A: compound shown below (weight-average molecular weight (Mw): 41,000)

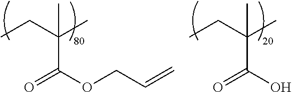

Infrared light absorber 1: structure shown below

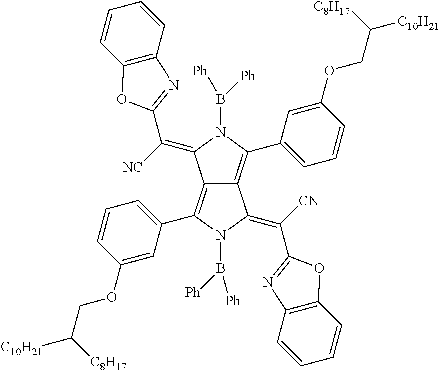

Photopolymerization initiator: structure shown below

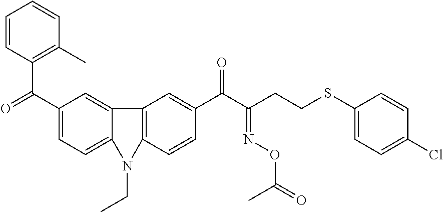 [SMILES: CCn1c2ccc(C(=O)/C(CCSc3ccc(Cl)cc3)=N/OC(C)=O)cc2c2cc(C(=O)c3ccccc3C)ccc21]

<Infrared Light Absorbing Composition 2>

0.5 parts by mass of an infrared light absorber 2 (maximum absorption wavelength: 710 nm) shown below were dissolved in 69.5 parts by mass of ion exchange water to which 30.0 parts by mass of a 10 mass % aqueous solution of gelatin was then further added and stirred to thereby prepare an infrared light absorbing composition 2.

Infrared light absorber 2: structure shown below

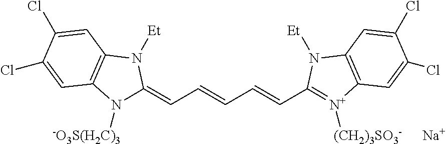

<Production of Infrared Light Absorbing Layer 1>

The infrared light absorbing composition 1 was applied using a spin coater (manufactured by Mikasa Co., Ltd.) to form a coating film. Next, pre-heating (pre-baking) was carried out at 100° C. for 120 seconds. Thereafter, the entire surface exposure was carried out at 1,000 mJ/cm² using an i-line stepper. Next, post-heating (post-baking) was carried out at 220° C. for 300 seconds to obtain an infrared light absorbing layer 1 having a film thickness of 0.7 μm.

<Production of Infrared Light Absorbing Layer 2>

The infrared light absorbing composition 2 prepared above was applied using a spin coater (manufactured by Mikasa Co., Ltd.). Next, a coating film was formed and pre-heated (pre-baked) at 100° C. for 120 seconds. This was followed by post-heating (post-baking) at 220° C. for 300 seconds to obtain an infrared light absorbing layer 2 having a film thickness of 0.2 μm.

<Low Refractive Dispersion Liquid 1>

First, tetramethoxysilane (TMOS) as a silicon alkoxide (A) and trifluoropropyltrimethoxysilane (TFPTMS) as a fluoroalkyl group-containing silicon alkoxide (B) were prepared. These components were weighed such that the ratio (mass ratio) of the fluoroalkyl group-containing silicon alkoxide (B) in the case where the mass of the silicon alkoxide (A) was 1 was 0.6, and were placed and mixed in a separable flask to obtain a mixture. Propylene glycol monomethyl ether acetate (PGMEA) in an amount of 1.0 part by mass with respect to 1 part by mass of this mixture was added as an organic solvent (E), and the mixture was stirred at a temperature of 30° C. for 15 minutes to prepare a first liquid. As the silicon alkoxide (A), an oligomer obtained by polymerizing about 3 to 5 monomers in advance was used.

Apart from this first liquid, ion exchange water (C) in an amount of 1.0 part by mass and formic acid (D) in an amount of 0.01 parts by mass with respect to 1 part by mass of the mixture were placed and mixed in a beaker, and the mixture was stirred at a temperature of 30° C. for 15 minutes to prepare a second liquid. Next, the prepared first liquid was kept at a temperature of 55° C. in a water bath and then the second liquid was added to the first liquid, followed by stirring for 60 minutes while maintaining the above temperature. As a result, a hydrolyzate of the silicon alkoxide (A) and the fluoroalkyl group-containing silicon alkoxide (B) was obtained.

Then, the obtained hydrolyzate and the silica sol (F) in which beaded colloidal silica particles (average particle diameter of spherical particles: 15 nm, D₁/D₂: 5.5, and D₁: 80 nm) were dispersed were stirred and mixed at a ratio such that the SiO₂ content in the silica sol (F) was 200 parts by mass with respect to 100 parts by mass of the SiO₂ content in the hydrolyzate, thereby obtaining a low refractive dispersion liquid 1.

The beaded colloidal silica particles are composed of a plurality of spherical colloidal silica particles and metal oxide-containing silica that bonds the plurality of spherical colloidal silica particles to each other. The average particle diameter of the spherical colloidal silica particles measured by a dynamic light scattering method is defined as D₁ (nm) and the average particle diameter obtained according to the equation of D₂=2720/S from the specific surface area Sm²/g of the spherical colloidal silica particles measured by a nitrogen adsorption method is defined as D₂ (nm). The details thereof are described in JP2013-253145A.

<Preparation of low refractive composition 1>

| | |
|---|---|
| Low refractive dispersion liquid 1 | 75.3 parts by mass |
| Surfactant 1 shown above | 0.1 parts by mass |
| Organic solvent: ethyl lactate | 24.6 parts by mass |

<Production of Antireflection Layer 1>

The low refractive composition 1 was applied using a spin coater (manufactured by Mikasa Co., Ltd.) to form a coating film which was then pre-heated (pre-baked) at 100° C. for 120 seconds. This was followed by post-heating (post-baking) at 220° C. for 300 seconds to provide an antireflection layer 1 having a film thickness of 0.1 μm.

<Preparation of Low Refractive Dispersion Liquid 2>

A low refractive dispersion liquid 2 was prepared according to the same procedure as in the low refractive dispersion liquid 1, except that the beaded colloidal silica particles contained in the low refractive dispersion liquid 1 were changed to hollow particles. Specifically, the hydrolyzate and the silica of the hollow particles were stirred and mixed at a ratio such that the hollow particles become 200 parts by mass with respect to 100 parts by mass of the SiO₂ content in the hydrolyzate, whereby the low refractive dispersion liquid 2 was obtained.

<Production of Antireflection Layer 2>

The low refractive composition 2 prepared according to the following procedure was applied using a spin coater (manufactured by Mikasa Co., Ltd.) to form a coating film which was then pre-heated (pre-bake) at 100° C. for 120 seconds. Then, the coating film was subjected to entire surface exposure at 1,000 mJ/cm² using an i-line stepper. This was subsequently followed by post-heating (post-baking) at 220° C. for 300 seconds to provide an antireflection layer 2 having a film thickness of 0.1 μm.

(Preparation of low refractive composition 2)

| | | |
|---|---|---|
| Low refractive dispersion liquid 2 | 50.0 | parts by mass |
| KAYARAD DPHA | 2.7 | parts by mass |
| (manufactured by Nippon Kayaku Co., Ltd.) | | |
| IRGACURE-OXE02 | 5.0 | parts by mass |
| (manufactured by BASF Corporation) | | |
| Surfactant 1 shown above | 0.1 | parts by mass |
| Organic solvent: ethyl lactate | 41.9 | parts by mass |

(Synthesis of Siloxane Resin)

A hydrolysis condensation reaction was carried out using methyltriethoxysilane. The solvent used at this time was ethanol. The weight-average molecular weight of the obtained siloxane resin A-1 was about 10,000. The weight-average molecular weight was confirmed by gel permeation chromatography (GPC) according to the procedure described above.

Components having the following composition were mixed with a stirrer to prepare a low refractive composition 3.

<Preparation of low refractive composition 3>

| | |
|---|---|
| Siloxane resin A-1 | 20 parts by mass |
| Propylene glycol monomethyl ether acetate (PGMEA) | 64 parts by mass |
| Ethyl 3-ethoxypropionate (EEP) | 16 parts by mass |
| Emulsogen COL-020 (manufactured by Clariant | 2 parts by mass |
| Japan KK) | |

(Formation of Antireflection Layer 3)

The low refractive composition 3 obtained above was spin-coated at 1,000 rpm using a spin coater (manufactured by Mikasa Co., Ltd.) to obtain a coating film. The obtained coating film was heated on a hot plate at 100° C. for 2 minutes and immediately after heating it was heated at 230° C. for 10 minutes to form an antireflection layer 3 having a film thickness of 0.1 μm.

<Preparation of low refractive composition 4>

| | |
|---|---|
| Low refractive dispersion liquid 1 | 75.3 parts by mass |
| Infrared light absorber 1 shown above | 3.0 parts by mass |
| Surfactant 1 shown above | 0.1 parts by mass |
| Organic solvent: ethyl lactate | 24.6 parts by mass |

(Formation of Antireflection Layer 4)

The low refractive composition 4 prepared above was coated using a spin coater (manufactured by Mikasa Co., Ltd.) to form a coating film which was then pre-heated (pre-baked) at 100° C. for 120 seconds. This was subsequently followed by post-heating (post-baking) at 220° C. for 300 seconds to provide an antireflection layer 4 having a film thickness of 0.3 μm.

(Production of Laminate (Bandpass Filter))

With reference to the foregoing film forming method using the composition prepared above, laminates (Examples 1 to 18 and Comparative Examples 1 to 5) were prepared by sequentially forming each layer on a substrate as shown in the following tables (Tables 4 and 5).

TABLE 4

| | | | | | | | | | | |
|---|---|---|---|---|---|---|---|---|---|---|
| Example 1 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR400 | FL400 | FR450 | FL450 | FR500 | FL500 | FR550 | FL550 | FR600 |
| | 11^{th} layer | 12^{th} layer | 13^{th} layer | 14^{th} layer | 15^{th} layer | 16^{th} layer | 17^{th} layer | 18^{th} layer | 19^{th} layer | 20^{th} layer |
| | FL600 | FR750 | FL750 | FR800 | FL800 | FR850 | FL850 | FR900 | FL900 | FR950 |
| | 21^{st} layer | 22^{nd} layer | 23^{rd} layer | 24^{th} layer | 25^{th} layer | 26^{th} layer | 27^{th} layer | | | |
| | FL950 | FR1000 | FL1000 | FR1050 | FL1050 | FR1100 | FL1100 | | | |
| Example 2 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR400 | FL400 | FR450 | FL450 | FR500 | FL500 | FR550 | FL550 | FR600 |
| | 11^{th} layer | 12^{th} layer | 13^{th} layer | 14^{th} layer | 15^{th} layer | 16^{th} layer | 17^{th} layer | 18^{th} layer | 19^{th} layer | 20^{th} layer |
| | FL600 | FR650 | FL650 | FR700 | FL700 | FR750 | FL750 | FR800 | FL800 | FR950 |
| | 21^{st} layer | 22^{nd} layer | 23^{rd} layer | 24^{th} layer | 25^{th} layer | 26^{th} layer | 27^{th} layer | | | |
| | FL950 | FR1000 | FL1000 | FR1050 | FL1050 | FR1100 | FL1100 | | | |
| Example 3 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR400 | FL400 | FR450 | FL450 | FR500 | FL500 | FR550 | FL550 | FR600 |
| | 11^{th} layer | 12^{th} layer | 13^{th} layer | 14^{th} layer | 15^{th} layer | 16^{th} layer | 17^{th} layer | 18^{th} layer | 19^{th} layer | 20^{th} layer |
| | FL600 | FR650 | FL650 | FR700 | FL700 | FR750 | FL750 | FR800 | FL800 | FR850 |
| | 21^{st} layer | 22^{nd} layer | 23^{rd} layer | 24^{th} layer | 25^{th} layer | 26^{th} layer | 27^{th} layer | | | |
| | FL850 | FR1000 | FL1000 | FR1050 | FL1050 | FR1100 | FL1100 | | | |
| Example 4 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR900 | FL900 | FR950 |
| | 11^{th} layer | 12^{th} layer | 13^{th} layer | 14^{th} layer | 15^{th} layer | 16^{th} layer | 17^{th} layer | 18^{th} layer | | |
| | FL950 | FR1000 | FL1000 | FR1050 | FL1050 | FR1100 | FL1100 | Visible light | | |
| | | | | | | | | absorbing layer C | | |
| Example 5 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR950 | FL950 | FR1000 | FL1000 | FR1050 | FL1050 | FR1100 | FL1100 | Visible light |
| | | | | | | | | | | absorbing layer B |
| Example 6 | 1^{st} layer | 2^{nd} layer | 3^{rd} layer | 4^{th} layer | 5^{th} layer | 6^{th} layer | 7^{th} layer | 8^{th} layer | | |
| | Underlayer 1 | FR1000 | FL1000 | FR1050 | FL1050 | FR1100 | FL1100 | Visible light | | |
| | | | | | | | | absorbing layer A | | |
| Example 7 | 1^{st} layer | 2^{nd} layer | 3^{rd} layer | 4^{th} layer | 5^{th} layer | 6^{th} layer | 7^{th} layer | 8^{th} layer | 9^{th} layer | |
| | Underlayer 1 | FR1000 | FL1000 | FR1050 | FL1050 | FR1100 | FL1100 | Visible light | Antireflection | |
| | | | | | | | | absorbing layer A | layer 1 | |
| Example 8 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR950 | FL950 | FR1000 | FL1000 | FR1050 |
| | 11^{th} layer | 12^{th} layer | 13^{th} layer | 14^{th} layer | | | | | | |
| | FL1050 | FR1100 | FL1100 | Antireflection | | | | | | |
| | | | | layer 1 | | | | | | |
| Example 9 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR1000 | FL1000 | FR1050 |
| | 11^{th} layer | 12^{th} layer | 13^{th} layer | 14^{th} layer | | | | | | |
| | FL1050 | FR1100 | FL1100 | Antireflection | | | | | | |
| | | | | layer 1 | | | | | | |
| Example 10 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR950 | FL950 | FR1000 | FL1000 | FR1050 |
| | 11^{th} layer | 12^{th} layer | 13^{th} layer | 14^{th} layer | 15^{th} layer | | | | | |
| | FL1050 | FR1100 | FL1100 | Infrared light | Antireflection | | | | | |
| | | | | absorbing layer 1 | layer 1 | | | | | |
| Example 11 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR1000 | FL1000 | FR1050 |
| | 11^{th} layer | 12^{th} layer | 13^{th} layer | 14^{th} layer | 15^{th} layer | | | | | |
| | FL1050 | FR1100 | FL1100 | Infrared light | Antireflection | | | | | |
| | | | | absorbing layer 1 | layer 1 | | | | | |
| Example 12 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR950 | FL950 | FR1000 | FL1000 | FR1050 |
| | 11^{th} layer | 12^{th} layer | 13^{th} layer | 14^{th} layer | 15^{th} layer | | | | | |
| | FL1050 | FR1100 | FL1100 | Infrared light | Antireflection | | | | | |
| | | | | absorbing layer 2 | layer 1 | | | | | |
| Example 13 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR1000 | FL1000 | FR1050 |
| | 11^{th} layer | 12^{th} layer | 13^{th} layer | 14^{th} layer | 15^{th} layer | | | | | |
| | FL1050 | FR1100 | FL1100 | Infrared light | Antireflection | | | | | |
| | | | | absorbing layer 1 | layer 2 | | | | | |
| Example 14 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR1000 | FL1000 | FR1050 |
| | 11^{th} layer | 12^{th} layer | 13^{th} layer | 14^{th} layer | 15^{th} layer | | | | | |
| | FL1050 | FR1100 | FL1100 | Infrared light | Antireflection | | | | | |
| | | | | absorbing layer 1 | layer 3 | | | | | |
| Example 15 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR1000 | FL1000 | FR1050 |
| | 11^{th} layer | 12^{th} layer | 13^{th} layer | 14^{th} layer | | | | | | |
| | FL1050 | FR1100 | FL1100 | Antireflection | | | | | | |
| | | | | layer 4 | | | | | | |
| Example 16 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR1000 | FL1000 | FR1050 |
| | 11^{th} layer | 12^{th} layer | 13^{th} layer | 14^{th} layer | | | | | | |
| | FL1050 | FR1100 | FL1100 | Infrared light | | | | | | |
| | | | | absorbing layer 1 | | | | | | |
| Example 17 | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| | Underlayer 1 | FR750 | FL750 | FR800 | FL800 | FR850 | FL850 | FR1000 | FL1000 | FR1050 |
| | 11^{th} layer | 12^{th} layer | 13^{th} layer | | | | | | | |
| | FL1050 | FR1100 | FL1100 | | | | | | | |
| Comparative | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| Example 1 | Underlayer 1 | FR400 | FL400 | FR450 | FL450 | FR500 | FL500 | FR550 | FL550 | FR600 |
| | 11^{th} layer | 12^{th} layer | 13^{th} layer | 14^{th} layer | 15^{th} layer | 16^{th} layer | 17^{th} layer | 18^{th} layer | 19^{th} layer | 20^{th} layer |
| | FL500 | FR650 | FL650 | FR700 | FL700 | FR750 | FL750 | FR800 | FL800 | FR850 |
| | 21^{st} Player | 22^{nd} layer | 23^{rd} layer | 24^{th} layer | 25^{th} layer | 26^{th} layer | | | | |
| | FR1000 | FL1000 | FR1050 | FL1050 | FR1100 | FL1100 | | | | |
| Comparative | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| Example 2 | Underlayer 1 | FR400 | FL400 | FR450 | FL450 | FR500 | FL500 | FR550 | FL550 | FR600 |
| | 11^{th} layer | 12^{th} layer | 13^{th} layer | 14^{th} layer | 15^{th} layer | 16^{th} layer | 17^{th} layer | 18^{th} layer | 19^{th} layer | 20^{th} layer |
| | FL600 | FR650 | FL650 | FR700 | FL700 | FR750 | FL750 | FR800 | FL800 | FR850 |
| | 21^{st} Player | 22^{nd} layer | 23^{rd} layer | 24^{th} layer | 25^{th} layer | 26^{th} layer | | | | |
| | FL850 | FR1000 | FR1050 | FL1050 | FR1100 | FL1100 | | | | |
| Comparative | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| Example 3 | Underlayer 1 | FR750 | FL750 | FR800 | FL800 | FR850 | FR1000 | FL1000 | FR1050 | FL1050 |
| | 11^{th} layer | 12^{th} layer | 13^{th} layer | | | | | | | |
| | FR1100 | FL1100 | Antireflection | | | | | | | |
| | | | layer 1 | | | | | | | |
| Comparative | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| Example 4 | Underlayer 1 | FR750 | FL750 | FR800 | FL800 | FR850 | FL850 | FR1000 | FR1050 | FL1050 |
| | 11^{th} layer | 12^{th} layer | 13^{th} layer | | | | | | | |
| | FR1100 | FL1100 | Antireflection | | | | | | | |
| | | | layer 1 | | | | | | | |
| Comparative | 1^{st} layer | 2^{nd} layer | 3^{rd} layer | 4^{th} layer | 5^{th} layer | 6^{th} layer | 7^{th} layer | 8^{th} layer | 9^{th} layer | 10^{th} layer |
| Example 5 | FR400 | FL400 | FR450 | FL450 | FR500 | FL500 | FR550 | FL550 | FR600 | FL600 |
| | 11^{th} layer | 12^{th} layer | 13^{th} layer | 14^{th} layer | 15^{th} layer | 16^{th} layer | 17^{th} layer | 18^{th} layer | 19^{th} layer | 20^{th} layer |
| | FR650 | FL650 | FR700 | FL700 | FR750 | FL750 | FR800 | FL800 | FR850 | FL850 |
| | 21^{st} layer | 22^{nd} layer | 23^{rd} layer | 24^{th} layer | 25^{th} layer | 26^{th} layer | 27^{th} layer | | | |
| | FR1000 | FL1000 | FR1050 | FL1050 | FR1100 | FL1100 | FL1100 | | | |

TABLE 5

| | 1^{st} | 2^{nd} | 3^{rd} | 4^{th} | 5^{th} |
|---|---|---|---|---|---|
| | layer | layer | layer | layer | layer |
| Example | Underlayer | FR1 | FL1 | Infrared light | Antireflection |
| 18 | 1 | | | absorbing | layer 1 |
| | | | | layer 1 | |

<<Various Evaluations>>

<Haze>

Using the laminates obtained in the respective Examples and the respective Comparative Examples, the haze values thereof were measured with a haze meter NDH-5000 (manufactured by Nippon Denshoku Industries Co., Ltd.) and evaluated according to the following standards.

3: Haze value is less than 1.0%

2: Haze value is 1.0% or more and 2.0% or less

1: Haze value is greater than 2.0%

<Measurement Accuracy>

Using a UV-VIS-NIR spectrophotometer (U-4100, manufactured by Hitachi High-Technologies Corporation), the transmittance of the laminates obtained in the respective Examples and the respective Comparative Examples was measured to determine the (maximum transmittance of transmission band)/(minimum transmittance of light-shielding band) and evaluated according to the following standards.

3: The (maximum transmittance of transmission band)/(minimum transmittance of light-shielding band) is greater than 70

2: The (maximum transmittance of transmission band)/(minimum transmittance of light-shielding band) is 50 or more and 70 or less

1: The (maximum transmittance of transmission band)/(minimum transmittance of light-shielding band) is smaller than 50

The “maximum transmittance of transmission band” is intended to mean the maximum transmittance in the region from the half-value wavelength on the short wavelength side of the transmission band (for example, the first transmission band and the second transmission band described above) in the transmission spectrum of the laminate to the half-value wavelength on the long wavelength side of the transmission band. The “minimum transmittance of light-shielding band” is intended to mean the minimum transmittance in the wavelength range of 100 nm from the half-value wavelength on the short wavelength side of the transmission band (for example, the first transmission band and the second transmission band described above) in the transmission spectrum of the laminate to the short wavelength side, and in the wavelength range of 100 nm from the half-value wavelength on the long wavelength side to the long wavelength side. In the case where the minimum transmittance is “0%”, calculation is carried out assuming that the (minimum transmittance of light-shielding band) is “0.1%”.

Further, in the case where the laminate of the respective Examples includes two transmission bands of the first transmission band and the second transmission band, the above evaluation is carried out for both transmission bands, and those with the lowest evaluation score are shown in Tables 6 and 7.

<Angular Dependence>

Using the laminates obtained in the respective Examples and the respective Comparative Examples, the incidence angle was changed perpendicularly (at an angle of 0 degrees) and to 30 degrees with respect to the laminate surface, and the shift amount of the half-value wavelength of the transmission band was evaluated according to the following standards. More specifically, the shift amount is intended to mean the difference between the half-value wavelength position X at the time of incidence from the vertical direction and the half-value wavelength position Y at the time of incidence from the oblique direction.

3: less than 5 nm

2: 5 nm or more and less than 10 nm

1: 10 nm or more

Further, in the case where the laminate of the respective Examples includes two transmission bands of the first transmission band and the second transmission band, the above evaluation is carried out for both transmission bands, and those with the lowest evaluation score are shown in Tables 6 and 7.

As for the half-value wavelength, in the first transmission band, the shift amount was measured using the half-value wavelength on the short wavelength side, and in the second transmission band, the shift amount was measured using the half-value wavelength on the long wavelength side.

In Tables 6 and 7, the “Wavelength range” is intended to mean the range (nm) of the first transmission band (or the second transmission band).

In Tables 6 and 7, “Average transmittance 1A (%)” is intended to mean an average transmittance in the wavelength range from the half-value wavelength A on the short wavelength side of the first transmission band to the half-value wavelength B on the long wavelength side of the first transmission band, “Average transmittance 1B (%)” is intended to mean an average transmittance in the wavelength range of 100 nm from the half-value wavelength A on the short wavelength side to the short wavelength side, and “Average transmittance 1C (%)” is intended to mean an average transmittance in the wavelength range of 100 nm from the half-value wavelength B on the long wavelength side to the long wavelength side.

In Tables 6 and 7, “slope” is intended to mean a value (short-wave side slope) determined by (T2−T1)/20 described above, and a value (long-wave side slope) determined by (T3−T4)/20 described above.

In Tables 6 and 7, “Average transmittance 2A (%)” is intended to mean an average transmittance in the wavelength range from the half-value wavelength A on the short wavelength side of the second transmission band to the half-value wavelength B on the long wavelength side of the second transmission band, “Average transmittance 2B (%)” is intended to mean an average transmittance in the wavelength range of 50 nm from the half-value wavelength A on the short wavelength side to the short wavelength side, and “Average transmittance 2C (%)” is intended to mean an average transmittance in the wavelength range of 50 nm from the half-value wavelength B on the long wavelength side to the long wavelength side.

In the following laminates of the Examples, there is a wavelength range X in which the transmittance exceeds 30% in the wavelength range of 400 to 1,200 nm, and the wavelength range X was present only within at least one of the first transmission band or the second transmission band.

TABLE 6

| | First transmission band | | | | | | | Second transmission band |
|---|---|---|---|---|---|---|---|---|
| | Wavelength | | Average | Average | Average | Short-wave | Long-wave | Wavelength |
| | range | Half-width | transmittance | transmittance | transmittance | side slope | side slope | range |
| | (nm) | (nm) | 1A (%) | 1B (%) | 1C (%) | (T %/nm) | (T %/nm) | (nm) |
| Example 1 | 650-700 | 50 | 61 | 4 | 4 | 2.2 | 2.2 | — |
| Example 2 | 850-900 | 50 | 65 | 4 | 4 | 2.2 | 2.2 | — |
| Example 3 | 900-950 | 50 | 65 | 4 | 4 | 2.2 | 2.2 | — |
| Example 4 | 650-700 | 50 | 65 | 7 | 4 | 1.3 | 2.2 | — |
| Example 5 | 810-900 | 90 | 68 | 8 | 4 | 1.6 | 2.2 | — |
| Example 6 | 900-950 | 50 | 65 | 3 | 4 | 1.2 | 2.2 | — |
| Example 7 | 900-950 | 50 | 72 | 3 | 4 | 1.2 | 2.2 | — |
| Example 8 | 850-900 | 50 | 65 | 4 | 4 | 2.2 | 2.2 | 400-700 |
| Example 9 | 900-950 | 50 | 65 | 4 | 4 | 2.2 | 2.2 | 400-700 |
| Example 10 | 850-900 | 50 | 65 | 4 | 4 | 2.2 | 2.2 | 420-680 |
| Example 11 | 900-950 | 50 | 65 | 4 | 4 | 2.2 | 2.2 | 420-680 |
| Example 12 | 850-900 | 50 | 65 | 4 | 4 | 2.2 | 2.2 | 420-680 |
| Example 13 | 900-950 | 50 | 65 | 4 | 4 | 2.2 | 2.2 | 420-680 |
| Example 14 | 900-950 | 50 | 65 | 4 | 4 | 2.2 | 2.2 | 420-680 |
| Example 15 | 900-950 | 50 | 65 | 4 | 4 | 2.2 | 2.2 | 400-700 |
| Example 16 | 900-950 | 50 | 65 | 4 | 4 | 2.2 | 2.2 | 420-680 |
| Example 17 | 900-950 | 50 | 65 | 4 | 4 | 2.2 | 2.2 | 400-700 |
| Comparative | 900-950 | 50 | 65 | 30 | 4 | 2.2 | 2.2 | — |
| Example 1 | | | | | | | | |
| Comparative | 900-950 | 50 | 65 | 4 | 30 | 2.2 | 2.2 | — |
| Example 2 | | | | | | | | |
| Comparative | 900-950 | 50 | 65 | 30 | 4 | 2.2 | 2.2 | 400-700 |
| Example 3 | | | | | | | | |
| Comparative | 900-950 | 50 | 65 | 4 | 30 | 2.2 | 2.2 | 400-700 |
| Example 4 | | | | | | | | |
| Comparative | 900-950 | 50 | 43 | 4 | 4 | 2.2 | 2.2 | — |
| Example 5 | | | | | | | | |

| | Second transmission band | | | | | | | | |
|---|---|---|---|---|---|---|---|---|---|
| | | Average | Average | Average | Laminate configuration | | Evaluation | | |
| | Half-width | transmittance | transmittance | transmittance | Color material | Antireflection | | Measurement | Angular |
| | (nm) | 2A (%) | 2B (%) | 2C (%) | layer | layer | Haze | accuracy | dependence |
| Example 1 | — | — | — | — | Absent | Absent | 2 | 2 | 2 |
| Example 2 | — | — | — | — | Absent | Absent | 2 | 2 | 2 |
| Example 3 | — | — | — | — | Absent | Absent | 2 | 2 | 2 |
| Example 4 | — | — | — | — | Visible light | Absent | 2 | 2 | 3 |
| | | | | | absorbing layer | | | | |
| | | | | | C | | | | |
| Example 5 | — | — | — | — | Visible light | Absent | 2 | 2 | 3 |
| | | | | | absorbing layer | | | | |
| | | | | | B | | | | |
| Example 6 | — | — | — | — | Visible light | Absent | 2 | 2 | 3 |
| | | | | | absorbing layer | | | | |
| | | | | | A | | | | |
| Example 7 | — | — | — | — | Visible light | Antireflection | 3 | 3 | 3 |
| | | | | | absorbing layer | layer 1 | | | |
| | | | | | A | | | | |
| Example 8 | 300 | 96 | 7 | 5 | Absent | Antireflection | 3 | 3 | 2 |
| | | | | | | layer 1 | | | |
| Example 9 | 300 | 96 | 7 | 5 | Absent | Antireflection | 3 | 3 | 2 |
| | | | | | | layer 1 | | | |
| Example 10 | 260 | 92 | 7 | 3 | Infrared light | Antireflection | 3 | 3 | 3 |
| | | | | | absorbing layer | layer 1 | | | |
| | | | | | 1 | | | | |
| Example 11 | 260 | 92 | 7 | 3 | Infrared light | Antireflection | 3 | 3 | 3 |
| | | | | | absorbing layer | layer 1 | | | |
| | | | | | 1 | | | | |
| Example 12 | 260 | 91 | 6 | 2 | Infrared light | Antireflection | 3 | 3 | 3 |
| | | | | | absorbing layer | layer 1 | | | |
| | | | | | 2 | | | | |
| Example 13 | 260 | 92 | 7 | 3 | Infrared light | Antireflection | 3 | 3 | 3 |
| | | | | | absorbing layer | layer 2 | | | |
| | | | | | 1 | | | | |
| Example 14 | 260 | 92 | 7 | 3 | Infrared light | Antireflection | 3 | 3 | 3 |
| | | | | | absorbing layer | layer 3 | | | |
| | | | | | 1 | | | | |
| Example 15 | 300 | 96 | 7 | 5 | Absent | Antireflection | 3 | 3 | 2 |
| | | | | | | layer 4 | | | |
| Example 16 | 260 | 87 | 7 | 3 | Infrared light | Absent | 2 | 2 | 3 |
| | | | | | absorbing layer | | | | |
| | | | | | 1 | | | | |
| Example 17 | 300 | 91 | 7 | 5 | Absent | Absent | 2 | 2 | 2 |
| Comparative | — | — | — | — | Absent | Absent | 1 | 1 | 2 |
| Example 1 | | | | | | | | | |
| Comparative | — | — | — | — | Absent | Absent | 1 | 1 | 2 |
| Example 2 | | | | | | | | | |
| Comparative | 300 | 96 | 7 | 5 | Absent | Antireflection | 1 | 1 | 2 |
| Example 3 | | | | | | layer 1 | | | |
| Comparative | 300 | 96 | 7 | 5 | Absent | Antireflection | 1 | 1 | 2 |
| Example 4 | | | | | | layer 1 | | | |
| Comparative | — | — | — | — | Absent | Absent | 1 | 1 | 2 |
| Example 5 | | | | | | | | | |

TABLE 7

| | First transmission band | | | | | | | Second transmission band |
|---|---|---|---|---|---|---|---|---|
| | Wavelength | | Average | Average | Average | Short-wave | Long-wave | Wavelength |
| | range | Half-width | transmittance | transmittance | transmittance | side slope | side slope | range |
| | (nm) | (nm) | 1A (%) | 1B (%) | 1C (%) | (T %/nm) | (T %/nm) | (nm) |
| Example 18 | 900-960 | 60 | 65 | 4 | 4 | 2.2 | 2.3 | 420-680 |

| | Second transmission band | | | | | | | | |
|---|---|---|---|---|---|---|---|---|---|
| | | Average | Average | Average | Laminate configuration | | Evaluation | | |
| | Half-width | transmittance | transmittance | transmittance | Color material | Antireflection | | Measurement | Angular |
| | (nm) | 2A (%) | 2B (%) | 2C (%) | layer | layer | Haze | accuracy | dependence |
| Example 18 | 260 | 92 | 7 | 3 | Infrared light | Antireflection | 3 | 3 | 3 |
| | | | | | absorbing layer | layer 1 | | | |
| | | | | | 1 | | | | |

As shown in Tables 6 and 7 above, it was confirmed that the laminate of the present invention exhibits the desired effects.

In particular, it was confirmed that in the case where the infrared light absorbing layer is included in the laminate, the angular dependence is further improved.

In addition, it was confirmed that in the case where the antireflection layer is included in the laminate, the measurement accuracy is excellent.

On the other hand, in Comparative Examples, it was confirmed that the effects of the present invention are not obtained in Comparative Examples 1 to 5 which do not satisfy the predetermined average transmittance conditions.

### EXPLANATION OF REFERENCES

10, 100, 200, 300, 400: laminate

12a, 12b, 12c, 12d: first reflective layer

14a, 14b, 14c, 14d: second reflective layer

16: first transmission band

18: second transmission band

20: substrate

22: underlayer

24: antireflection layer

26: infrared light absorbing layer

28: visible light absorbing layer

What is claimed is:

1. A laminate, comprising:
at least one first reflective layer formed by immobilizing a liquid crystal phase in which a rotational direction of the helical axis is rightward; and
at least one second reflective layer formed by immobilizing a liquid crystal phase in which the rotational direction of the helical axis is leftward,
wherein the laminate has a first transmission band in the wavelength range of 300 to 3,000 nm,
the half-width of the first transmission band is 200 nm or less,
an average transmittance in a wavelength range from a half-value wavelength A on the short wavelength side of the first transmission band to a half-value wavelength B on the long wavelength side of the first transmission band is 50% or more, and
the average transmittance in the wavelength range of 100 nm from the half-value wavelength A to the short wavelength side and the average transmittance in the wavelength range of 100 nm from the half-value wavelength B to the long wavelength side are respectively less than 20%.

2. The laminate according to claim 1, further having a second transmission band in the wavelength range of 300 to 3,000 nm, wherein
the half-width of the second transmission band is 200 nm or more,
the average transmittance in the wavelength range from a half-value wavelength C on the short wavelength side of the second transmission band to a half-value wavelength D on the long wavelength side of the second transmission band is 30% or more, and
the average transmittance in the wavelength range of 50 nm from the half-value wavelength C to the short wavelength side and the average transmittance in the wavelength range of 50 nm from the half-value wavelength D to the long wavelength side are respectively less than 30%.

3. The laminate according to claim 2, wherein the average transmittance in the wavelength range from the half-value wavelength C to the half-value wavelength D is 70% or more.

4. The laminate according to claim 2, wherein at least one of the first transmission band or the second transmission band is within a wavelength range of 650 to 3,000 nm.

5. The laminate according to claim 3, wherein at least one of the first transmission band or the second transmission band is within a wavelength range of 650 to 3,000 nm.

6. The laminate according to claim 2, wherein at least one of the first transmission band or the second transmission band is within a wavelength range of 650 to 1,200 nm.

7. The laminate according to claim 3, wherein at least one of the first transmission band or the second transmission band is within a wavelength range of 650 to 3,000 nm.

8. The laminate according to claim 2, further having a wavelength range X being present only within at least one of the first transmission band or the second transmission band,
wherein the wavelength range X is a range in which the transmittance exceeds 30% in the wavelength range of 400 to 1,200 nm.

9. The laminate according to claim 3, further having a wavelength range X being present only within at least one of the first transmission band or the second transmission band,
wherein the wavelength range X is a range in which the transmittance exceeds 30% in the wavelength range of 400 to 1,200 nm.

10. The laminate according to claim 4, further having a wavelength range X being present only within at least one of the first transmission band or the second transmission band,
wherein the wavelength range X is a range in which the transmittance exceeds 30% in the wavelength range of 400 to 1,200 nm.

11. The laminate according to claim 6, further having a wavelength range X being present only within at least one of the first transmission band or the second transmission band,
wherein the wavelength range X is a range in which the transmittance exceeds 30% in the wavelength range of 400 to 1,200 nm.

12. The laminate according to claim 1, wherein the value determined by (T2-T1)/20 is 1 to 5 in the case where the transmittance at a wavelength of 10 nm from the half-value wavelength A to the short wavelength side is T1 and the transmittance at a wavelength of 10 nm from the half-value wavelength A to the long wavelength side is T2, and
the value determined by (T3-T4)/20 is 1 to 5 in the case where the transmittance at a wavelength of 10 nm from the half-value wavelength B to the short wavelength side is T3 and the transmittance at a wavelength of 10 nm from the half-value wavelength B to the long wavelength side is T4, with the unit of T1 to T4 being %.

13. The laminate according to claim 1, which is used as a filter for an optical sensor.

14. The laminate according to claim 1, which is used as a filter for a solid-state imaging device.

15. An optical sensor, comprising:
the laminate according to claim 1; and
a light source emitting light having a peak wavelength located within a first transmission band of the laminate.

16. A kit for use in the production of the laminate according to claim 1, comprising:
a liquid crystal composition containing at least a liquid crystal compound and a dextrorotatory chiral agent; and
a liquid crystal composition containing at least a liquid crystal compound and a levorotatory chiral agent.
